(19) United States
(12) Patent Application Publication
(10) Pub. No.: US 2026/0173638 A1
(43) Pub. Date: Jun. 18, 2026

(54) ORGANIC LIGHT-EMITTING DEVICE

(71) Applicant: CANON KABUSHIKI KAISHA, Tokyo (JP)

(72) Inventors: HIROKI OHRUI, Tokyo (JP); YOSUKE NISHIDE, Kanagawa (JP); HIRONOBU IWAWAKI, Kanagawa (JP); ITARU TAKAYA, Kanagawa (JP); SATORU SHIOBARA, Kanagawa (JP); NAOKI YAMADA, Tokyo (JP)

(21) Appl. No.: 19/531,325

(22) Filed: Feb. 5, 2026

Related U.S. Application Data
(63) Continuation of application No. PCT/JP2024/027904, filed on Aug. 5, 2024.

(30) Foreign Application Priority Data
Aug. 9, 2023 (JP) 2023-130036

(51) Int. Cl. H10K 50/11; F21S 43/145; G02B 27/01; G03G 15/04; H04N 23/63; H10K 50/16; H10K 50/19; H10K 85/30; H10K 85/60; H10K 101/40

(52) U.S. Cl. CPC H10K 50/11; H10K 50/16; H10K 50/19; H10K 85/324; H10K 85/342; H10K 85/346; H10K 85/622; H10K 85/623; H10K 85/624; H10K 85/626; H10K 85/633; H10K 85/636; H10K 85/654; H10K 85/656; H10K 85/6572; H10K 85/6574; H10K 85/6576; H10K 85/658; F21S 43/145; G02B 27/0172; G02B 2027/0178; G03G 15/04054; G03G 2215/0412; H04N 23/633; H10K 2101/40

(57) ABSTRACT

The present disclosure relates to an organic light-emitting device that is configured to operate at a low driving voltage and that has excellent durability. The organic light-emitting device includes a first light-emitting unit and a second light-emitting unit with a charge generation region interposed therebetween. The charge generation region includes an n-type charge generation layer containing at least a first organic compound and a second organic compound. The first organic compound and the second organic compound satisfy the relationships represented by the following Formulae [1] and [2-1]:

$$\vert LUMO ( H 1 ) - LUMO ( H 2 ) \vert \leq 0.1 eV \qquad [ 1 ]$$

$$HOMO ( H 2 ) - HOMO ( H 1 ) > 0. eV \qquad [ 2 - 1 ]$$

wherein LUMO(H1) represents the LUMO energy level of the first organic compound,
LUMO(H2) represents the LUMO energy level of the second organic compound,
HOMO(H1) represents the HOMO energy level of the first organic compound, and
HOMO(H2) represents the HOMO energy level of the second organic compound.

### CROSS-REFERENCE TO RELATED APPLICATIONS

This application is a Continuation of International Patent Application No. PCT/JP2024/027904, filed Aug. 5, 2024, which claims the benefit of Japanese Patent Application No. 2023-130036, filed Aug. 9, 2023, both of which are hereby incorporated by reference herein in their entirety.

### BACKGROUND

### Field of the Technology

The present disclosure relates to an organic light-emitting device and various apparatuses having the organic light-emitting device.

### Description of the Related Art

An organic electroluminescent device (hereinafter, also referred to as an “organic EL device” or an “organic light-emitting device”) is a device that emits light by energizing an organic compound layer that includes an anode, a cathode, and a light-emitting layer disposed between these electrodes.

In recent years, in addition to single-color organic light-emitting devices that emit white light by incorporating red, green, and blue-light-emitting materials into a single light-emitting layer, stacked organic light-emitting devices have been developed in which separate light-emitting layers for red, green, and blue are stacked. Stacked organic light-emitting devices tend to have higher driving voltages than single-layer organic light-emitting devices. Therefore, a structure in which an intermediate layer called a charge generation region or an intermediate electrode is provided is known. The intermediate layer may be more prone to degradation than other organic layers. Since degradation of the intermediate layer leads to higher driving voltage, lower efficiency, and reduced durability, the development of a stable charge generation layer is required.

U.S. Patent Application Publication No. 2015/0090984 describes a configuration in which an n-type charge generation layer includes at least two or more materials with different LUMOs. U.S. Patent Application Publication No. 2016/0104844 describes a configuration in which an organic compound having a pyrene skeleton is used in an n-type charge generation layer.

However, in the stacked organic light-emitting device described in U.S. Patent Application Publication No. 2015/0090984, the n-type charge generation layer is composed of two or more materials having different LUMO levels. Therefore, electron trap levels may be formed, leading to a reduction in the electron mobility within the n-type charge generation layer. Consequently, the driving voltage of the organic light-emitting device may increase. In addition, in the stacked organic light-emitting device described in U.S. Patent Application Publication No. 2016/0104844, an organic compound contained in the n-type charge generation layer has a heterocycle as a substituent on a pyrene skeleton. Compounds having heterocyclic groups may have low stability to holes. Therefore, the stacked organic light-emitting device disclosed in U.S. Patent Application Publication No. 2016/0104844 has room for improvement in the durability of the n-type charge generation layer.

### SUMMARY

The present disclosure has been made in view of the above problems, and the present disclosure is directed to providing an organic light-emitting device that is configured to operate at a low driving voltage and that has excellent durability.

According to an aspect of the present disclosure, there is provided an organic light-emitting device including, in this order, a first electrode, a first light-emitting unit, a charge generation region, a second light-emitting unit, and a second electrode. The charge generation region includes at least one n-type charge generation layer. The at least one n-type charge generation layer contains at least a first organic compound and a second organic compound. The first organic compound and the second organic compound satisfy the relationships represented by the following formulae [1] and [2-1]:

$$\vert LUMO ( H 1 ) - LUMO ( H 2 ) \vert \leq 0.1 eV \qquad [ 1 ]$$

$$HOMO ( H 2 ) - HOMO ( H 1 ) > 0. eV \qquad [ 2 - 1 ]$$

where, in the formulae [1] and [2-1], LUMO(H1) represents the LUMO energy level of the first organic compound, LUMO(H2) represents the LUMO energy level of the second organic compound, HOMO(H1) represents the HOMO energy level of the first organic compound, and HOMO(H2) represents the HOMO energy level of the second organic compound.

According to another aspect of the present disclosure, there is provided an organic light-emitting device including, in this order, a first electrode, a first light-emitting unit, a charge generation region, a second light-emitting unit, and a second electrode. The charge generation region includes at least one n-type charge generation layer. The at least one n-type charge generation layer contains at least a first organic compound and a second organic compound. The first organic compound is a nitrogen-containing aromatic compound. The second organic compound is represented by the following General Formula [I] or [II]:

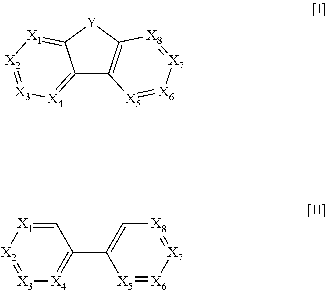

where, in General Formulae [I] and [II], X₁ to X₈ each represent a carbon atom having a substituent R or a nitrogen atom. Y in General Formula [I] represents a carbon atom having substituents R₁ and R₂, or any of an oxygen atom, a sulfur atom, a selenium atom, and a tellurium atom. When Y in General Formula [I] represents a carbon atom having substituents R₁ and R₂, at least one of X₁ to X₈ represents a nitrogen atom. When the second organic compound is represented by General Formula [II], at least one of X₁ to X₈ represents a nitrogen atom. R, R₁, and R₂ are each selected from a hydrogen atom, a deuterium atom, a halogen atom, a substituted or unsubstituted alkyl group, a substituted or unsubstituted aryl group, a substituted or unsubstituted heterocyclic group, a substituted or unsubstituted amino group, a substituted or unsubstituted silyl group, a substituted or unsubstituted alkoxy group, and a cyano group. In General Formulae [I] and [II], when, among X₁ to X₈, carbon atoms each having a substituent R are adjacent to each other and the substituent R has a carbon atom, the adjacent substituents R may be taken together to form a ring. In General Formula [I], when R₁ and R₂ each have a carbon atom, the adjacent substituents R₁ and R₂ may be taken together to form a ring.

Features of the present disclosure will become apparent from the following description of embodiments with reference to the attached drawings.

### BRIEF DESCRIPTION OF THE DRAWINGS

FIG. 1 is a schematic cross-sectional view illustrating an example of an organic light-emitting device according to an embodiment of the present disclosure.

FIG. 2A is a schematic cross-sectional view illustrating an example of a pixel of a display apparatus according to an embodiment of the present disclosure.

FIG. 2B is a schematic cross-sectional view of an example of a display apparatus including organic light-emitting devices according to an embodiment of the present disclosure.

FIG. 3 is a schematic view of an example of a display apparatus according to an embodiment of the present disclosure.

FIG. 4A is a schematic view of an example of an image pickup apparatus according to an embodiment of the present disclosure.

FIG. 4B is a schematic view of an example of an electronic apparatus according to an embodiment of the present disclosure.

FIG. 5A is a schematic view of an example of a display apparatus according to an embodiment of the present disclosure.

FIG. 5B is a schematic view of an example of a foldable display apparatus according to an embodiment of the present disclosure.

FIG. 6A is a schematic view of an example of a lighting apparatus according to an embodiment of the present disclosure.

FIG. 6B is a schematic view of an example of an automobile including an automotive lighting unit according to an embodiment of the present disclosure.

FIG. 7A is a schematic view illustrating an example of a wearable device according to an embodiment of the present disclosure.

FIG. 7B is a schematic view of an example of a wearable device according to an embodiment of the present disclosure, the wearable device including an image pickup apparatus.

FIG. 8A is a schematic view of an example of an image-forming apparatus according to an embodiment of the present disclosure.

FIG. 8B is a schematic view of an example of an exposure light source of an image-forming apparatus according to an embodiment of the present disclosure.

FIG. 8C is a schematic view of an example of an exposure light source of an image-forming apparatus according to an embodiment of the present disclosure.

### DESCRIPTION OF THE EMBODIMENTS

### First Organic Light-Emitting Device

An organic light-emitting device according to a first embodiment of the present disclosure includes, in this order, a first electrode, a first light-emitting unit, a charge generation region, a second light-emitting unit, and a second electrode. The charge generation region includes at least one n-type charge generation layer. The at least one n-type charge generation layer contains at least a first organic compound and a second organic compound. The first organic compound and the second organic compound satisfy the following formulae [1] and [2-1]:

$$\vert LUMO ( H 1 ) - LUMO ( H 2 ) \vert \leq 0.1 eV \qquad [ 1 ]$$

$$HOMO ( H 2 ) - HOMO ( H 1 ) > 0. eV \qquad [ 2 - 1 ]$$

where LUMO(H1) represents the LUMO energy level of the first organic compound,
LUMO(H2) represents the LUMO energy level of the second organic compound,
HOMO(H1) represents the HOMO energy level of the first organic compound, and
HOMO(H2) represents the HOMO energy level of the second organic compound.

The term “HOMO” refers to the “highest occupied molecular orbital”. The term “LUMO” refers to the “lowest unoccupied molecular orbital”. The energy level of the HOMO is also referred to as “the HOMO” or “the HOMO level”. The energy level of the LUMO is also referred to as “the LUMO” or “the LUMO level”. The unit is “eV”.

The organic light-emitting device according to the present embodiment may include a third light-emitting unit in addition to the first light-emitting unit and the second light-emitting unit. The third light-emitting unit may be disposed between the first electrode and the first light-emitting unit, between the first light-emitting unit and the second light-emitting unit, or between the second light-emitting unit and the second electrode.

In the organic light-emitting device according to the present embodiment, the first electrode may be an anode, and the second electrode may be a cathode.

The organic light-emitting device according to the present embodiment may have a device configuration that can emit white light. Specifically, the first light-emitting unit may emit red and green light, and the second light-emitting unit may emit blue light. The first light-emitting unit, the second light-emitting unit, and the third light-emitting unit may emit red, green, and blue light, respectively.

The organic light-emitting device according to the present embodiment may have a device configuration that can emit light other than white light. Specifically, the first light-emitting unit and the second light-emitting unit may emit light of the same color With such a device configuration, an organic light-emitting device with improved luminance can be produced.

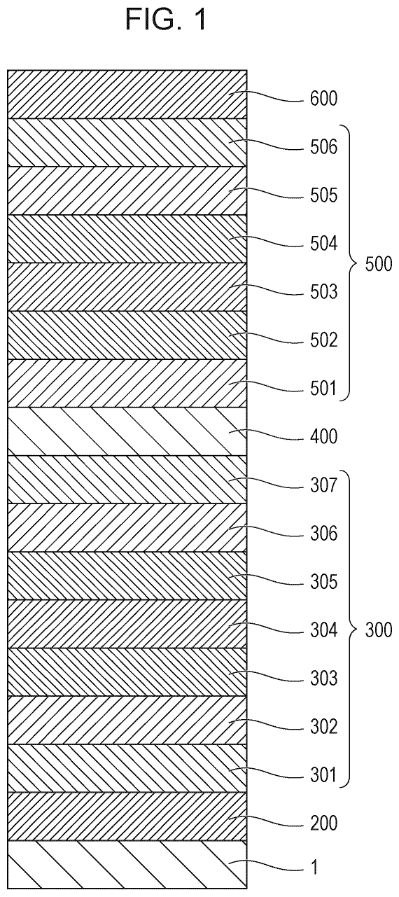

An embodiment of the present disclosure will be described in more detail below with reference to FIG. 1.

FIG. 1 is a schematic cross-sectional view of an organic light-emitting device according to an embodiment of the present disclosure. A first electrode 200, a first light-emitting unit 300, a charge generation region 400, a second light-emitting unit 500, and a second electrode 600 are stacked in this order over a substrate 1.

In the organic light-emitting device according to the present embodiment, the first light-emitting unit 300 includes a first light-emitting layer 304. The first light-emitting layer 304 contains at least a third organic compound and a first light-emitting compound. The first light-emitting layer 304 may contain a fourth organic compound, as needed. The first light-emitting unit 300 may include other layers, as needed. In the organic light-emitting device according to the present embodiment, the first light-emitting unit 300 may specifically include a first hole injection layer 301, a first hole transport layer 302, a first electron-blocking layer 303, a first light-emitting layer 304, a first hole-blocking layer 305, a first electron transport layer 306, and a first electron injection layer 307.

In the organic light-emitting device according to the present embodiment, the second light-emitting unit 500 includes a second light-emitting layer 503. The second light-emitting layer 503 contains a fifth organic compound and at least a second light-emitting compound, and may contain a sixth organic compound and a third light-emitting compound, as needed. The second light-emitting unit 500 may include other layers, as needed. Specifically, the second light-emitting unit 500 may include a second hole transport layer 501, a second electron-blocking layer 502, a second light-emitting layer 503, a second hole-blocking layer 504, a second electron transport layer 505, and a second electron injection layer 506.

In the organic light-emitting device according to the present embodiment, the charge generation region 400 includes at least one n-type charge generation layer. The charge generation region 400 serves to inject electrons into the first light-emitting unit. Therefore, the organic light-emitting device according to the present embodiment does not necessarily have to include the first electron injection layer 307. When the first electron injection layer 307 is not provided, the driving voltage of the organic light-emitting device according to the present embodiment can be reduced.

When the organic light-emitting device according to the present embodiment includes the first electron injection layer 307, it is preferable that the first electron injection layer 307 be provided adjacent to the n-type charge generation layer, and that the n-type charge generation layer and the first electron injection layer 307 contain a common material. In this case, the adhesion between the n-type charge generation layer and the first electron injection layer 307 is increased, so that the function as an electron injection layer can be further improved.

The third organic compound contained in the first light-emitting layer 304 and the fifth organic compound contained in the second light-emitting layer 503 are host compounds. The fourth organic compound contained in the first light-emitting layer 304 and the sixth organic compound contained in the second light-emitting layer 503 are assist compounds. The first light-emitting compound contained in the first light-emitting layer 304 and the second and third light-emitting compounds contained in the second light-emitting layer 503 are guest compounds.

The term “host compound” used here refers to a compound having the highest proportion by mass in compounds contained in the light-emitting layer. The term “guest compound” refers to a compound that has a lower proportion by mass than the host compound in the compounds contained in the light-emitting layer and that is responsible for main light emission. The term “assist compound” is a compound that has a lower proportion by mass than the host compound in the compounds contained in each light-emitting layer and that assists the light emission of the guest compound. The assist compound is also referred to as a “second host compound”.

Specific configurations of the charge generation region 400 according to the present embodiment are described below, but the present disclosure is not limited thereto.
(i) n-type charge generation layer/hole injection layer
(ii) n-type charge generation layer/p-type charge generation layer
(iii) n-type charge generation layer/connection layer/hole injection layer
(iv) n-type charge generation layer/connection layer/p-type charge generation layer

In the organic light-emitting device according to the present embodiment, the n-type charge generation layer is a mixed layer containing the first organic compound and the second organic compound. The n-type charge generation layer may contain alkali metal atoms, alkaline-earth metal atoms, or an organic compound with high electron-donating properties, typified by a compound having an imidazolidine skeleton, and preferably contains alkali metal atoms or alkaline-earth metal atoms. The p-type charge generation layer may be a mixed layer containing a hole-transporting compound and an electron-accepting compound. The hole injection layer may be a layer containing an electron-accepting compound or a metal oxide. The connection layer may be a layer containing an electron-transporting compound or a hole-transporting compound.

Examples of an alkali metal atom include, but are not limited to, a lithium atom, a sodium atom, a potassium atom, a rubidium atom, and a cesium atom. Among these, a lithium atom or a cesium atom is preferred.

Examples of an alkaline-earth metal atom include, but are not limited to, a beryllium atom, a magnesium atom, a calcium atom, and a strontium atom.

The first organic compound is, for example, a nitrogen-containing aromatic compound. Specific examples thereof include a phenanthrolinyl group, an oxazolyl group, an oxadiazolyl group, a diazolyl group, a thiadiazolyl group, a triazolyl group, a naphthyridinyl group, and derivatives thereof. Among these, the first organic compound is preferably a phenanthroline derivative or a naphthyridine derivative. Phenanthroline derivatives and naphthyridine derivatives have particularly strong interactions with alkali metals and are therefore particularly preferred as materials for the n-type charge generation layer.

As the second organic compound, an aromatic hydrocarbon compound or an aromatic heterocyclic compound is preferably used.

The configuration of the first organic light-emitting device according to the present disclosure has the following features.

(1-1) The first organic compound and the second organic compound of the n-type charge generation layer satisfy the relationship of the following formula [1]:

$$\vert LUMO ( H 2 ) - LUMO ( H 1 ) \vert \leq 0.1 eV . \qquad [ 1 ]$$

In the organic light-emitting device according to the present embodiment, the electron mobility in the n-type charge generation layer can be improved by satisfying the relationship of the above formula [1]. Therefore, the driving voltage of the organic light-emitting device according to the present embodiment is further reduced.

Table 1 below presents a comparison of the driving voltage and durability of the organic light-emitting devices of Examples 1, 2, and 9 and Comparative Example 1, which will be described below. As presented in Table 1, the entries labeled “No.” in the columns for the first organic compound and the second organic compound correspond to the respective exemplified compound numbers described below. The ΔHOMO and ΔLUMO are defined by the following equations. The driving-voltage ratio and durability ratio are relative values, with the driving voltage and durability of the device in Comparative Example 1 each set to 1.0.

$$Δ HOMO = HOMO ( H 2 ) - HOMO ( H 1 ) \\ Δ LUMO = \vert LUMO ( H 1 ) - LUMO ( H 2 ) \vert$$

The entry “1-a” in Table 1 is as follows.

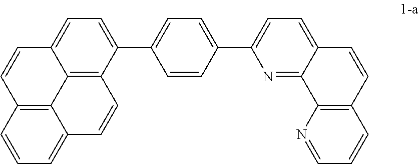 [SMILES: c1cnc2c(c1)ccc1ccc(-c3ccc(-c4ccc5ccc6cccc7ccc4c5c67)cc3)nc12]

TABLE 1

| | | | Second | | | | | | |
|---|---|---|---|---|---|---|---|---|---|
| | First organic | | organic | | | | | | |
| | compound | | compound | | Alkali | | | Driving | |
| | | LUMO | | LUMO | metal | | | voltage | Durability |
| | No. | HOMO | No. | HOMO | atom | ΔLUMO | ΔHOMO | ratio | ratio |
| Example 1 | ET1 | −3.1 | B3 | −3.0 | Cs | 0.1 | 0.1 | 0.9 | 1.1 |
| | | −6.6 | | −6.5 | | | | | |
| Example 2 | ET1 | −3.1 | A6 | −3.1 | Cs | 0.0 | 0.7 | 0.7 | 1.4 |
| | | −6.6 | | −5.9 | | | | | |
| Example 9 | ET1 | −3.1 | F10 | −3.1 | Cs | 0.0 | 0.6 | 0.8 | 1.3 |
| | | −6.6 | | −6.0 | | | | | |
| Comparative | ET1 | −3.1 | 1-a | −2.9 | Cs | 0.2 | 0.5 | 1.0 | 1.0 |
| Example 1 | | −6.6 | | −6.1 | | | | | |

As described above, the n-type charge generation layer serves to inject electrons into, and transport electrons to, the light-emitting layer. More specifically, a nitrogen-containing aromatic compound typified by ET1 (BPhen), which is used as the first organic compound, interacts with alkali metal atoms or alkaline-earth metal atoms, thereby exhibiting electron-injection properties and serving to transport electrons in the n-type charge generation layer.

When the difference in LUMO levels between the first organic compound and the second organic compound is large, electron trap levels are formed, thereby potentially decreasing the electron mobility in the n-type charge generation layer. This may result in an increase in the driving voltage of the organic light-emitting device. Accordingly, in the organic light-emitting device according to the present embodiment, the difference in LUMO levels between the first organic compound and the second organic compound is preferably small. In other words, the first organic compound and the second organic compound preferably satisfy the relationship represented by Formula [1].

When the first organic compound and the second organic compound satisfy the relationship represented by Formula [1], the n-type charge generation layer is less likely to trap electrons, thereby improving the electron mobility in the n-type charge generation layer. Thus, the driving voltage of the organic light-emitting device according to the present embodiment is further reduced.

The difference between the absolute value of LUMO(H1) and the absolute value of LUMO(H2) may be less than 0.1 eV This is because, within this range, the difference in LUMO levels between the first organic compound and the second organic compound is almost negligible, so that neither of them exhibits electron-trapping properties with respect to the other.

(1-2) The first organic compound and the second organic compound in the n-type charge generation layer satisfy the relationships represented by Formula [1] and Formula [2-1]:

$$HOMO ( H 2 ) - HOMO ( H 1 ) > 0. eV . \qquad [ 2 - 1 ]$$

In the n-type charge generation layer, the first organic compound exhibits electron-injection properties and is also responsible for electron transport, and is therefore unstable to holes. The second organic compounds described in Table 1 are each designed to have a higher HOMO level (closer to the vacuum level) than ET1 used as the first organic compound so as to also satisfy the relationship represented by Formula [2-1]. Accordingly, each second organic compound is configured to trap holes, thereby making it possible to inhibit degradation of the first organic compound due to holes, inhibit degradation of the n-type charge generation layer as a whole, and thus inhibit luminance degradation of the organic light-emitting device.

In the organic light-emitting device according to an embodiment of the present disclosure, the relationships represented by Formula [1] and the following Formula [2-2] are preferably satisfied.

$$HOMO ( H 2 ) - HOMO ( H 1 ) \geq 0.2 eV \qquad [ 2 - 2 ]$$

As described in Examples 2 and 9 in Table 1, the durability characteristics are further improved by enhancing the hole-trapping properties due to the second organic compound in the n-type charge generation layer. When the charge generation region is provided with a p-type charge generation layer, the p-type charge generation layer may be a mixed layer containing a hole-transporting compound and an electron-accepting compound. The electron-accepting compound serves to extract electrons from the hole-transporting compound, but has an unstable nature with respect to holes, which carry the opposite charge. When the above formula [2-2] is satisfied, degradation of the first organic compound is inhibited, and the n-type charge generation layer has a hole-trap configuration, which makes it difficult for holes to reach the p-type charge generation layer, thereby inhibiting degradation of the organic light-emitting device.

As described above, when the relationships represented by Formula [1] and Formula [2-1] are satisfied, and preferably when the relationships represented by Formula [1] and Formula [2-2] are satisfied, the n-type charge generation layer exhibits both electron-transport properties and hole-trapping properties, and, as presented in Table 1, a lower driving voltage and improved durability of the organic light-emitting device are achieved.

The organic light-emitting device according to an embodiment of the present disclosure preferably has the following configuration (1-3).

(1-3) The first light-emitting unit has the first light-emitting layer, the first light-emitting layer contains at least the third organic compound and the first light-emitting compound, and the third organic compound and the first light-emitting compound satisfy the relationship represented by the following Formula [3].

$$LUMO ( H 3 ) - LUMO ( D 1 ) > HOMO ( D 1 ) - HOMO ( D 3 ) \qquad [ 3 ]$$

where LUMO(H3) represents the LUMO energy level of the third organic compound,
LUMO(D1) represents the LUMO energy level of the first light-emitting compound,
HOMO(H3) represents the HOMO energy level of the third organic compound, and
HOMO(D1) represents the HOMO energy level of the first light-emitting compound.

Formula [3] indicates that the first light-emitting layer is an electron-trap type. When holes are excessive in the emitting layer, excitons generated in the light-emitting layer tend to undergo a degradation mode that proceeds via a cationic state. For this reason, a configuration that does not trap holes in the light-emitting layer of the first light-emitting unit, i.e., an electron-trap configuration, is particularly preferred in an embodiment of the present disclosure. In other words, it is more preferable for the holes not to be trapped in the light-emitting layer but to be trapped in another layer.

In the first light-emitting layer, the relationship represented by the following Formula [4] is satisfied:

$$LUMO ( H 3 ) - LUMO ( D 1 ) \geq 0.1 e V . \qquad [ 4 ]$$

Formula [4] indicates that the LUMO level difference in the first light-emitting layer is sufficient, and sufficient electron-trapping properties are exhibited.

It is preferable that the first light-emitting layer further contain the fourth organic compound and that the third organic compound and the fourth organic compound satisfy the relationship represented by the following Formula [5]:

$$HOMO ( H 4 ) - HOMO ( H 3 ) \geq 0.1 eV \qquad [ 5 ]$$

where HOMO (H4) represents the HOMO energy level of the fourth organic compound.

Formula [5] indicates that the fourth organic compound traps holes. When such an organic compound is introduced into the light-emitting layer as an assist material, the light-emitting layer can trap both electrons and holes. This can inhibit hole leakage into the n-type charge generation layer, thereby improving the durability of the organic light-emitting device.

As described above, in an embodiment of the present disclosure, the configuration is such that holes are likely to leak from the light-emitting layer, and therefore it is preferable to trap holes in another layer. In particular, as described in (1-2) above, when the first organic compound and the second organic compound in the n-type charge generation layer satisfy the relationship represented by Formula [2-1], holes can be trapped within the n-type charge generation layer.

In the present specification, the HOMO and LUMO levels are described as being “higher” when they are closer to the vacuum level, and “lower” when they are further from the vacuum level. The fact that the LUMO of the charge generation layer is lower than the HOMO of the hole transport layer indicates that the LUMO of the charge generation layer is further from the vacuum level than the HOMO of the hole transport layer.

The HOMO and LUMO can be calculated using molecular orbital calculations. The molecular orbital calculations may be performed using density functional theory (DFT) or the like, and a functional, such as B3LYP, and a basis set, such as 6-31G*, may be used. The molecular orbital calculations can be carried out, for example, using Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010).

The HOMO and LUMO can also be calculated using the ionization potential and the band gap. The HOMO can be estimated by measuring the ionization potential. The ionization potential can be determined by depositing a compound to be measured on a substrate, such as glass, to form a deposited film and measuring the resulting deposited film using a measuring apparatus, such as an AC-3. The band gap can be measured by dissolving the compound to be measured in a solvent, such as toluene, and irradiating the solution with excitation light. The band gap can be determined by measuring the absorption edge of the absorption spectrum of the excitation light absorbed by the solution. Alternatively, the compound to be measured can be vapor-deposited on a substrate, such as glass, to form a vapor-deposited film, and the band gap can be measured by irradiating the vapor-deposited film with excitation light. In this case, the band gap can be determined by measuring the absorption edge of the absorption spectrum of the excitation light absorbed by the vapor-deposited film.

The LUMO can be calculated using the values of the band gap and the ionization potential. The LUMO can be estimated by adding the band gap value to the ionization potential.

The LUMO can also be estimated from the reduction potential. For example, a one-electron reduction potential is estimated using cyclic voltammetry (CV) measurement. The CV measurement can be performed, for example, in a 0.1 M tetrabutylammonium perchlorate solution in N,N-dimethylformamide (DMF), using an Ag/Ag⁺ reference electrode, a Pt counter electrode, and a glassy carbon working electrode. The LUMO can be estimated by subtracting, from 4.8 eV, which is the ionization potential of ferrocene, the difference between the reduction potential of the compound obtained and the reduction potential of ferrocene.

In an embodiment of the present disclosure, the ionization potential and the band gap of the above-described vapor-deposited film are measured, the HOMO is estimated from the obtained ionization potential, and the LUMO is calculated by adding the band gap to the ionization potential.

The durability of an organic light-emitting device can be evaluated based on the time it takes for the luminance to deteriorate. The durability can be regarded as better when the time required for the luminance to decrease from an initial luminance to a predetermined luminance is longer.

### Second Organic Light-Emitting Device

An organic light-emitting device according to a second embodiment of the present disclosure includes, in this order, a first electrode, a first light-emitting unit, a charge generation region, a second light-emitting unit, and a second electrode, in which the charge generation region includes at least one n-type charge generation layer.

(2-1) In the organic light-emitting device according to the present embodiment, the n-type charge generation layer contains at least the first organic compound and the second organic compound, the first organic compound is a nitrogen-containing aromatic compound, and the second organic compound is represented by the following General Formula [I] or [II].

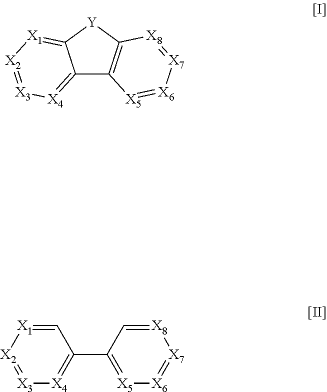

In General Formulae [I] and [II], X₁ to X₈ each represent a carbon atom having a substituent R or a nitrogen atom.

Y in General Formula [I] represents a carbon atom having substituents R₁ and R₂, or any of an oxygen atom, a sulfur atom, a selenium atom, and a tellurium atom.

When Y in General Formula [I] represents a carbon atom having substituents R₁ and R₂, at least one of X₁ to X₈ represents a nitrogen atom. When the second organic compound is represented by General Formula [II], at least one of X₁ to X₈ represents a nitrogen atom.

R, R₁, and R₂ are each selected from a hydrogen atom, a deuterium atom, a halogen atom, a substituted or unsubstituted alkyl group, a substituted or unsubstituted aryl group, a substituted or unsubstituted heterocyclic group, a substituted or unsubstituted amino group, a substituted or unsubstituted silyl group, a substituted or unsubstituted alkoxy group, and a cyano group. In General Formulae [I] and [II], when, among X₁ to X₈, carbon atoms each having a substituent R are adjacent to each other and each substituent R has a carbon atom, the adjacent substituents R may be taken together to form a ring. In General Formula [I], when R₁ and R₂ each have a carbon atom, the adjacent substituents R₁ and R₂ may be taken together to form a ring.

In the present embodiment, the n-type charge generation layer may contain an organic compound having high electron-donating properties, typified by a compound having an imidazoline skeleton, alkali metal atoms, or alkaline earth metal atoms. The n-type charge generation layer preferably contains alkali metal atoms or alkaline-earth metal atoms. When the second organic compound in the n-type charge generation layer is an organic compound represented by General Formula [I] or [II], diffusion of the alkali metal atoms or alkaline-earth metal atoms contained in the n-type charge generation layer into the light-emitting layer or the p-type charge generation layer can be inhibited, thereby inhibiting deterioration of the organic light-emitting device.

Examples of elements that exhibit electron-injection properties include alkali metal atoms and alkaline-earth metal atoms. When a layer containing these atoms and a phenanthroline derivative or a naphthyridine derivative is formed for the purpose of improving the electron-injection properties, the durability of the organic light-emitting device may deteriorate. Phenanthroline derivatives and naphthyridine derivatives easily form chelate structures with alkali metal atoms or alkaline-earth metal atoms, thereby improving the electron-injection properties. However, when a voltage equal to or higher than a certain level is applied, alkali metal atoms or alkaline-earth metal atoms move between these derivative molecules via the chelate structure and diffuse into the light-emitting layer. As a result, the alkali metal atoms or alkaline-earth metal atoms may function as a quenching component (quencher) for the light-emitting material, thereby leading to a rapid decrease in luminance.

In addition, a complex having the chelate structure formed of the above derivative and alkali metal atoms or alkaline-earth metal atoms transports electrons toward the anode side, and at the same time, positively charged alkali metal ions or alkaline-earth metal ions are coordinated to the complex. These positively charged metal ionic species diffuse into the p-type charge generation layer as a driving voltage is applied. As a result, the function of the p-type charge generation layer deteriorates, thereby leading to an increase in driving voltage.

The organic compound represented by General Formula [I] or [II] has two nitrogen atoms separated by a large spatial distance compared with the above derivatives, thereby making it difficult to form a chelate structure with alkali metal atoms or their ions or alkaline-earth metal atoms or their ions. Specifically, as illustrated below, the phenanthroline skeleton and the naphthyridine skeleton have a small N-N spatial distance, that is, a small bond angle, and therefore readily form chelate structures. In contrast, the organic compound represented by General Formula [I] or [II] has a large spatial distance between N-N atoms, making it difficult to form a chelate structure.

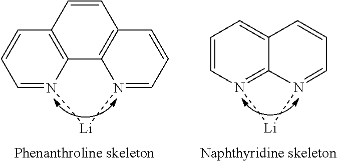

### Compound Represented by General Formula [I]

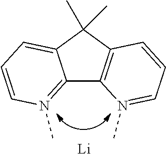

### Compound Represented by General Formula [II]

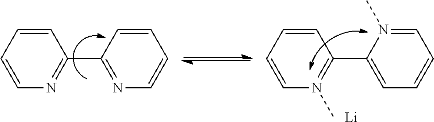

Accordingly, when an organic compound represented by General Formula [I] or [II] is incorporated as the second organic compound in the n-type charge generation layer, it is possible to reduce the diffusion of alkali metal atoms or alkaline-earth metal atoms into the light-emitting layer via the phenanthroline derivative. When the charge generation region includes a p-type charge generation layer, diffusion of alkali metal ions or alkaline-earth metal ions into the p-type charge generation layer can be inhibited. As a result, it is possible to provide an organic light-emitting device that has excellent durability and in which an increase in driving voltage is inhibited.

In the present embodiment, the second organic compound is preferably represented by the following General Formula [III].

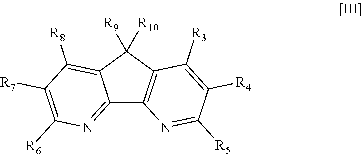

In General Formula [III], substituents R₃ to R₁₀ are each independently selected from the group consisting of a hydrogen atom, a deuterium atom, a substituted or unsubstituted alkyl group, a substituted or unsubstituted aryl group, and a substituted or unsubstituted heterocyclic group.

When adjacent substituents among R₃ to R₁₀ each have a carbon atom, the adjacent substituents may be taken together to form a ring.

The second organic compound is preferably represented by the following General Formula [IV].

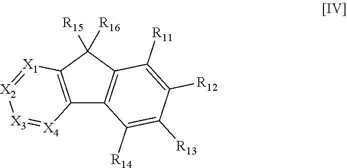

In General Formula [IV], X₁ to X₄ each represent a carbon atom having a substituent R or a nitrogen atom, and at least one of X₁ to X₄ represents a nitrogen atom.

R and R₁₁ to R₁₆ are each independently selected from the group consisting of a hydrogen atom, a deuterium atom, a substituted or unsubstituted alkyl group, a substituted or unsubstituted aryl group, and a substituted or unsubstituted heterocyclic group.

When adjacent substituents among R₁₁ to R₁₆ each have a carbon atom, the adjacent substituents may be taken together to form a ring.

The second organic compound is preferably represented by the following General Formula [V].

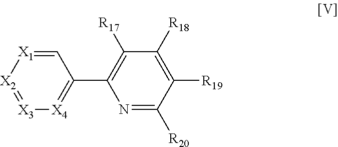

In General Formula [V], X₁ to X₄ each represent a carbon atom having a substituent R or a nitrogen atom, and at least one of X₁ to X₄ represents a nitrogen atom.

R and R₁₇ to R₂₀ are each independently selected from the group consisting of a hydrogen atom, a deuterium atom, a substituted or unsubstituted alkyl group, a substituted or unsubstituted aryl group, and a substituted or unsubstituted heterocyclic group.

When adjacent substituents among R₁₇ to R₂₀ each have a carbon atom, the adjacent substituents may be taken together to form a ring.

The second organic compound is preferably represented by the following General Formula [VI].

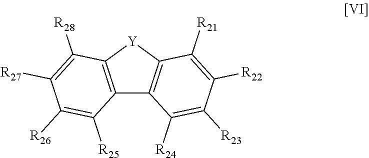

In General Formula [VI], Y represents an oxygen atom, a sulfur atom, a selenium atom, or a tellurium atom.

R₂₁ to R₂₈ are each independently selected from the group consisting of a hydrogen atom, a deuterium atom, a substituted or unsubstituted alkyl group, a substituted or unsubstituted aryl group, and a substituted or unsubstituted heterocyclic group.

When adjacent substituents among R₂₁ to R₂₈ each have a carbon atom, the adjacent substituents may be taken together to form a ring.

The elements and substituents given as X₁ to X₈, R, and R₁ to R₂₈ in General Formulae [I] to [VI] will be described below.

In the present specification, examples of a halogen atom include, but are not limited to, a fluorine atom, a chlorine atom, a bromine atom, and an iodine atom. Among these, a fluorine atom is preferred.

The alkyl group may be an alkyl group having 1 or more and 20 or less carbon atoms. Specific examples thereof include, but are not limited to, a methyl group, an ethyl group, a n-propyl group, an isopropyl group, a n-butyl group, an isobutyl group, a sec-butyl group, a tert-butyl group, a n-pentyl group, an isopentyl group, a tert-pentyl group, a neopentyl group, a n-hexyl group, an octyl group, a cyclohexyl group, a 1-adamantyl group, and a 2-adamantyl group. The alkyl group preferably has 1 or more and 10 or less carbon atoms, more preferably 1 or more and 6 or less carbon atoms. Specifically, a methyl group or a tert-butyl group is preferred.

The alkoxy group may be an alkoxy group having 1 or more and 10 or less carbon atoms. Specific examples thereof include, but are not limited to, a methoxy group, an ethoxy group, an n-propoxy group, an isopropoxy group, an n-butoxy group, a tert-butoxy group, a 2-ethyloctyloxy group, and a benzyloxy group. The alkoxy group preferably has 1 or more and 4 or less carbon atoms. Specifically, a methoxy group is preferred.

The aryl group may be an aryl group having 6 or more and 30 or less carbon atoms. Specific examples thereof include, but are not limited to, a phenyl group, a naphthyl group, a phenanthryl group, an anthryl group, a fluorenyl group, a biphenylenyl group, an acenaphthylenyl group, a chrysenyl group, a pyrenyl group, a triphenylenyl group, a picenyl group, a fluoranthenyl group, a perylenyl group, a naphthacenyl group, a terphenyl group, and a biphenyl group.

The heterocyclic group may be a heterocyclic group having 3 or more and 27 or less carbon atoms. Specific examples thereof include, but are not limited to, a thienyl group, a pyrrolyl group, a pyrazinyl group, a pyridyl group, an indolyl group, a quinolyl group, an isoquinolyl group, a naphthyridinyl group, an acridinyl group, a phenanthrolinyl group, a carbazolyl group, a benzo[a]carbazolyl group, a benzo[b]carbazolyl group, a benzo[c]carbazolyl group, a phenazinyl group, a phenoxazinyl group, a phenothiazinyl group, a benzothiophenyl group, a dibenzothiophenyl group, a benzofuranyl group, a dibenzofuranyl group, an oxazolyl group, and an oxadiazolyl group.

Specific examples of a silyl group include, but are not limited to, a trimethylsilyl group and a triphenylsilyl group.

Specific examples of an amino group include, but are not limited to, an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisolylamino group, an N-mesityl-N-phenylamino group, an N,N-dimesitylamino group, an N-phenyl-N-(4-tert-butylphenyl)amino group, and an N-phenyl-N-(4-trifluoromethylphenyl)amino group. The amino group is preferably an N,N-dimethylamino group or an N,N-diphenylamino group.

Examples of substituents that may be further contained in the alkyl group, the alkoxy group, the aryl group, the heterocyclic group, the silyl group, and the amino group include, but are not limited to, alkyl groups, such as a methyl group, an ethyl group, a n-propyl group, an isopropyl group, a n-butyl group, an isobutyl group, a sec-butyl group, a tert-butyl group, a n-pentyl group, an isopentyl group, a tert-pentyl group, a neopentyl group, a n-hexyl group, and a cyclohexyl group; alkoxy groups, such as a methoxy group, an ethoxy group, an isopropoxy group, a n-butoxy group, and a tert-butoxy group; substituted amino groups, such as an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisolylamino group, an N-mesityl-N-phenylamino group, an N,N-dimesitylamino group, an N-phenyl-N-(4-tert-butylphenyl)amino group, and an N-phenyl-N-(4-trifluoromethylphenyl)amino group; aryl groups, such as a phenyl group, a naphthyl group, a phenanthryl group, an anthryl group, a fluorenyl group, a biphenylenyl group, an acenaphthylenyl group, a chrysenyl group, a pyrenyl group, a triphenylenyl group, a picenyl group, a fluoranthenyl group, a perylenyl group, a naphthacenyl group, a biphenyl group, and a terphenyl group; heteroaryl groups, such as a thienyl group, a pyrrolyl group, a pyrazinyl group, a pyridyl group, an indolyl group, a quinolyl group, an isoquinolyl group, a naphthyridinyl group, an acridinyl group, a phenanthrolinyl group, a carbazolyl group, a benzo[a]carbazolyl group, a benzo[b]carbazolyl group, a benzo[c]carbazolyl group, a phenazinyl group, a phenoxazinyl group, a phenothiazinyl group, a benzothiophenyl group, a dibenzothiophenyl group, a benzofuranyl group, a dibenzofuranyl group, an oxazolyl group, and an oxadiazolyl group; a cyano group; and a trifluoromethyl group.

For the second organic light-emitting device according to an embodiment of the present disclosure, the following configurations (2-2) to (2-6) described below are preferred.

(2-2) An electron transport layer is provided on the anode side of the n-type charge generation layer and is adjacent to the n-type charge generation layer, and the electron transport layer contains an organic compound represented by general formula [I] or [II].

Table 2 compares the driving voltage and durability of the organic light-emitting devices of Examples 18 to 23 and Comparative Example 3 described below. In the table, the entries labeled “No.” in the columns for the electron transport layer, the first organic compound, and the second organic compound correspond to the respective exemplified compound numbers described below. The ΔHOMO and ΔLUMO are defined by the following equations. The driving-voltage ratio and durability ratio are relative values, with the driving voltage and durability of the device in Comparative Example 1 each set to 1.0.

$$Δ HOMO = HOMO ( H 2 ) - HOMO ( H 1 ) \\ Δ LUMO = \vert LUMO ( H 1 ) - LUMO ( H 2 ) \vert$$

TABLE 2

| | | | | | Second | | | | | | |
|---|---|---|---|---|---|---|---|---|---|---|---|
| | First electron | | First organic | | organic | | | | | | |
| | transport layer | | compound | | compound | | Alkali | | | Driving | |
| | | LUMO | | LUMO | | LUMO | metal | | | voltage | Durability |
| | No. | HOMO | No. | HOMO | No. | HOMO | atom | ΔLUMO | ΔHOMO | ratio | ratio |
| Example 18 | 1-a | −2.9 | ET1 | −3.1 | AA6 | −3.0 | Li | 0.1 | 0.5 | 0.9 | 1.1 |
| | | −6.1 | | −6.6 | | −6.1 | | | | | |
| Example 19 | AA6 | −3.1 | ET1 | −3.1 | AA6 | −3.0 | Li | 0.1 | 0.5 | 0.9 | 1.2 |
| | | −6.1 | | −6.6 | | −6.1 | | | | | |
| Example 20 | 1-a | −2.9 | ET1 | −3.1 | CC21 | −3.2 | Li | 0.1 | 0.4 | 0.9 | 1.1 |
| | | −6.1 | | −6.6 | | −6.2 | | | | | |
| Example 21 | CC21 | −3.0 | ET1 | −3.1 | CC21 | −3.2 | Li | 0.1 | 0.4 | 0.9 | 1.2 |
| | | −6.1 | | −6.6 | | −6.2 | | | | | |
| Example 22 | 1-a | −3.0 | ET1 | −3.1 | DD6 | −3.1 | Li | 0.0 | 0.6 | 0.8 | 1.2 |
| | | −6.0 | | −6.6 | | −6.0 | | | | | |
| Example 23 | DD6 | −2.9 | ET1 | −3.1 | DD6 | −3.1 | Li | 0.0 | 0.6 | 0.8 | 1.3 |
| | | −6.1 | | −6.6 | | −6.0 | | | | | |
| Comparative | 1-a | −2.9 | ET1 | −3.1 | 1−a | −2.9 | Li | 0.2 | 0.5 | 1.0 | 1.0 |
| Example 3 | | −6.1 | | −6.6 | | −6.1 | | | | | |

It can be seen that the device lifetime is further improved when the material used for the electron transport layer is changed to an organic compound represented by General Formula [I] or [II]. The reason for this is as follows: When the organic compound represented by General Formula [I] or [II] is incorporated not only in the n-type charge generation layer but also in the electron transport layer, the diffusion of alkali metal atoms into the light-emitting layer is inhibited, and the quenching of the light-emitting material by the alkali metal atoms is inhibited, thereby improving the durability of the organic light-emitting device.

(2-3) The second organic compound in the n-type charge generation layer is identical to the organic compound represented by General Formula [I] or [II] used in the electron transport layer that is disposed on the anode side and that is adjacent to the n-type charge generation layer.

When the second organic compound in the n-type charge generation layer is identical to the compound used in the electron transport layer that is disposed on the anode side and that is adjacent to the n-type charge generation layer, the injection barrier from the n-type charge generation layer to the electron transport layer can be eliminated, thereby facilitating the injection and transport of electrons into the electron transport layer.

(2-4) The first organic compound and the second organic compound in the n-type charge generation layer satisfy the relationship represented by the following Formula [1].

$$\vert LUMO ( H 1 ) - LUMO ( H 2 ) \vert \leq 0.1 eV \qquad [ 1 ]$$

Formula [1] described above is the same as Formula [1] described for the first organic light-emitting device. For the same reason as in the first organic light-emitting device, the electron mobility in the n-type charge generation layer can be improved when the relationship represented by Formula [1] is satisfied. Therefore, the driving voltage of the organic light-emitting device according to the present embodiment is further reduced.

(2-5) The first organic compound and the second organic compound in the n-type charge generation layer satisfy the relationship represented by Formula [2-1].

$$HOMO ( H 2 ) - HOMO ( H 1 ) > 0. eV \qquad [ 2 - 1 ]$$

As described above, in the configuration according to an embodiment of the present disclosure, there may be cases in which holes are liable to leak from the light-emitting layer. That is, it is preferable to trap holes in another layer instead of trapping holes in the light-emitting layer. In particular, when the first organic compound and the second organic compound in the n-type charge generation layer satisfy the relationship represented by Formula [2-1], holes can be trapped in the n-type charge generation layer. More specifically, the compound represented by General Formula [I] or [II] traps holes in the n-type charge generation layer. This can inhibit degradation of the first organic compound due to holes, the compound being more unstable to holes because of its interaction with alkali metal atoms or alkaline-earth metal atoms. It is thus possible to inhibit deterioration of the entire n-type charge generation layer and deterioration of the luminance of the organic light-emitting device. Furthermore, since the n-type charge generation layer has a configuration for trapping holes, holes are less likely to reach the p-type charge generation layer, thereby making it possible to inhibit deterioration of the organic light-emitting device. Formula [2-1] described above is the same as Formula [2-1] described in the first organic light-emitting device.

In the present embodiment, when the relationship represented by the following Formula [2-2] is satisfied, the hole-trapping properties of the second organic compound are improved, thereby further improving the durability characteristics.

$$HOMO ( H 2 ) - HOMO ( H 1 ) \geq 0.2 eV \qquad [ 2 - 2 ]$$

Formula [2-2] described above is the same as Formula [2-2] described in the first organic light-emitting device.

(2-6) The first light-emitting unit includes the first light-emitting layer, the first light-emitting layer contains at least the third organic compound and the first light-emitting compound, and the third organic compound and the first light-emitting compound satisfy the relationship represented by Formula [3].

$$LUMO ( H 3 ) - LUMO ( D 1 ) > HOMO ( D 1 ) - HOMO ( H 3 ) \qquad [ 3 ]$$

Formula [3] described above is the same as Formula [3] described in the first organic light-emitting device. For the same reason as in the first organic light-emitting device, when the relationship represented by Formula [3] is satisfied, the first light-emitting layer is an electron-trap type. This inhibits deterioration due to holes, thereby improving the durability of the organic light-emitting device.

As with the first organic light-emitting device, the first light-emitting layer preferably satisfies the relationship represented by the following Formula [4] in order to exhibit sufficient electron-trapping properties.

$$LUMO ( H 3 ) - LUMO ( D 1 ) \geq 0.1 eV \qquad ( 4 )$$

Examples of compounds that can be used in the organic light-emitting device according to an embodiment of the present disclosure will be illustrated below.

Examples of the first organic compound in the n-type charge generation layer include, but are not limited to, phenanthroline derivatives and naphthyridine derivatives represented by ET1 to ET14 below.

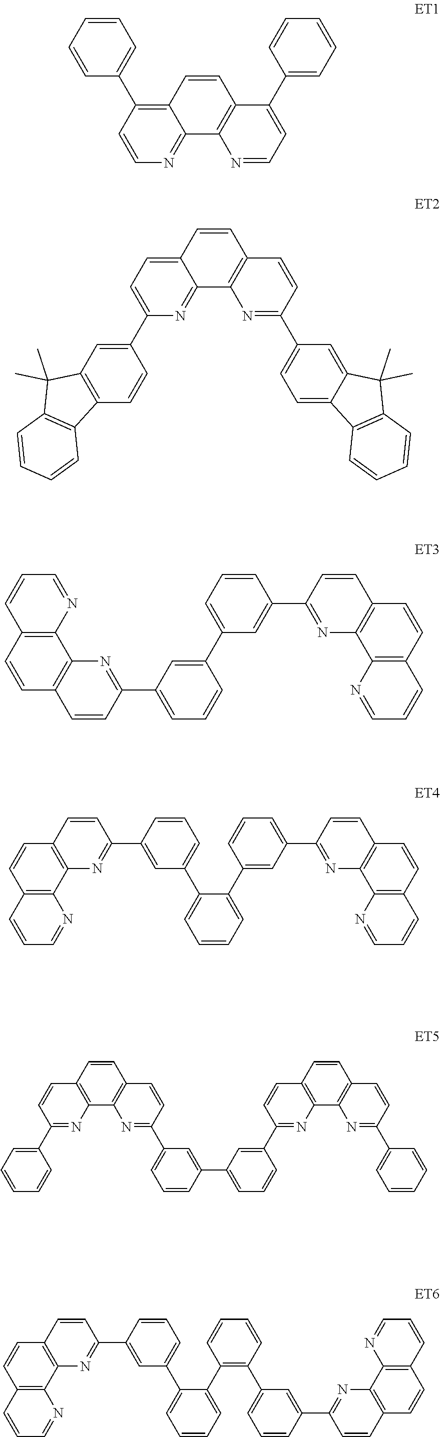

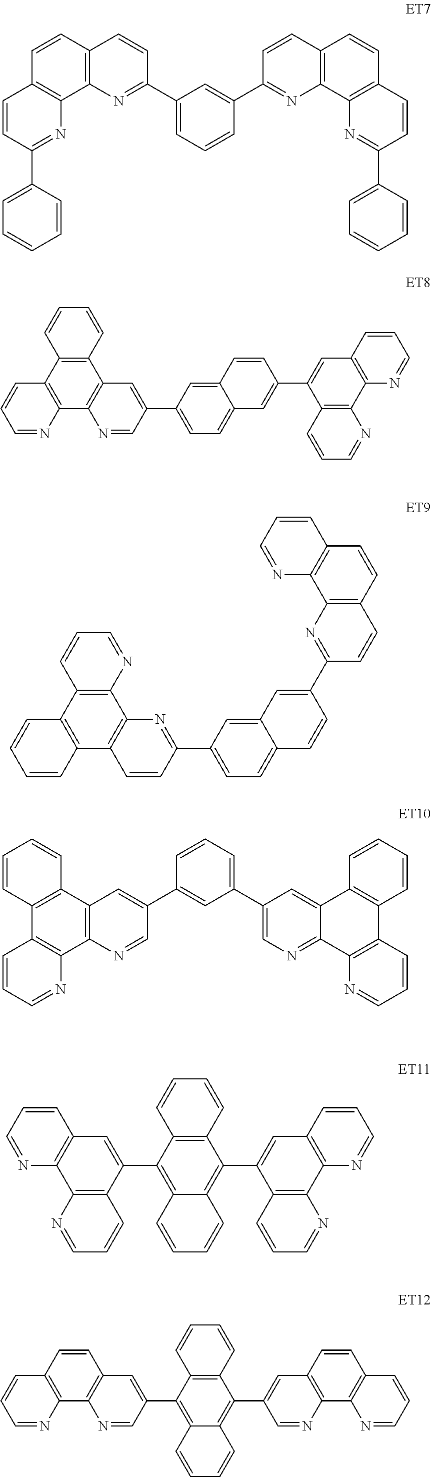 [SMILES: c1ccc(-c2ccc3ccc4ccc(-c5cccc(-c6ccc7ccc8ccc(-c9ccccc9)nc8c7n6)c5)nc4c3n2)cc1 ; c1cnc2c(c1)cc(-c1ccc3cc(-c4cnc5c(c4)c4ccccc4c4cccnc45)ccc3c1)c1cccnc12 ; c1cnc2c(c1)ccc1ccc(-c3ccc4ccc(-c5ccc6c7ccccc7c7cccnc7c6n5)cc4c3)nc12 ; c1cc(-c2cnc3c(c2)c2ccccc2c2cccnc23)cc(-c2cnc3c(c2)c2ccccc2c2cccnc23)c1 ; c1cnc2c(c1)cc(-c1c3ccccc3c(-c3cc4cccnc4c4ncccc34)c3ccccc13)c1cccnc12 ; c1cnc2c(c1)ccc1cc(-c3c4ccccc4c(-c4cnc5c(ccc6cccnc65)c4)c4ccccc34)cnc12]

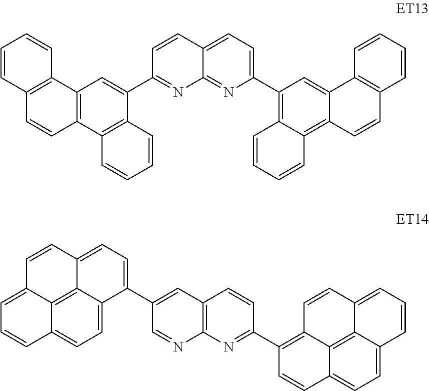 [SMILES: c1ccc2c(c1)ccc1c3ccccc3c(-c3ccc4ccc(-c5cc6c7ccccc7ccc6c6ccccc56)nc4n3)cc21 ; c1cc2ccc3ccc(-c4cnc5nc(-c6ccc7ccc8cccc9ccc6c7c89)ccc5c4)c4ccc(c1)c2c34]

Examples of the second organic compound in the n-type charge generation layer include, but are not limited to, the group of compounds represented by A1 to A12 below. This group of compounds is a group of compounds each containing a fluorene skeleton substituted with a fused polycyclic group having three or more rings, and is characterized by a high HOMO level, hole-trapping properties, and high electron mobility.

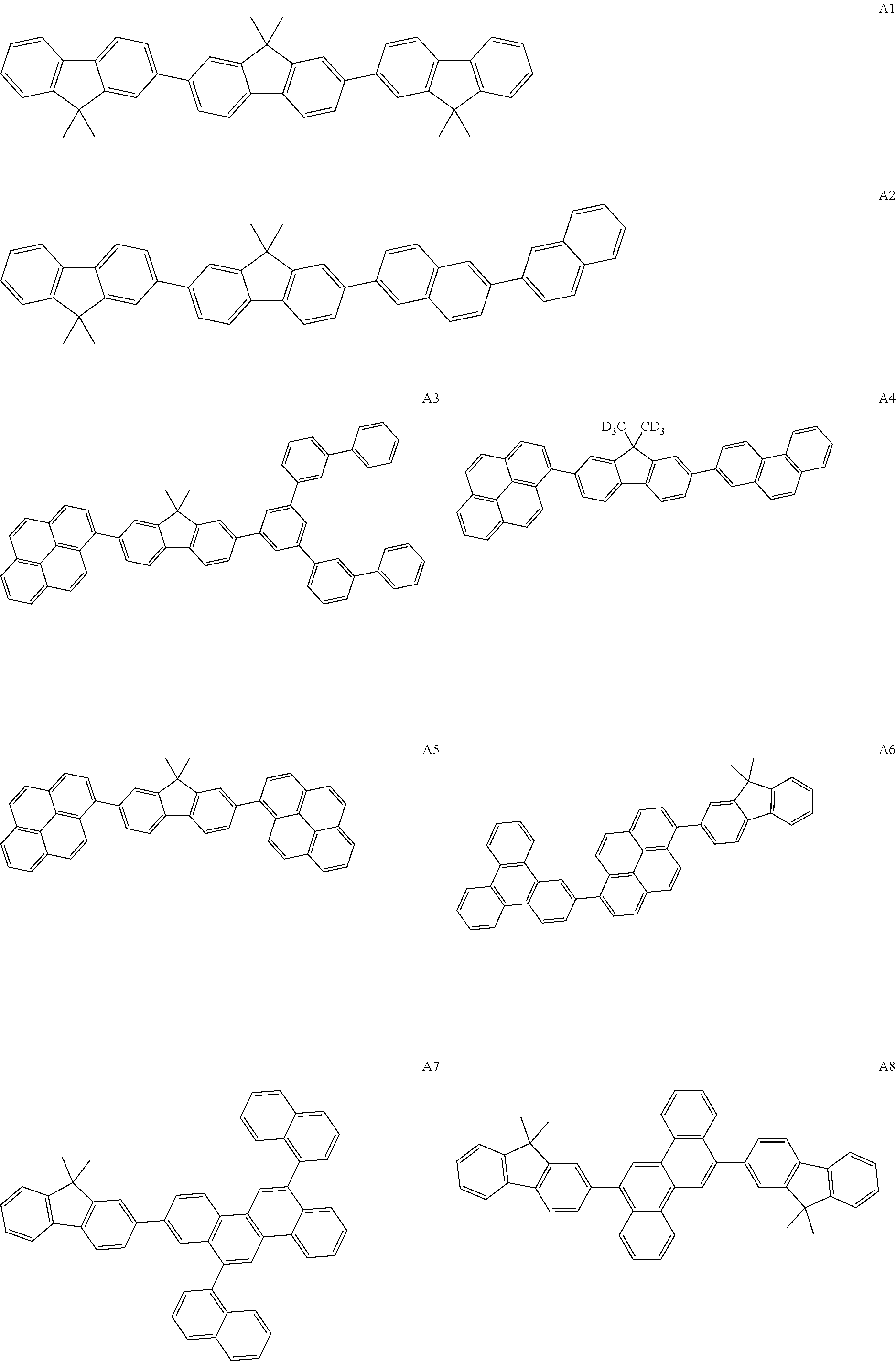

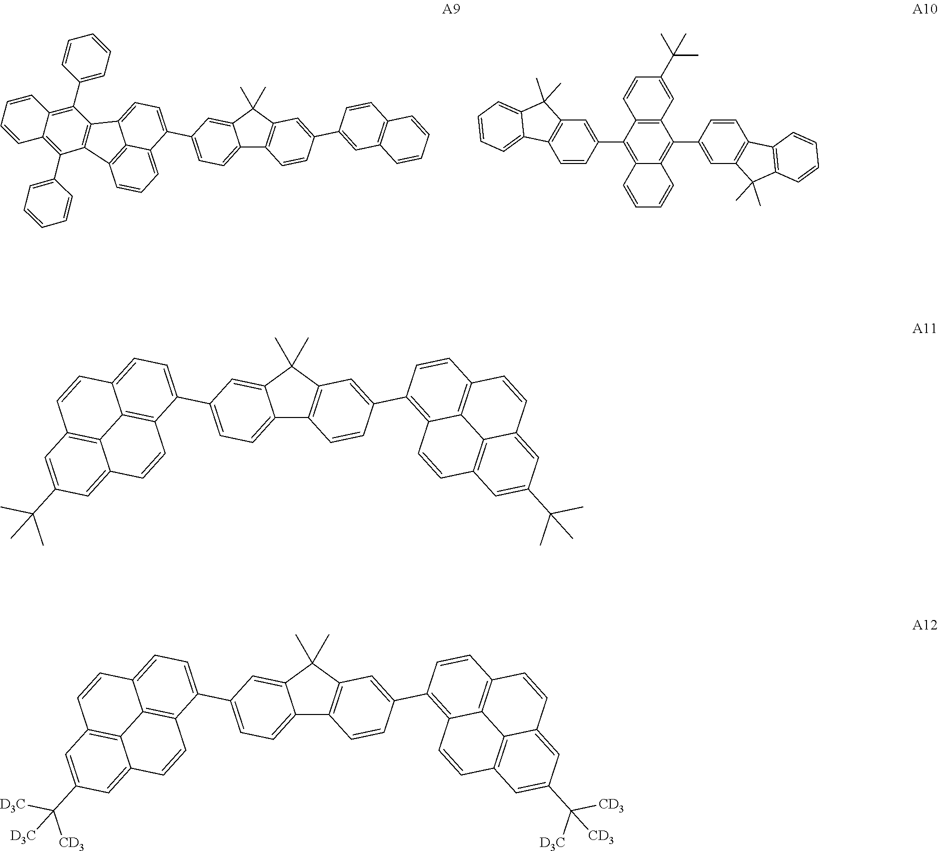

Examples of the second organic compounds in the n-type charge generation layer also include, but are not limited to, the group of compounds represented by B1 to B8 below. This group of compounds is a group of compounds each containing a fluorene skeleton substituted with at least one phenylene group, and tends to have a lower HOMO level than Compound Group A, but is characterized by low crystallizability and excellent film properties.

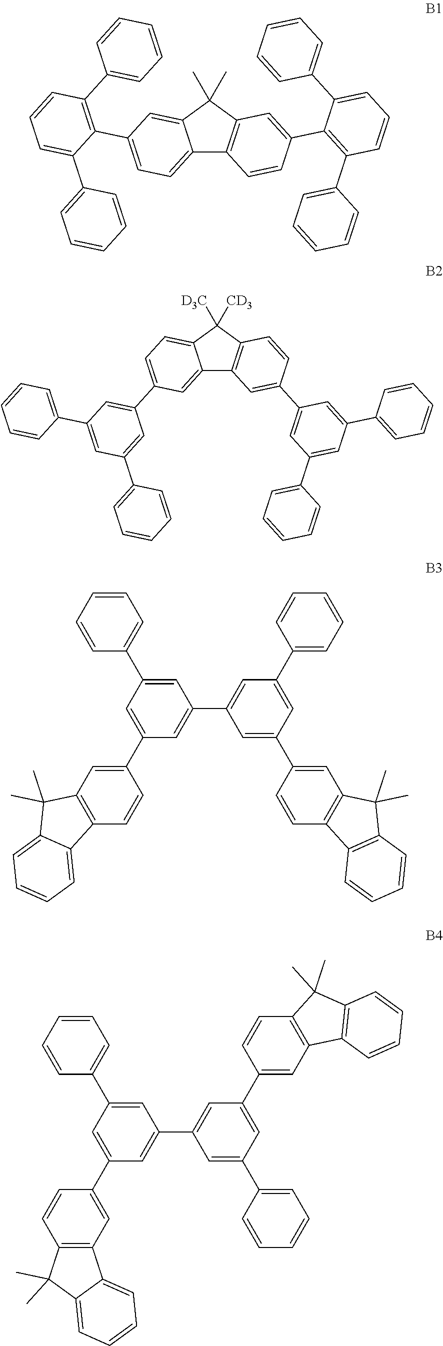

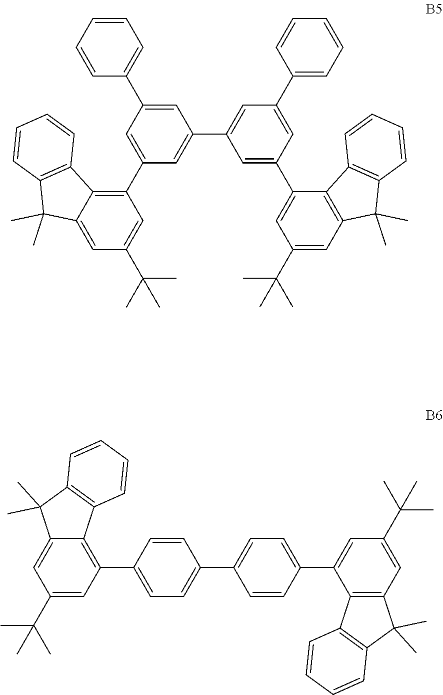

Examples of the second organic compounds in the n-type charge generation layer also include, but are not limited to, the group of compounds represented by C1 to C8 below. This group of compounds is a group of compounds each containing a fluorene skeleton substituted with at least one fused polycyclic group having four or more rings, and tends to have a lower HOMO level than Compound Group A, but is characterized by a high glass transition temperature and excellent heat resistance.

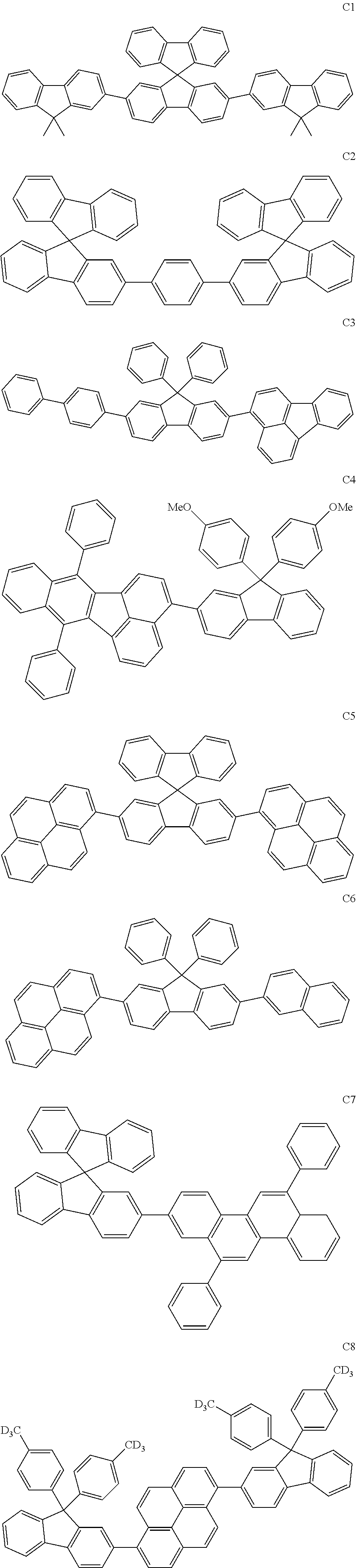

Examples of the second organic compounds in the n-type charge generation layer also include, but are not limited to, the group of compounds represented by D1 to D44 below. These compounds belonging to this group are fused polycyclic aromatic hydrocarbon compounds each having a chrysene skeleton at the center of its molecular structure. Because each of the compounds has the chrysene skeleton in its molecular structure, the group of compounds has wide band gaps and excellent charge-transport properties.

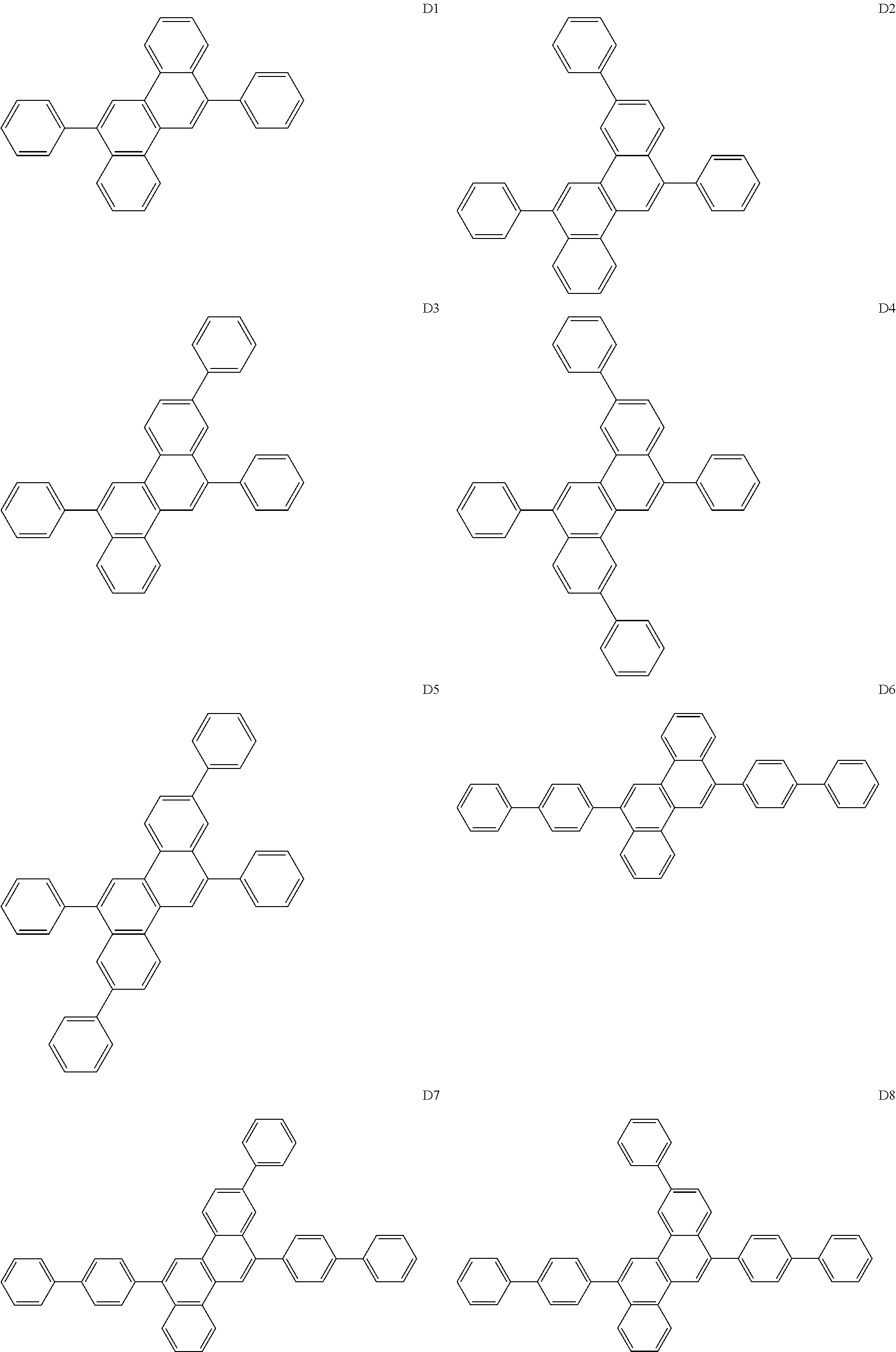

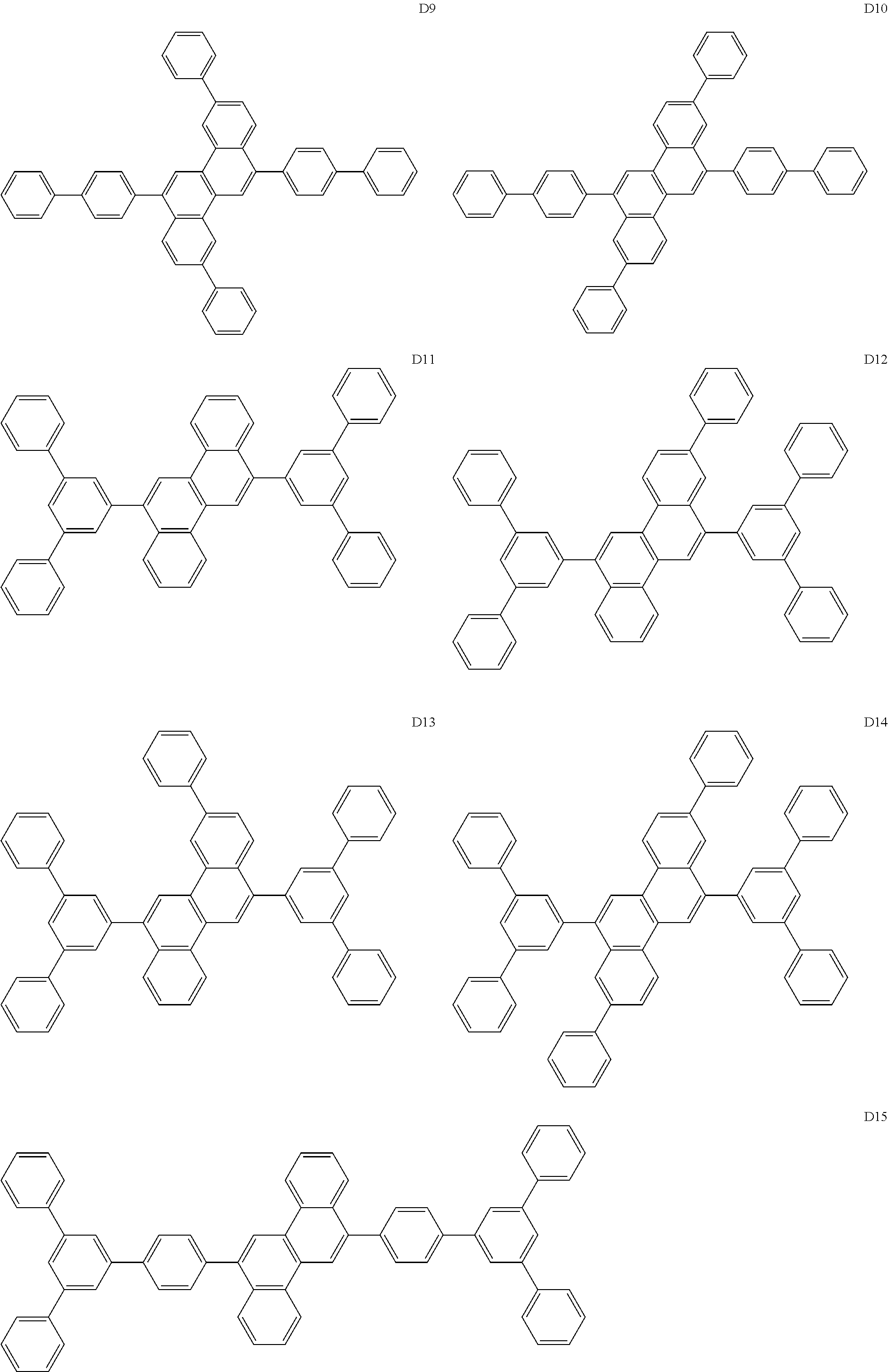

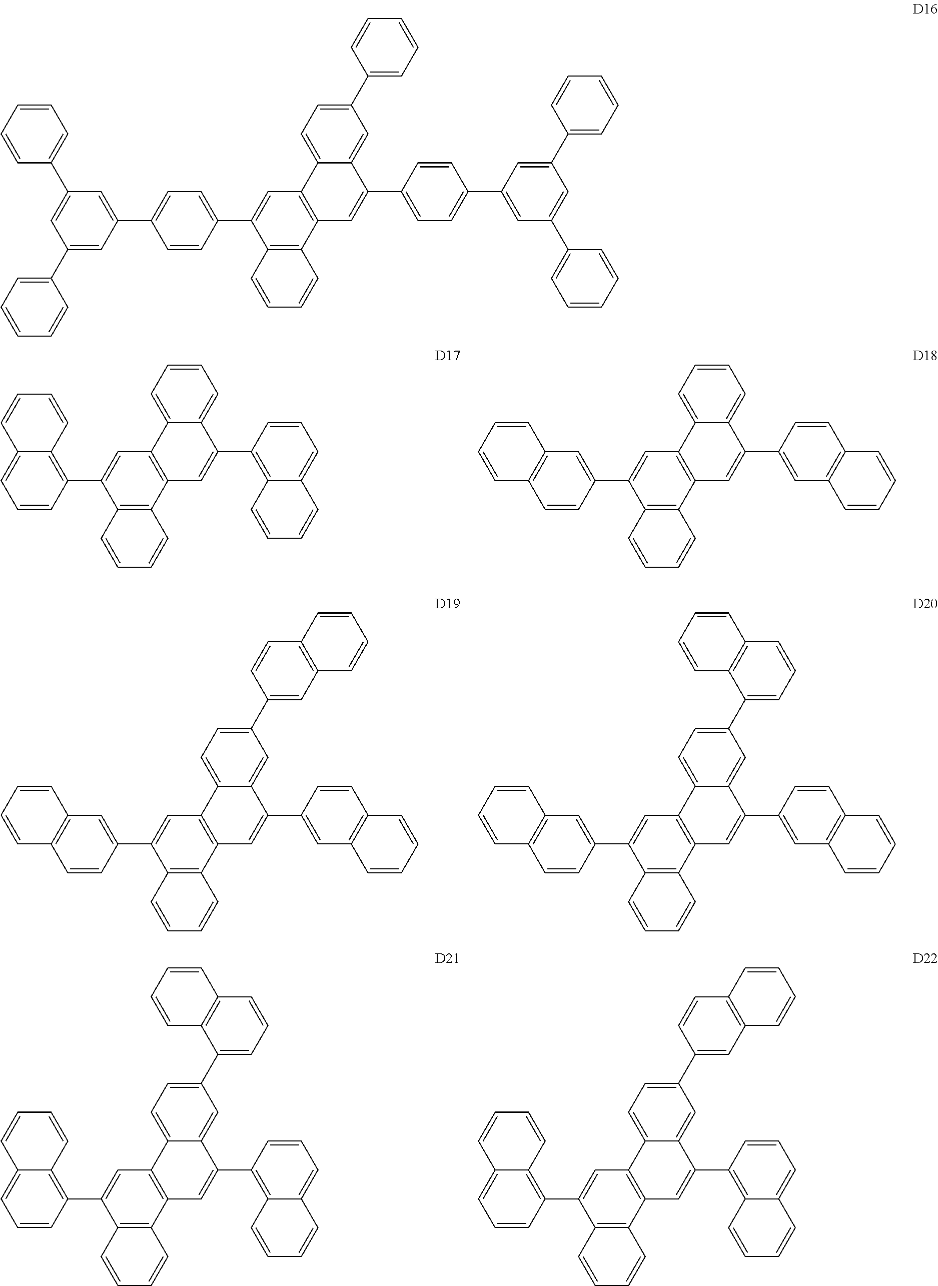

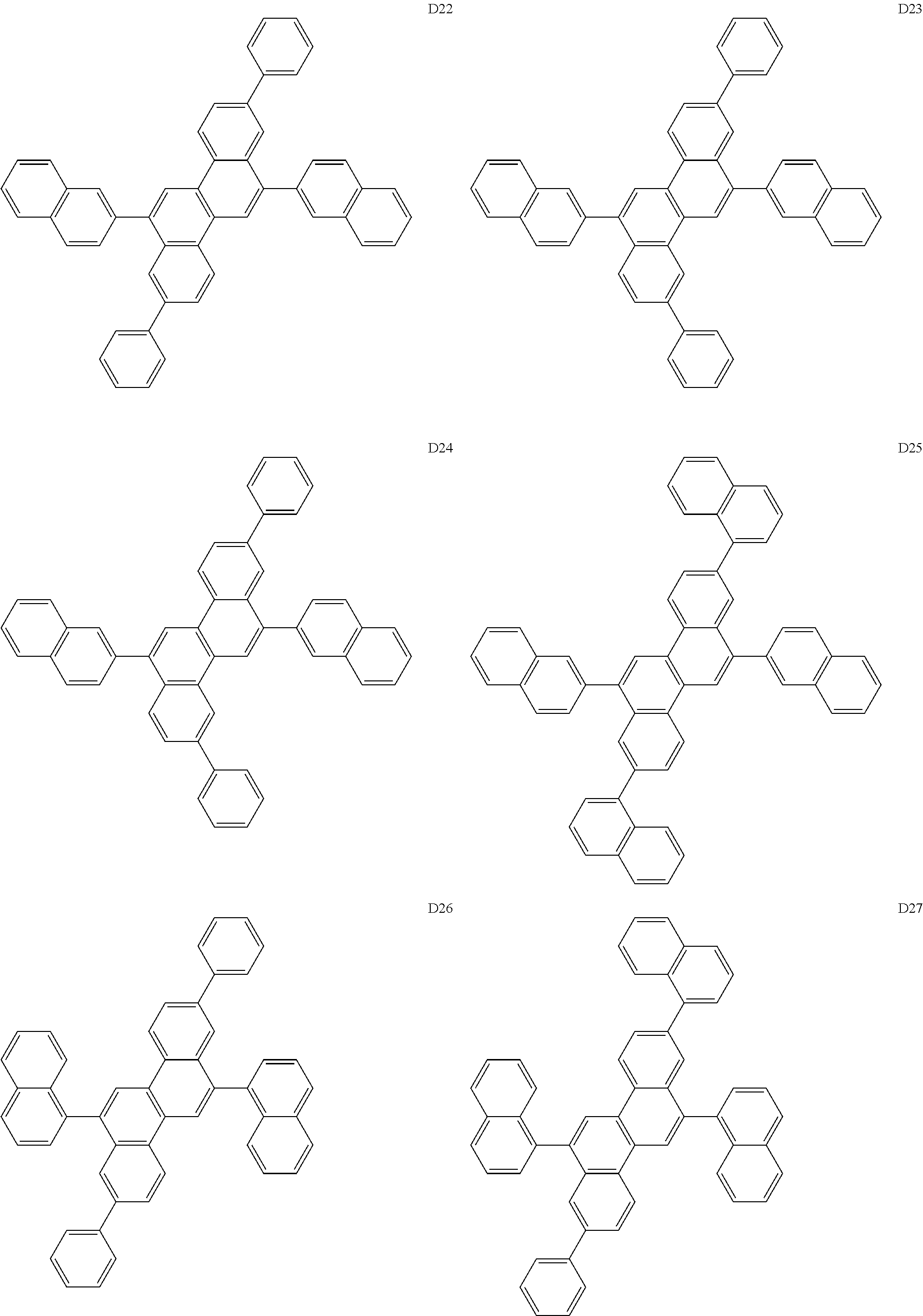

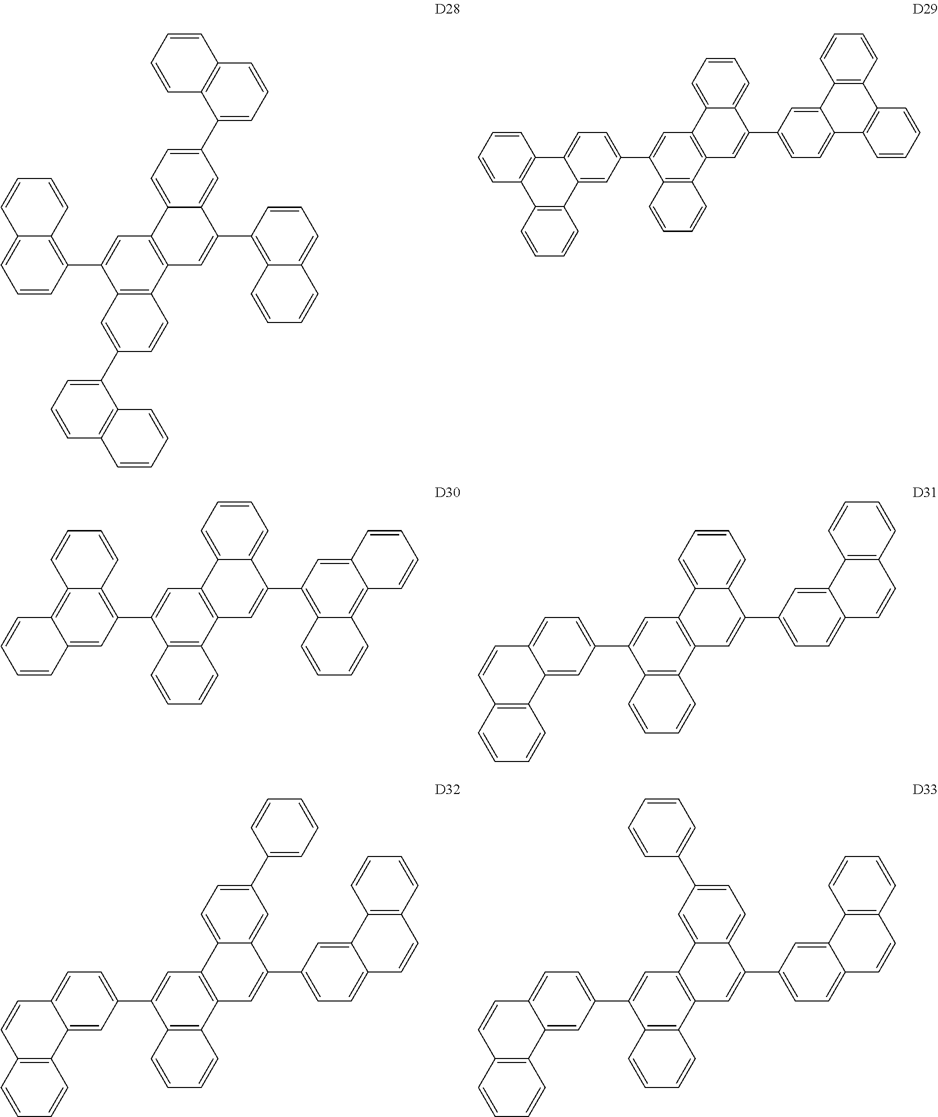

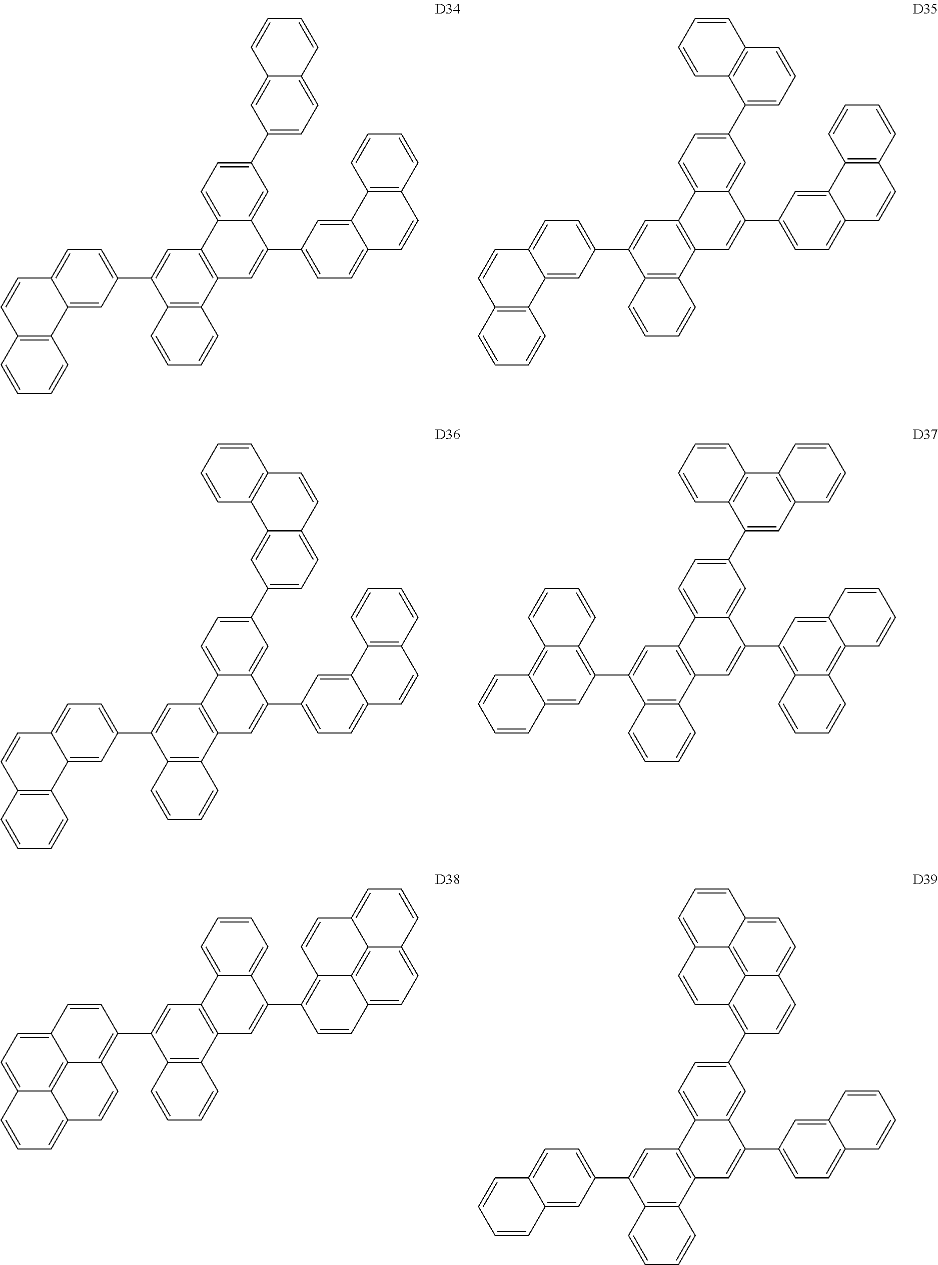

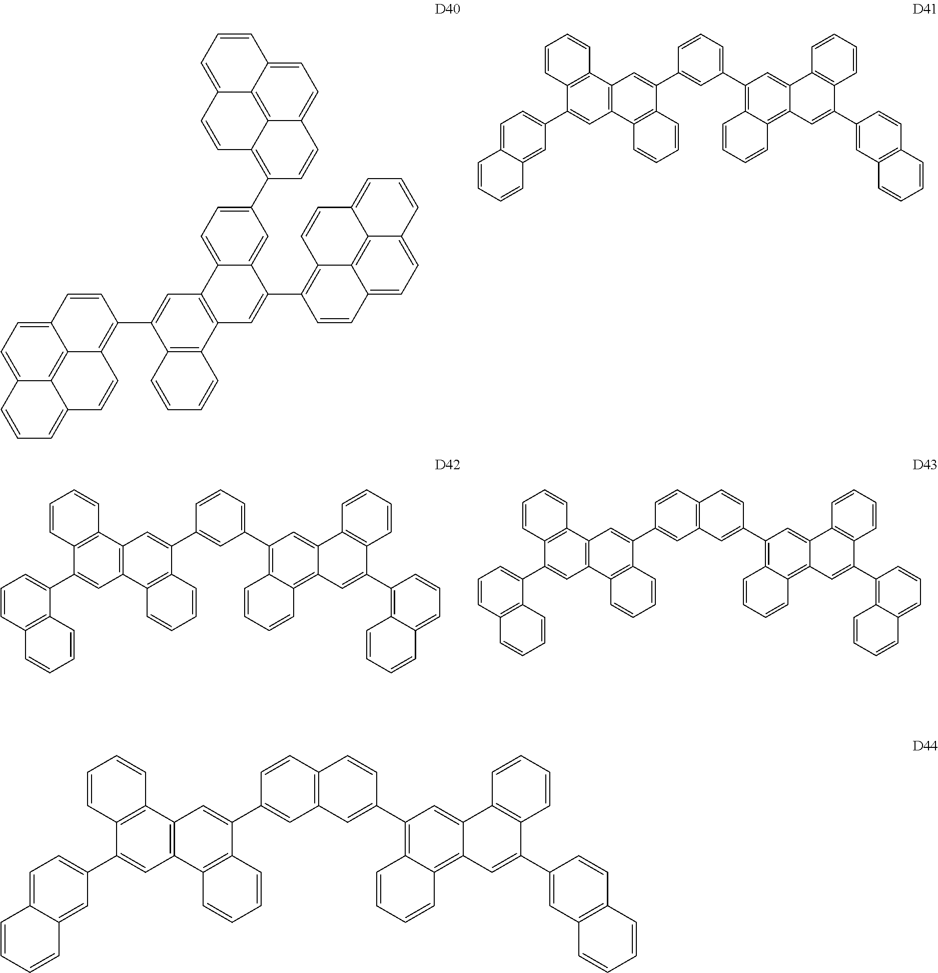

Examples of the second organic compounds in the n-type charge generation layer also include, but are not limited to, the group of compounds represented by E1 to E22 below. These compounds belonging to this group are fused polycyclic aromatic hydrocarbon compounds each having a triphenylene skeleton in its molecular structure. Since each of the compounds has the triphenylene skeleton in its molecular structure, the compound is highly planar and thus easily causes intermolecular stacking. Therefore, the compound has excellent electron mobility, resulting in the organic light-emitting device configured to operate at a low driving voltage.

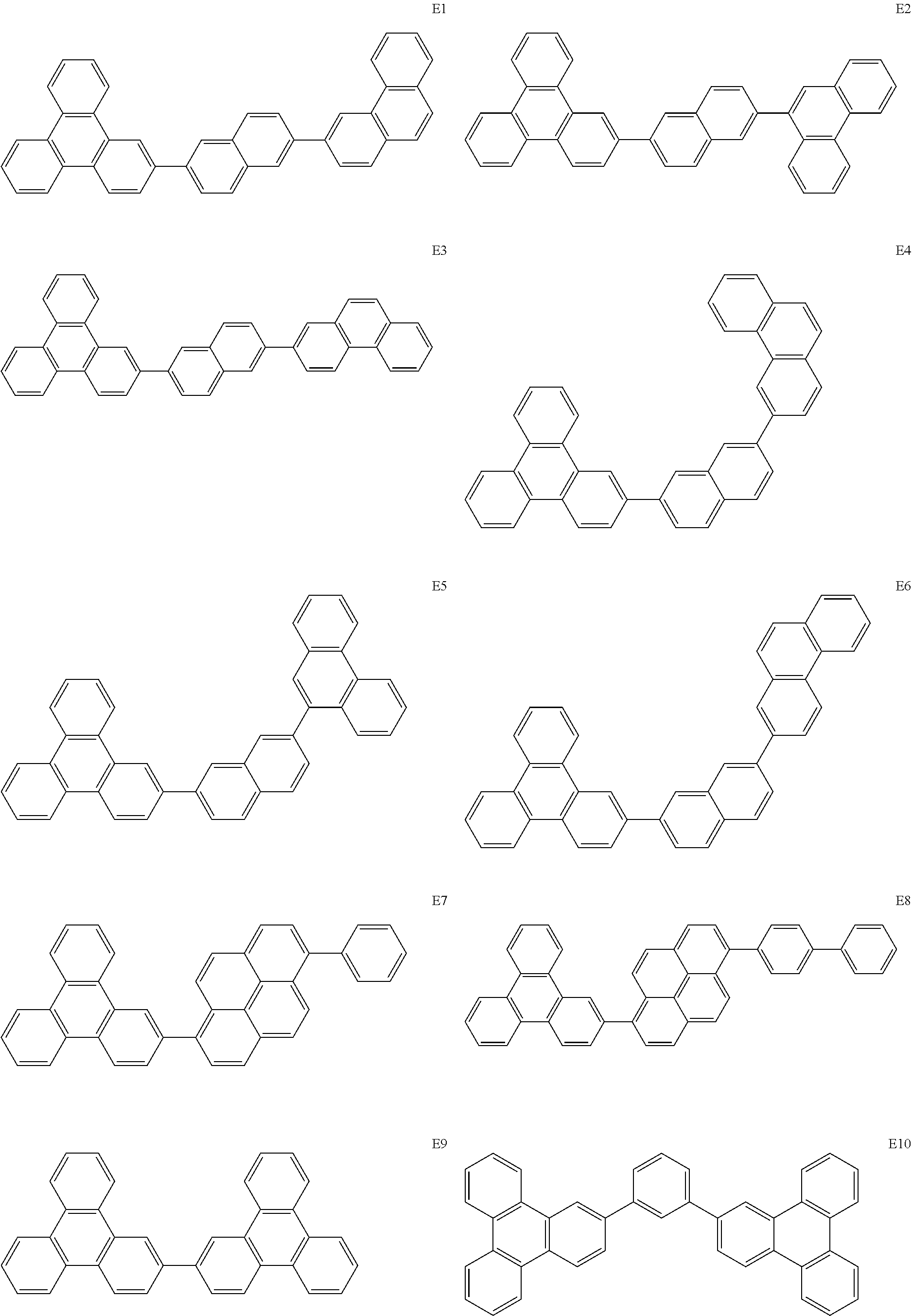

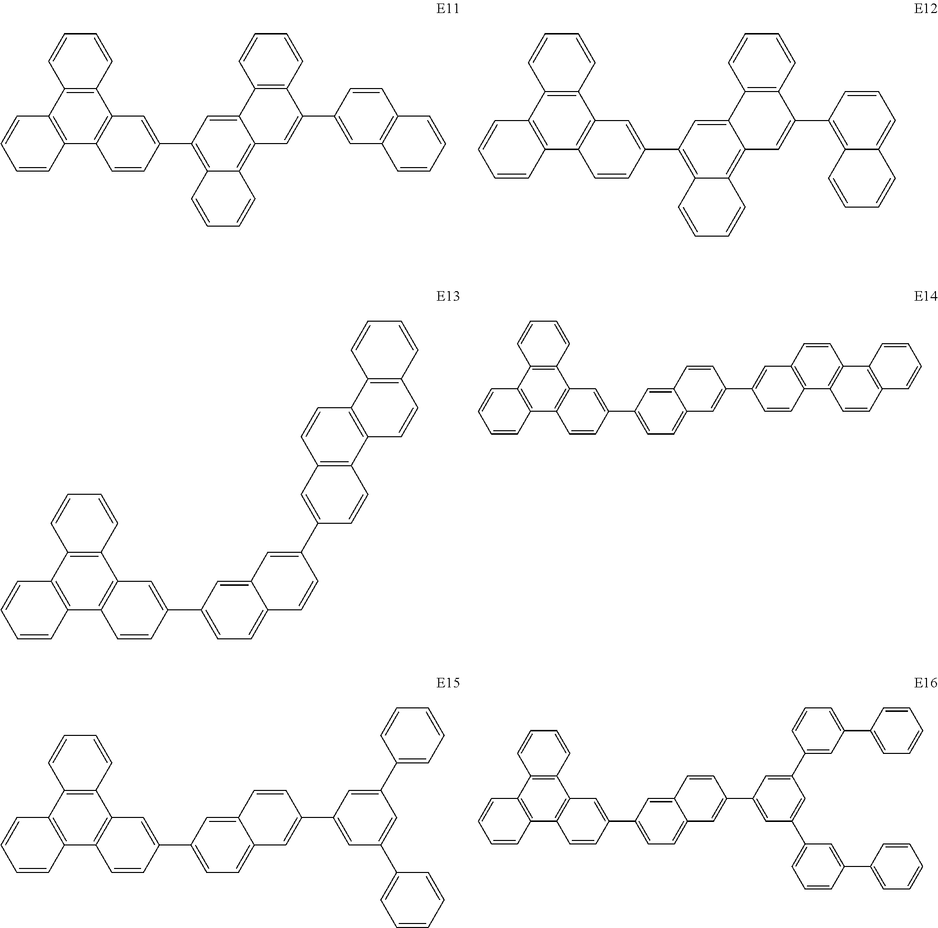

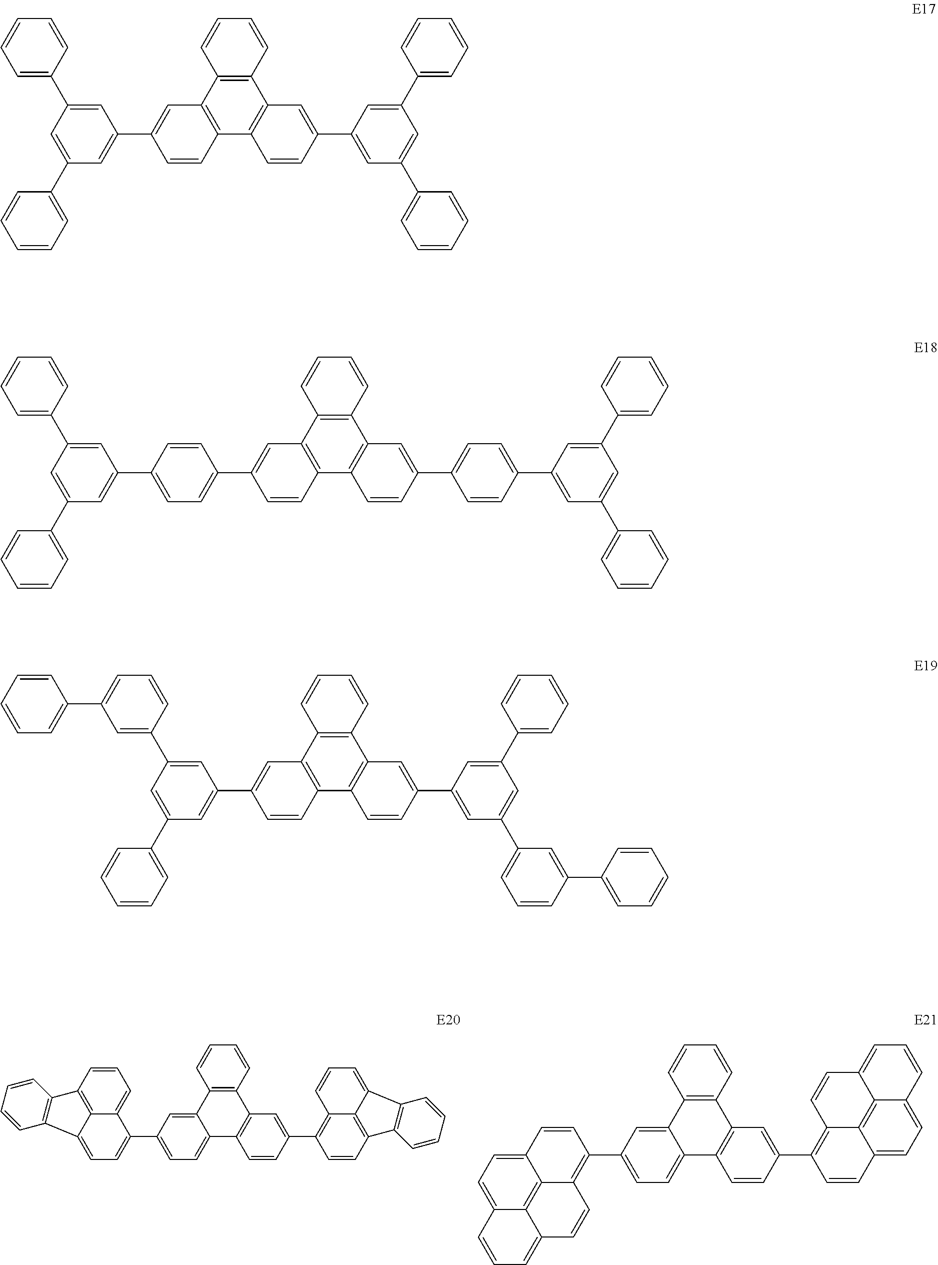

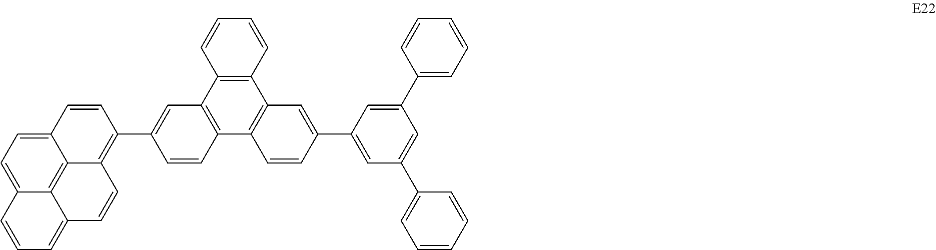 [SMILES: c1ccc(-c2cc(-c3ccccc3)cc(-c3ccc4c5ccc(-c6ccc7ccc8cccc9ccc6c7c89)cc5c5ccccc5c4c3)c2)cc1]

Examples of the second organic compounds in the n-type charge generation layer also include, but are not limited to, the group of compounds represented by F1 to F11 below. These compounds belonging to this group are fused polycyclic aromatic hydrocarbon compounds each having an anthracene skeleton in its molecular structure. Each of the compounds has the anthracene skeleton in its molecular structure and thus has a narrow band gap, and the lowest excited triplet energy level thereof is low. In addition, each compound is an organic compound having a high HOMO energy level (close to the vacuum level) and excellent hole-trapping properties.

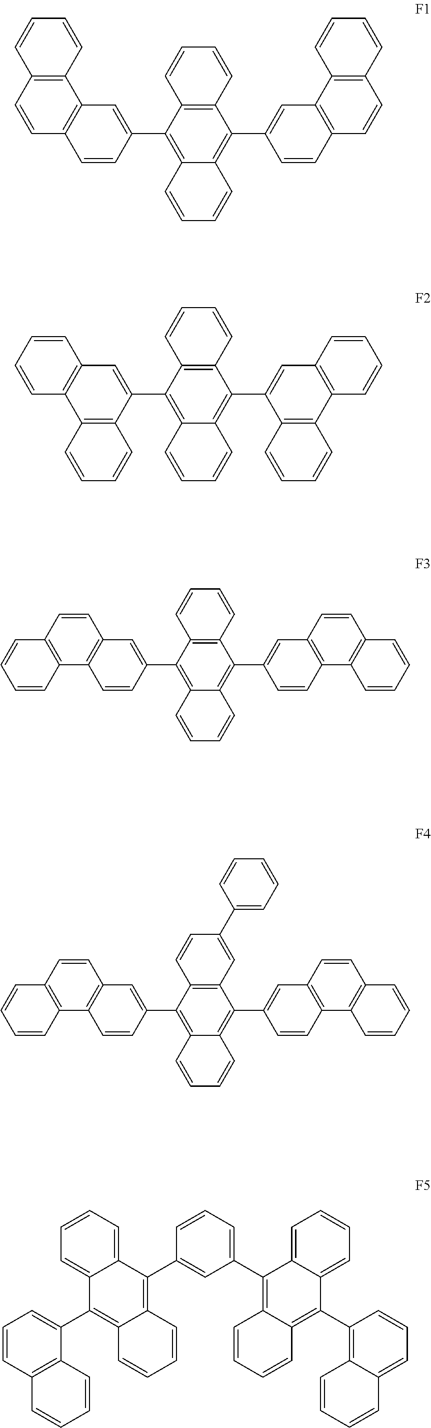

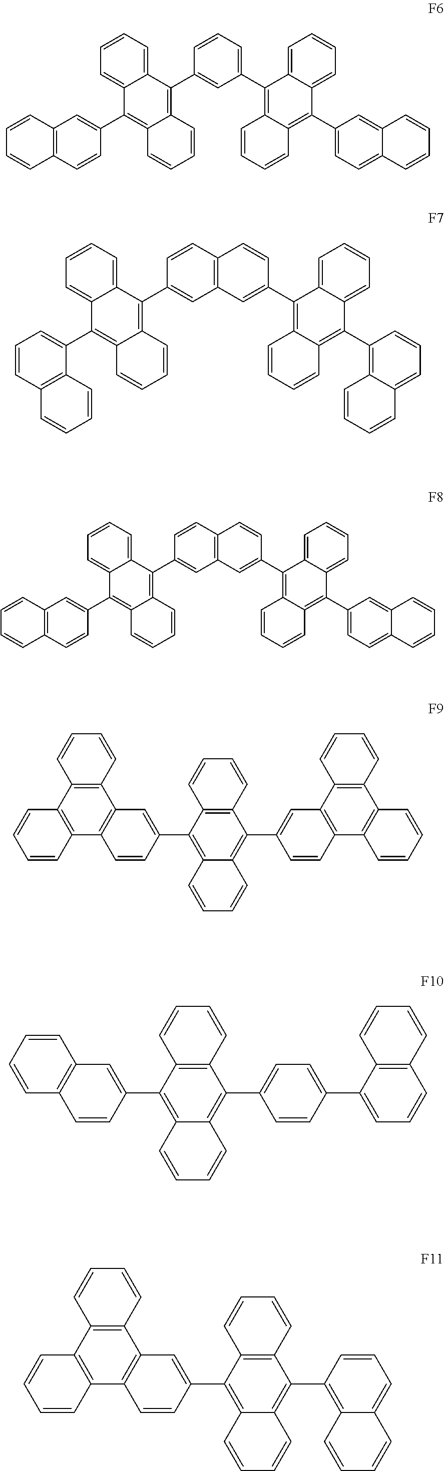

Examples of the second organic compounds in the n-type charge generation layer according to an embodiment of the present disclosure also include, but are not limited to, the group of compounds represented by G1 to G10 below. These compounds belonging to this group are fused polycyclic aromatic hydrocarbon compounds each having a divalent naphthalene skeleton in its molecular structure. The divalent naphthalene skeleton has a highly planar fused polycyclic aromatic hydrocarbon substituent, and thus the organic compound has excellent charge mobility. Accordingly, the organic light-emitting device can be configured to operate at a lower driving voltage.

Introducing different substituents into the naphthalene skeleton results in an organic compound with asymmetry and planarity. Such an organic compound has a high glass transition temperature and excellent charge mobility. Therefore, the organic light-emitting device can be configured to have excellent durability and operate at a lower driving voltage.

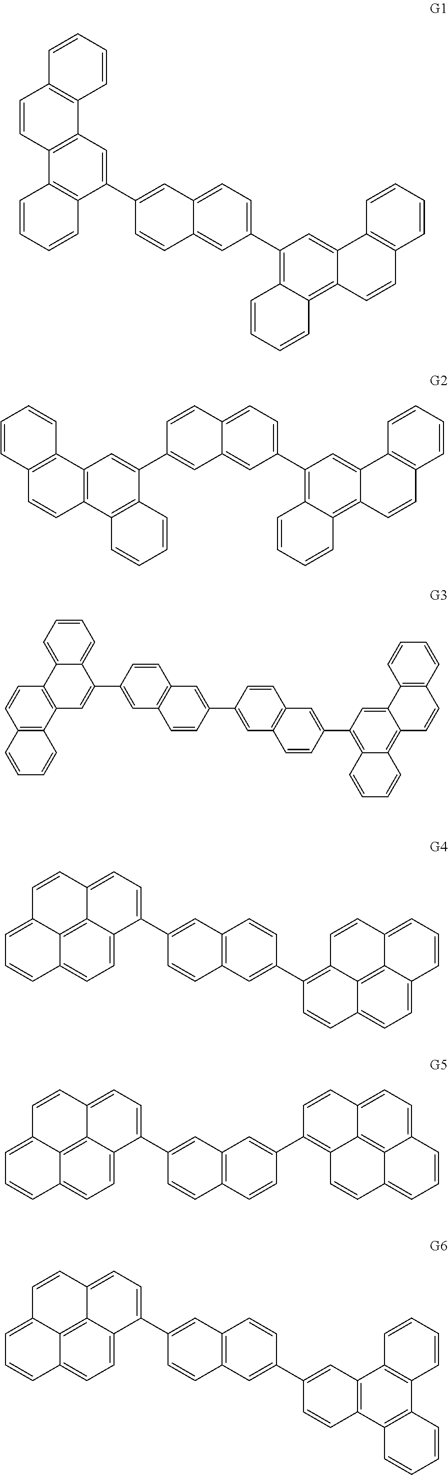

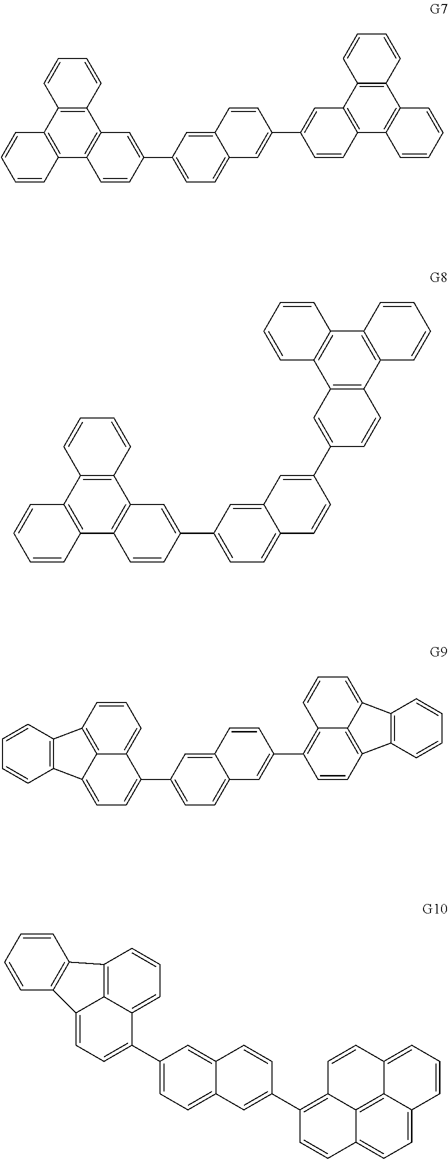

Examples of the second organic compounds in the n-type charge generation layer according to an embodiment of the present disclosure also include, but are not limited to, the group of compounds represented by H1 to H15 below. These compounds belonging to this group are fused polycyclic aromatic hydrocarbon compounds each having a perylene skeleton in its molecular structure. Since the exemplified compounds belonging to Group H each have a perylene skeleton in its molecular structure, Group H is a group of compounds each having a narrow band gap, and the lowest excited triplet energy level thereof is low. The exemplified compounds belonging to Group H are compounds each having a high HOMO energy level and thus are organic compounds with excellent hole-trapping properties.

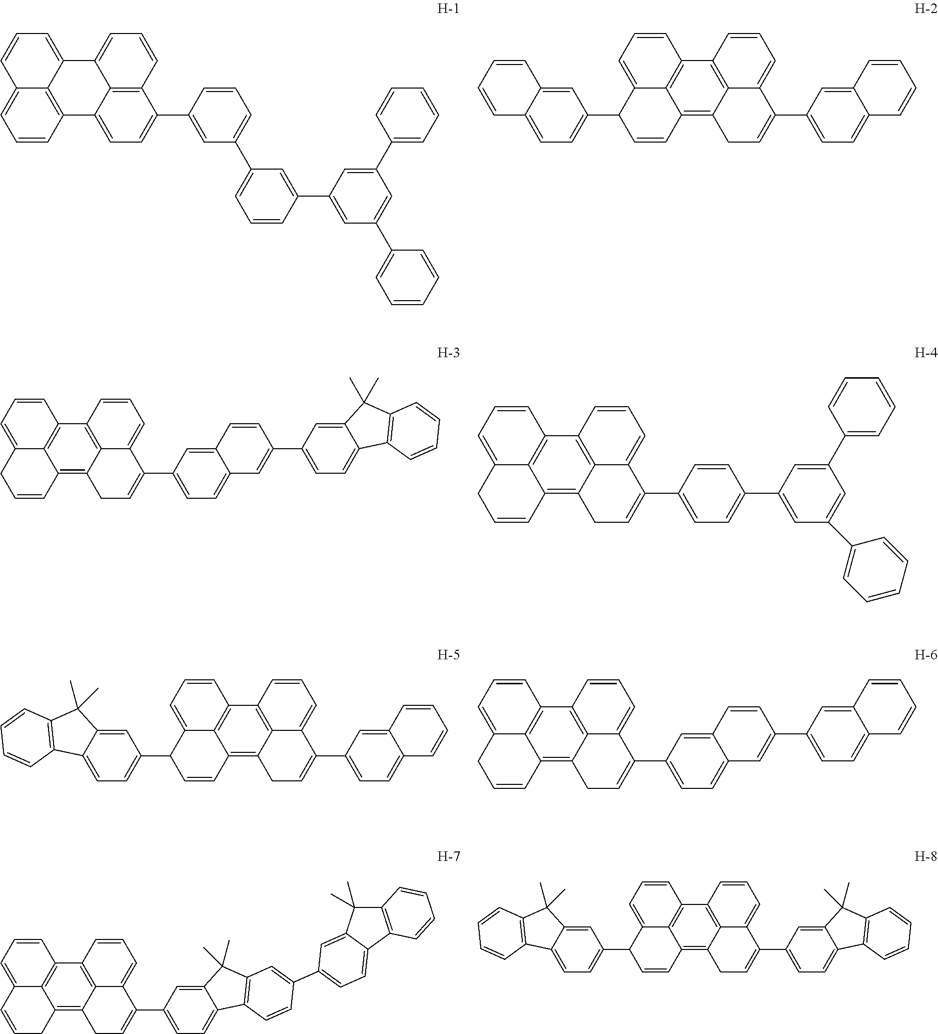

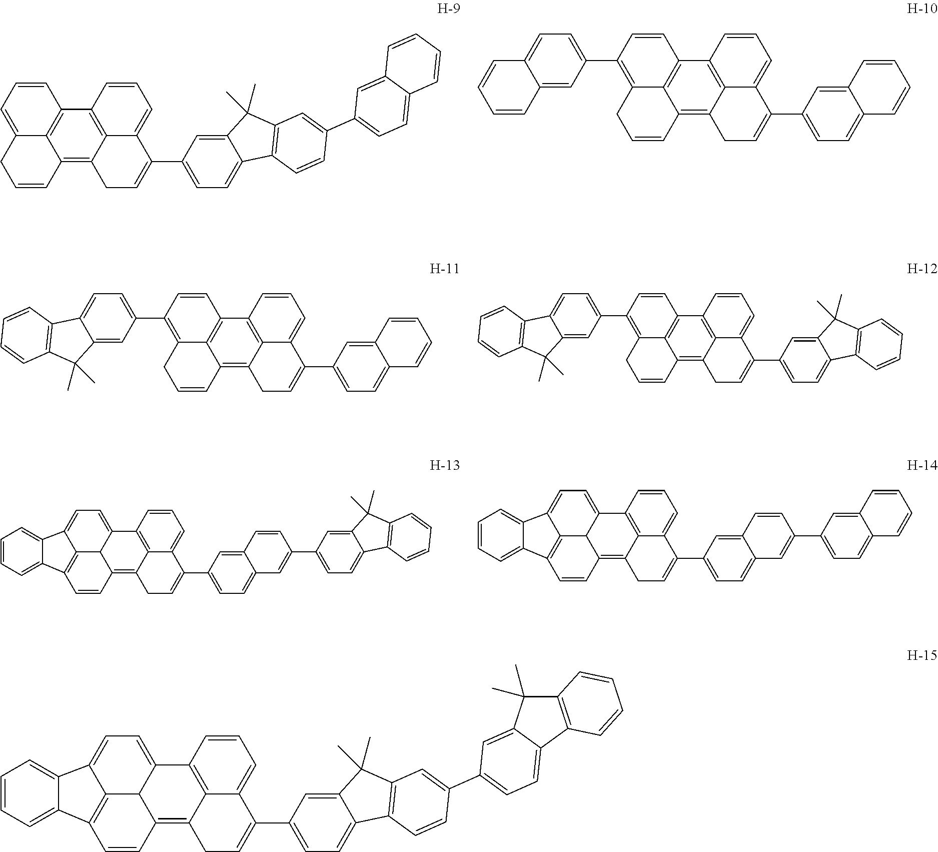

Specific examples of the organic compounds represented by General Formula [I] or [II] are illustrated below. However, the present disclosure is not limited thereto.

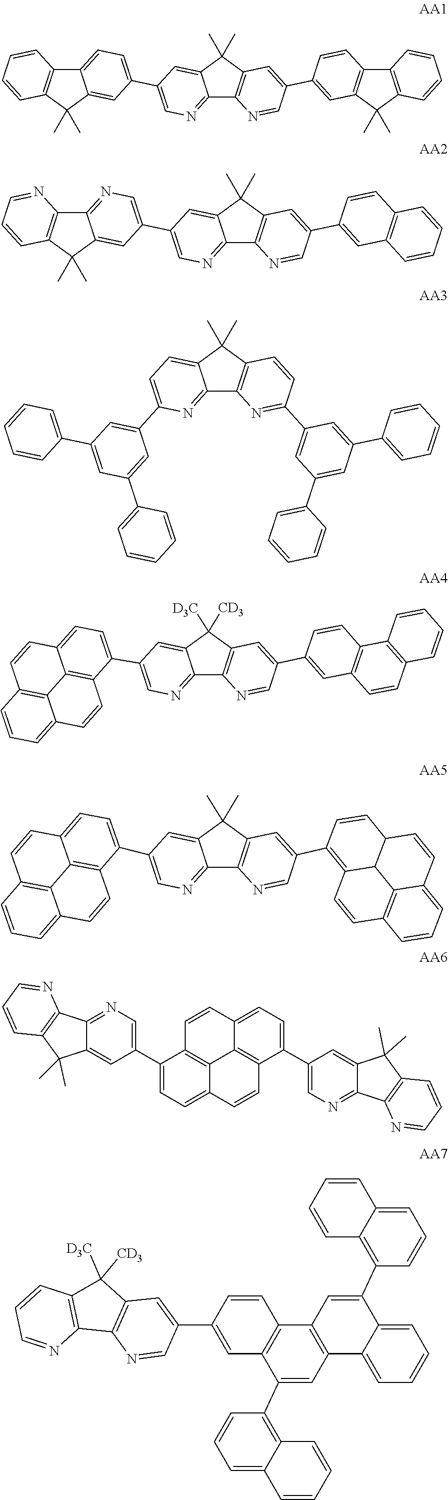

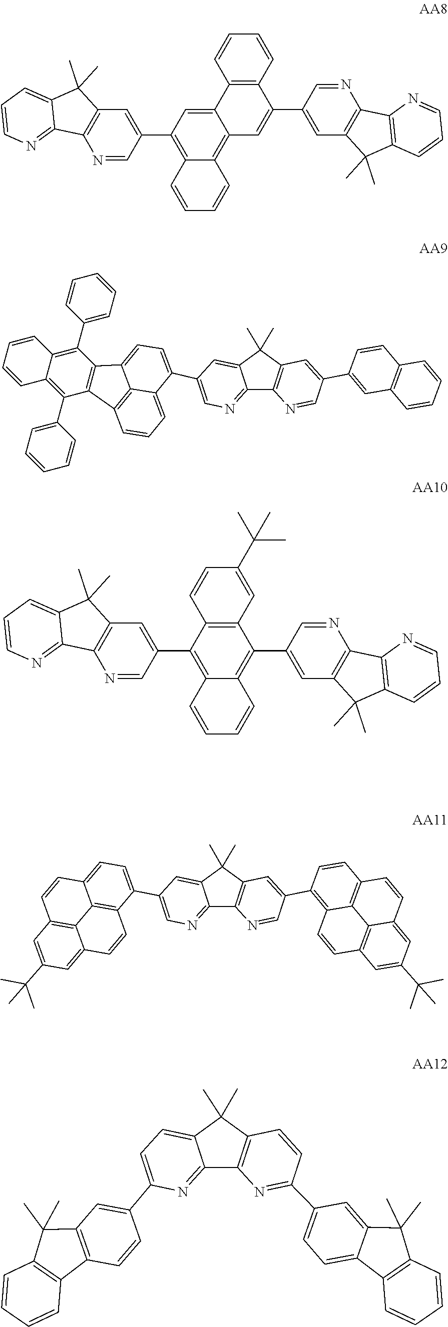

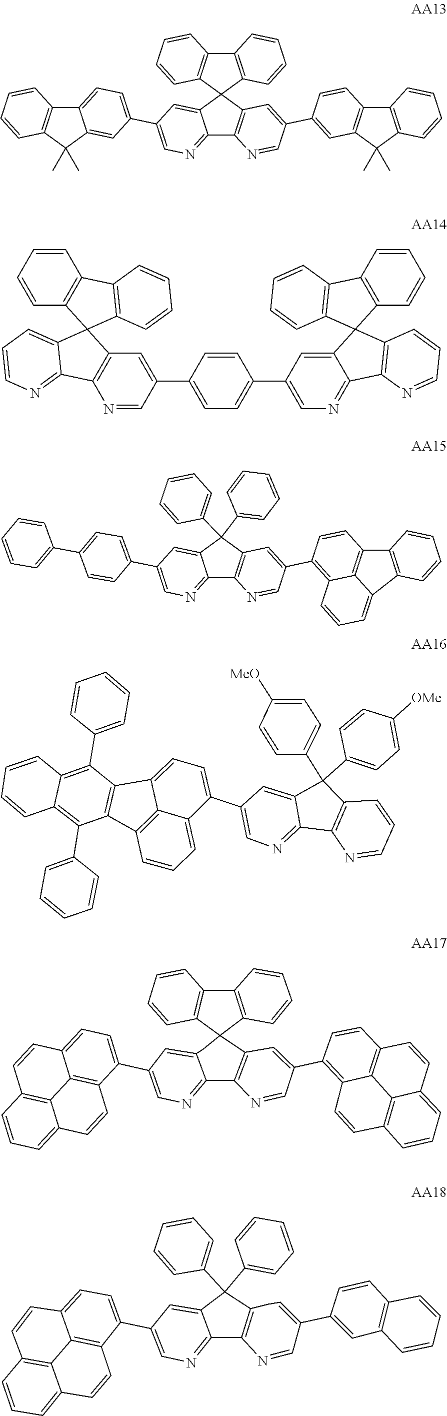

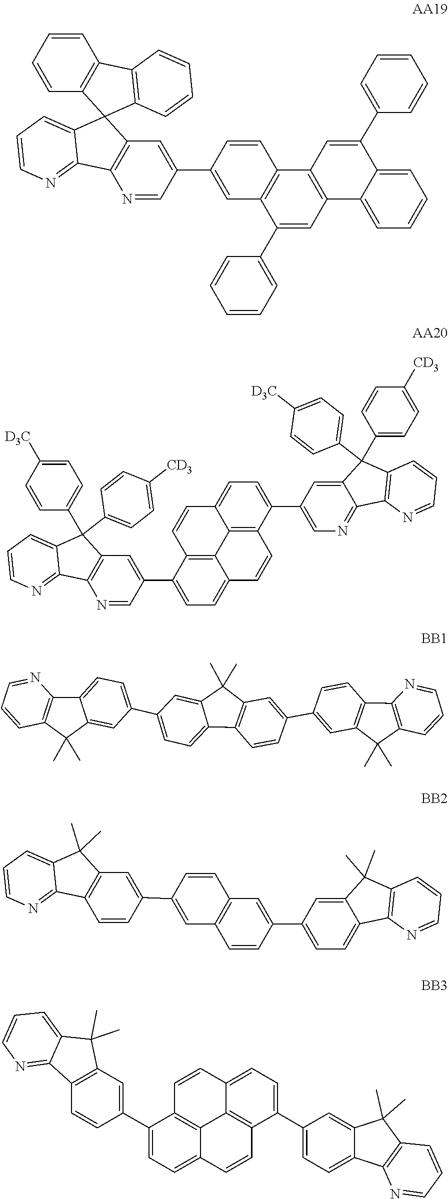

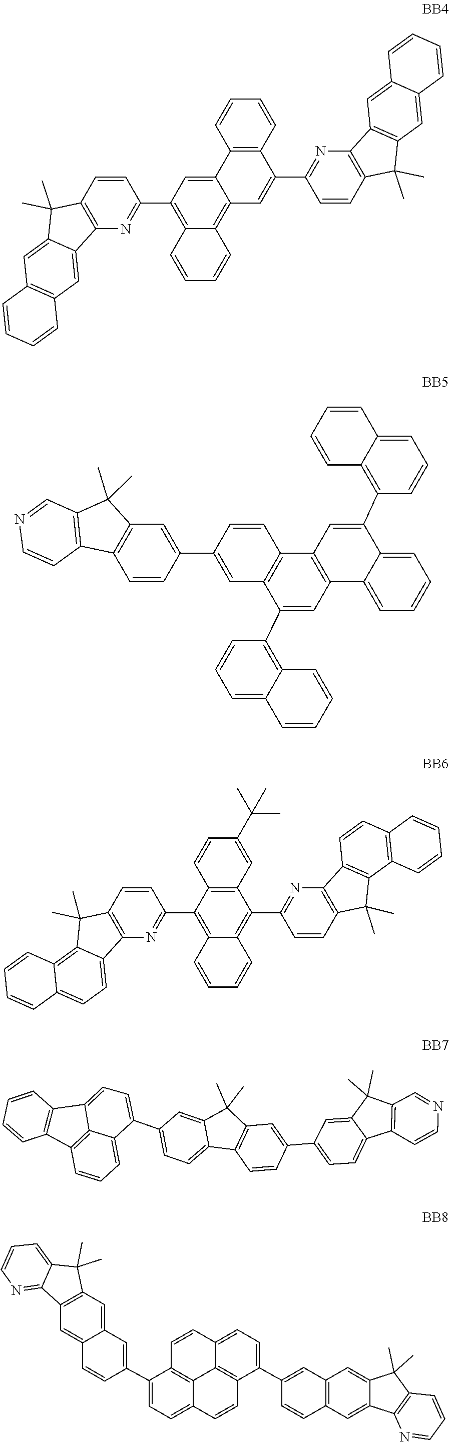

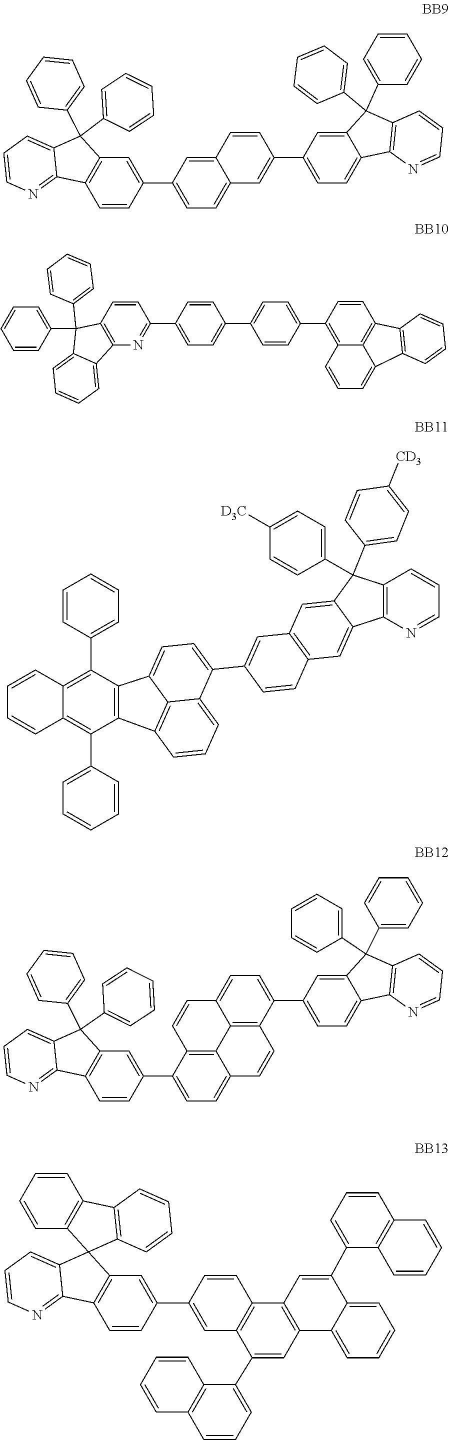

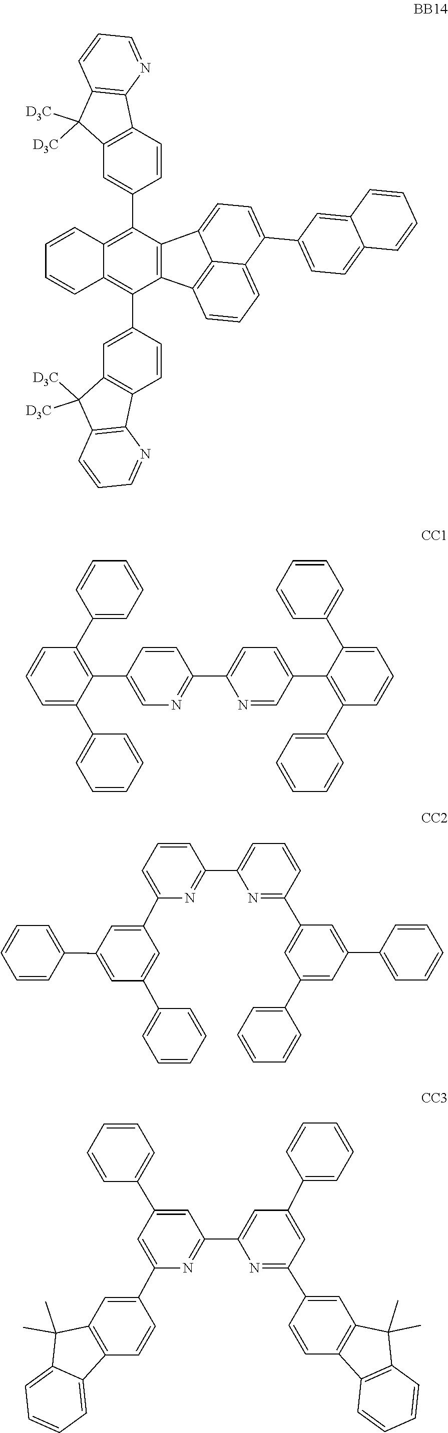

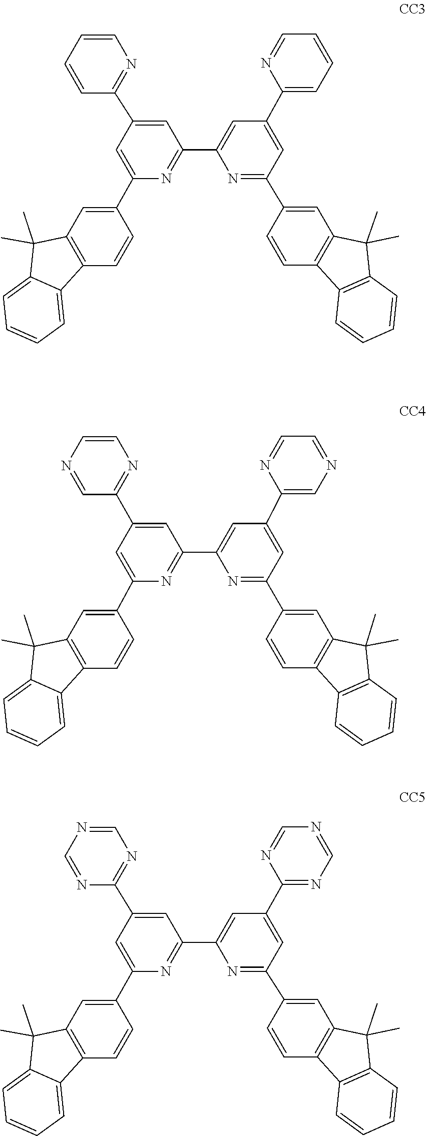

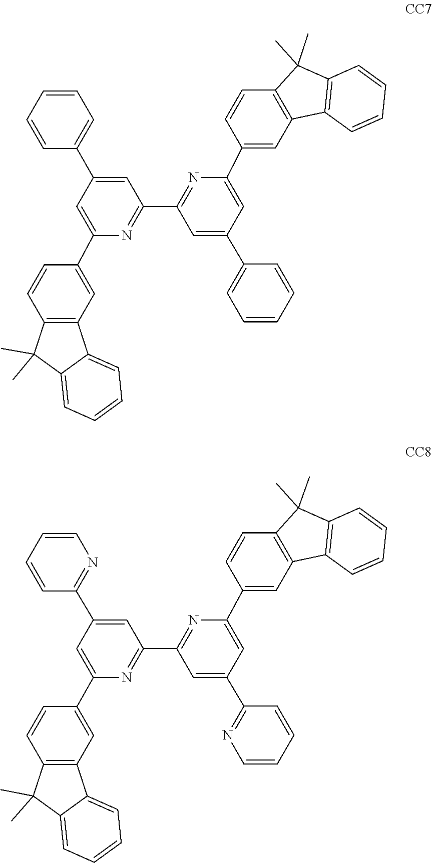

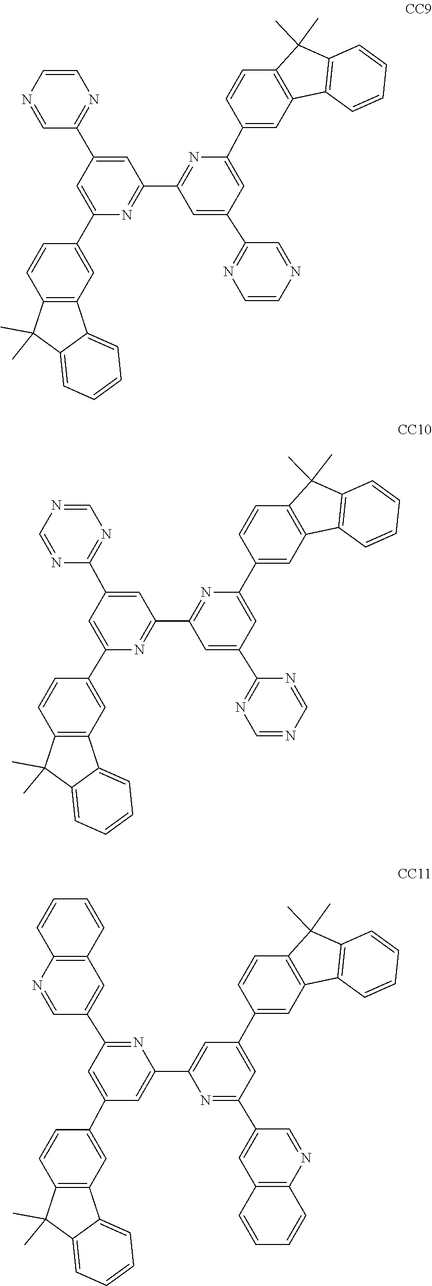

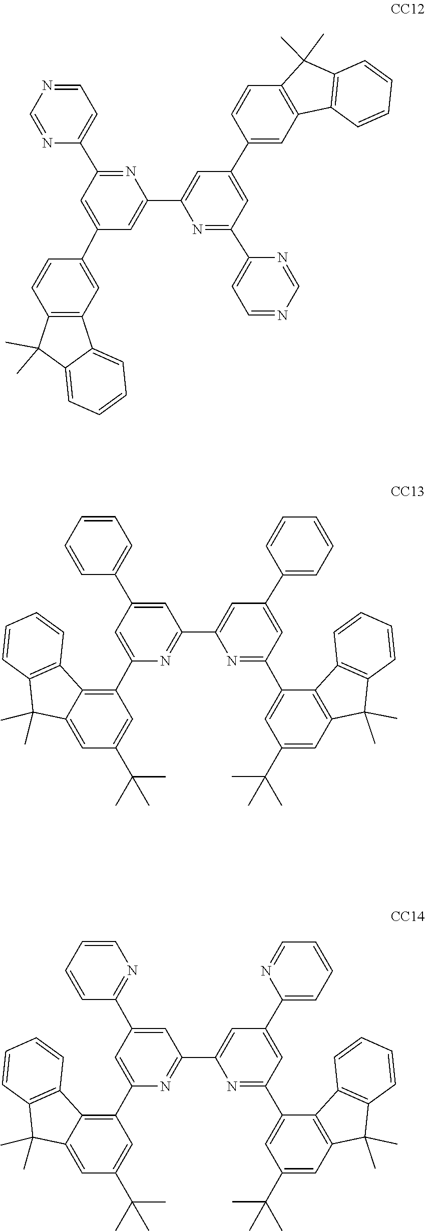

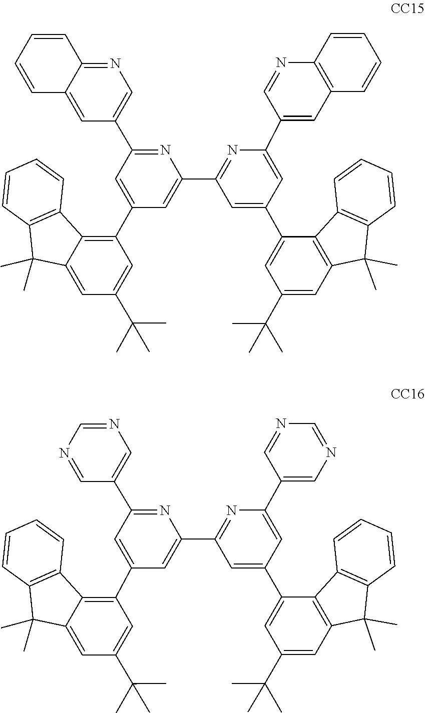

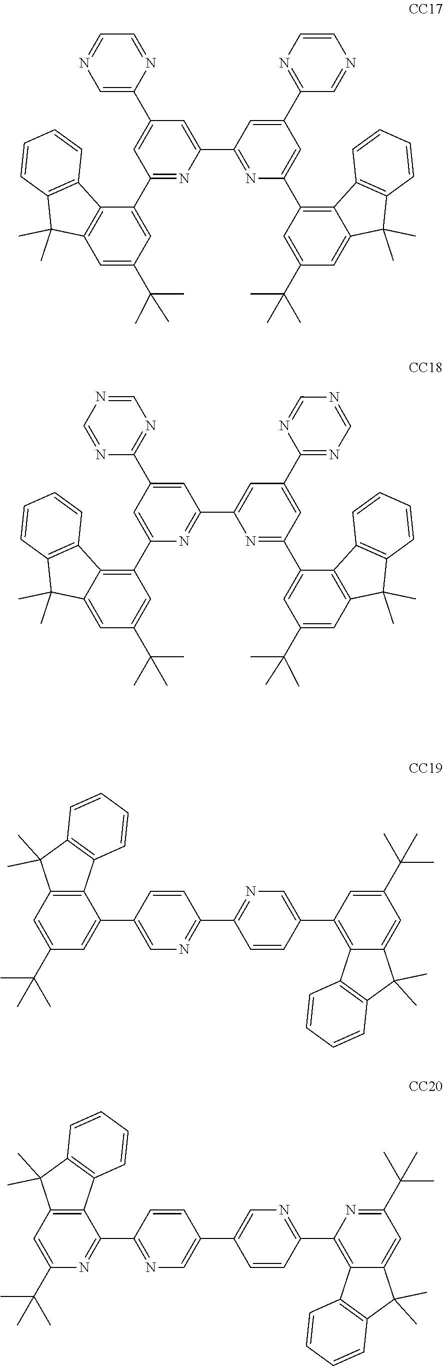

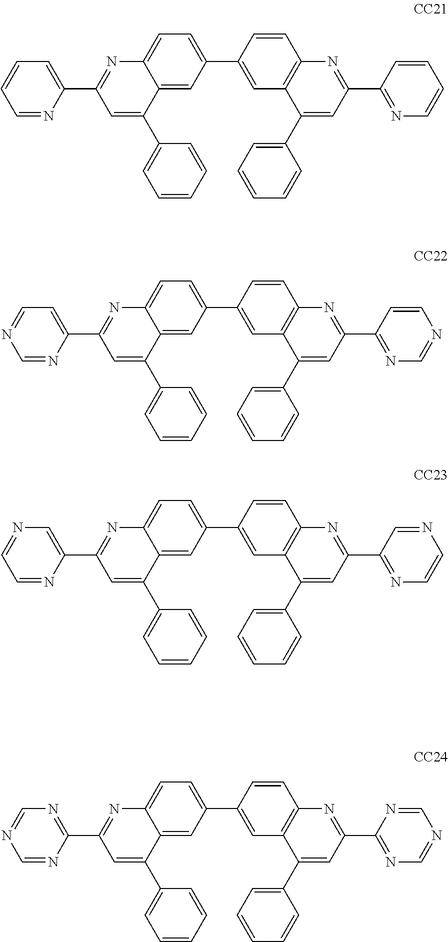

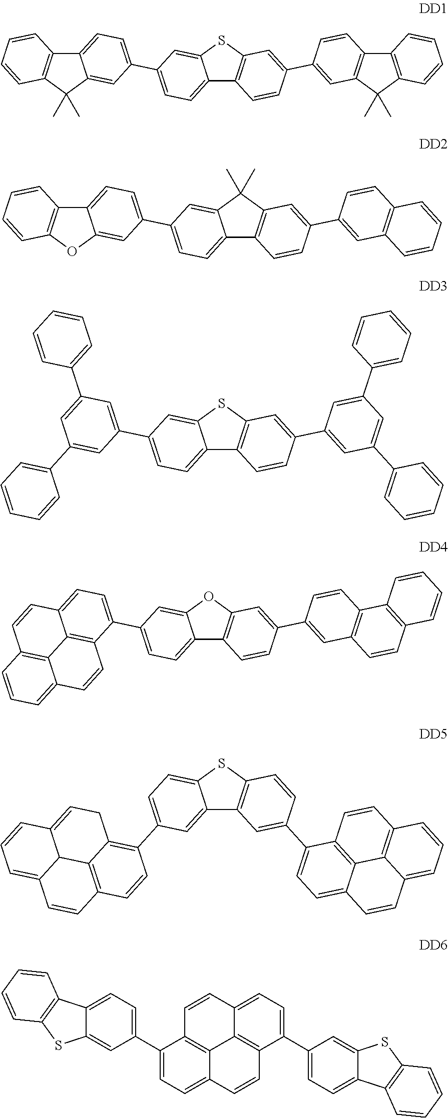

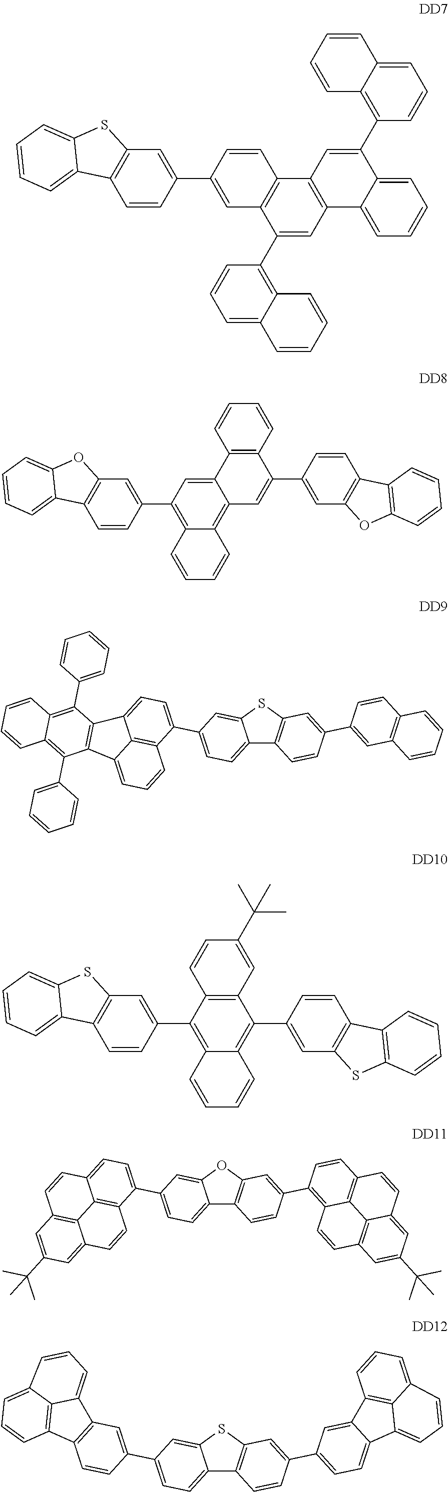

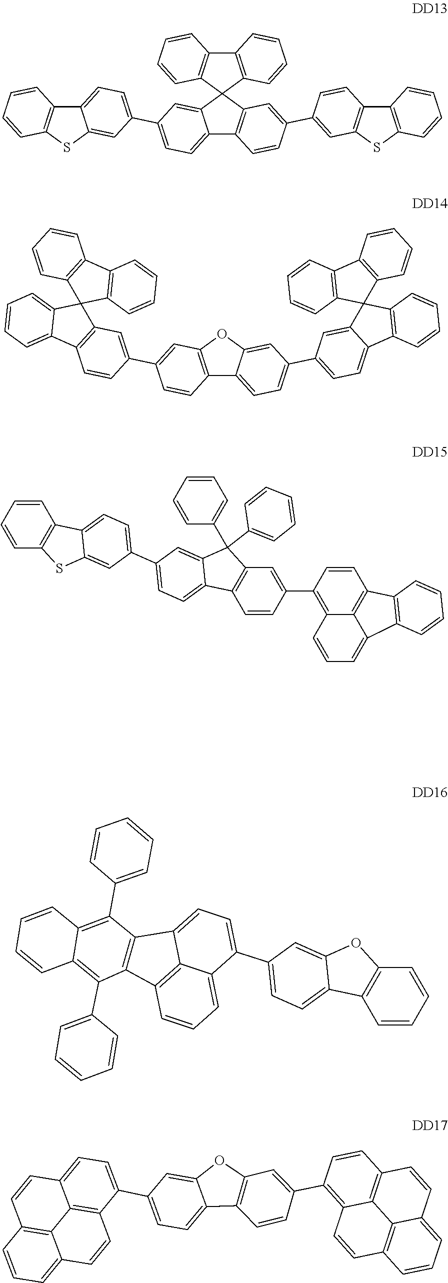

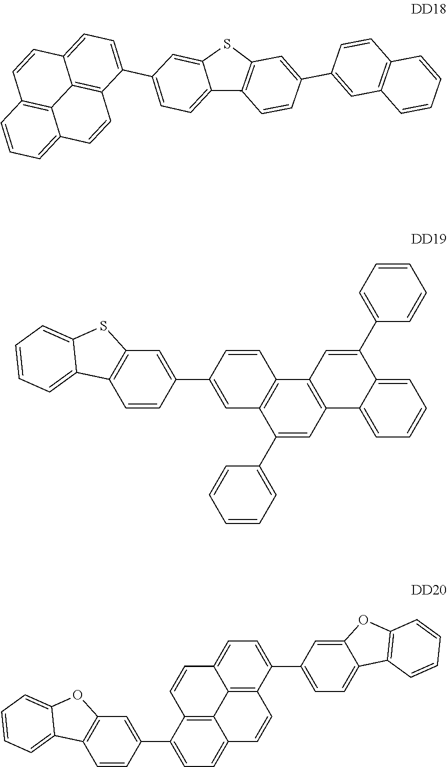

The exemplified compounds belonging to Group AA are each a compound represented by General Formula [I], where X₄ and X₅ each represent a nitrogen atom, and Y represents a carbon atom having substituents R₁ and R₂. That is, Group AA is a group of compounds represented by General Formula [III]. Compounds belonging to this group are characterized by low HOMO levels and high electron mobility.

The exemplified compounds belonging to Group BB are each a compound represented by General Formula [I], where X₄ or X₅ represents a nitrogen atom, and Y represents a carbon atom having substituents R₁ and R₂. That is, Group BB is a group of compounds represented by General Formula [IV]. Compounds belonging to this group are characterized by higher HOMO levels and higher electron mobility than compounds belonging to Group AA.

The exemplified compounds belonging to Group CC are each a compound represented by General Formula [II], where at least one of X₁ to X₈ represents a nitrogen atom. That is, Group CC is a group of compounds represented by General Formula [V]. Compounds belonging to this group have low HOMO levels, but are characterized by low crystallizability, excellent film properties, and high electron mobility.

The exemplified compounds belonging to Group DD are each a compound represented by General Formula [I], where X₄ and X₅ each represent a nitrogen atom, and Y represents an oxygen atom or a sulfur atom. That is, Group DD is a group of compounds represented by General Formula [VI]. Compounds belonging to this group are characterized by high glass transition temperatures, excellent heat resistance, and high electron mobility.

### Other Materials

In the organic light-emitting device according to the present embodiment, known low-molecular-weight and high-molecular-weight hole-injecting or hole-transporting compounds, host compounds, light-emitting compounds, electron-injecting or electron-transporting compounds, and the like may also be used as needed. Examples of these compounds are described below.

A hole injection/transport material is preferably a material having high hole mobility so as to facilitate the injection of holes from the anode and transport the injected holes to the light-emitting layer. To inhibit a deterioration in film quality, such as crystallization, in the organic light-emitting device, a material having a high glass transition temperature is preferred. Examples of low- or high-molecular-weight materials having the ability to inject and/or transport holes include triarylamine derivatives, aryl carbazole derivatives, phenylenediamine derivatives, stilbene derivatives, phthalocyanine derivatives, porphyrin derivatives, poly(vinyl carbazole), polythiophene, and other conductive polymers. Furthermore, the above-mentioned hole injection/transport material is also suitable for use in an electron-blocking layer or a p-type charge generation layer. The following are specific examples of compounds used as the hole injection/transport materials, but the hole injection/transport materials are not limited thereto.

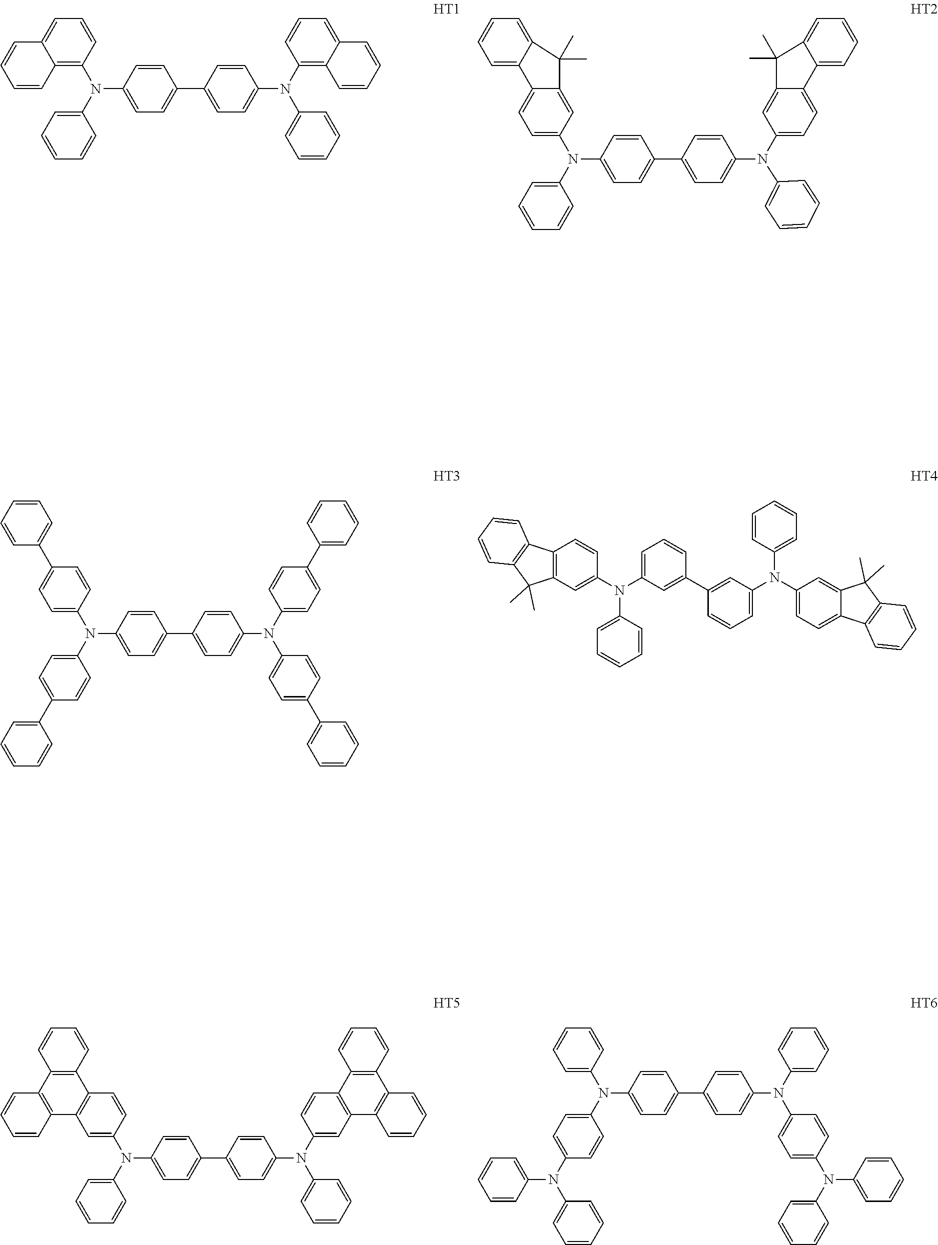

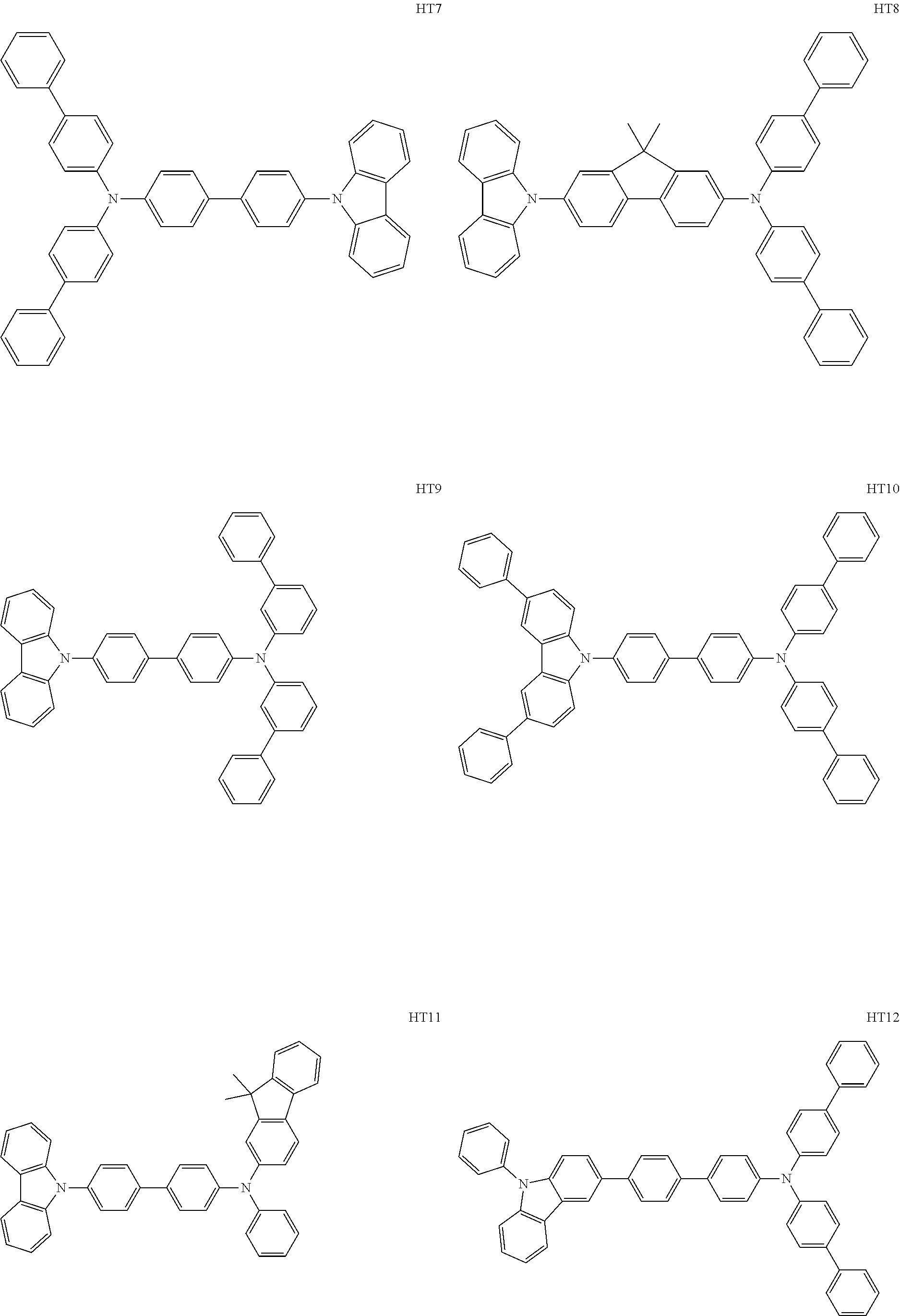

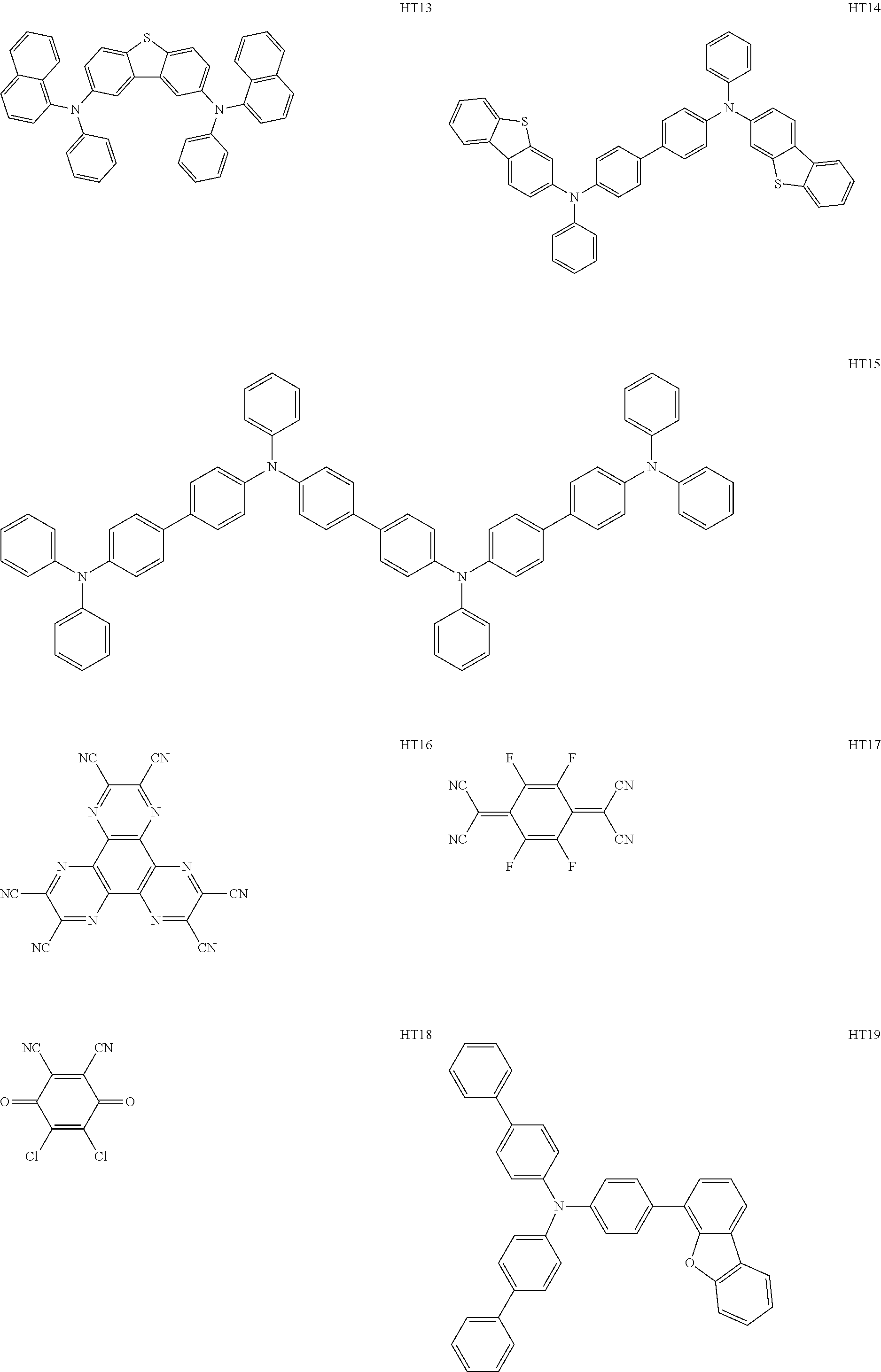

Examples of the light-emitting material mainly related to the light-emitting function include fused-ring compounds, such as fluorene derivatives, naphthalene derivatives, pyrene derivatives, perylene derivatives, tetracene derivatives, anthracene derivatives, and rubrene, quinacridone derivatives, coumarin derivatives, stilbene derivatives, organoaluminum complexes, such as tris(8-quinolinolato)aluminum, iridium complexes, platinum complexes, rhenium complexes, copper complexes, europium complexes, ruthenium complexes, and polymer derivatives, such as poly(phenylene vinylene) derivatives, polyfluorene derivatives, and polyphenylene derivatives. Specific examples of compounds that can be used as light-emitting materials are illustrated below, but the light-emitting materials are not limited to these.

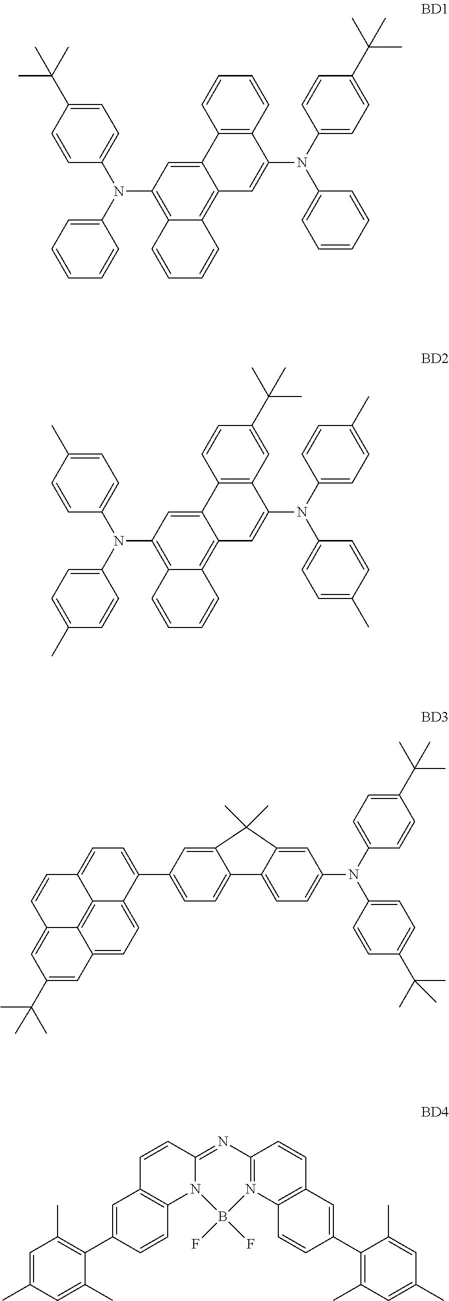

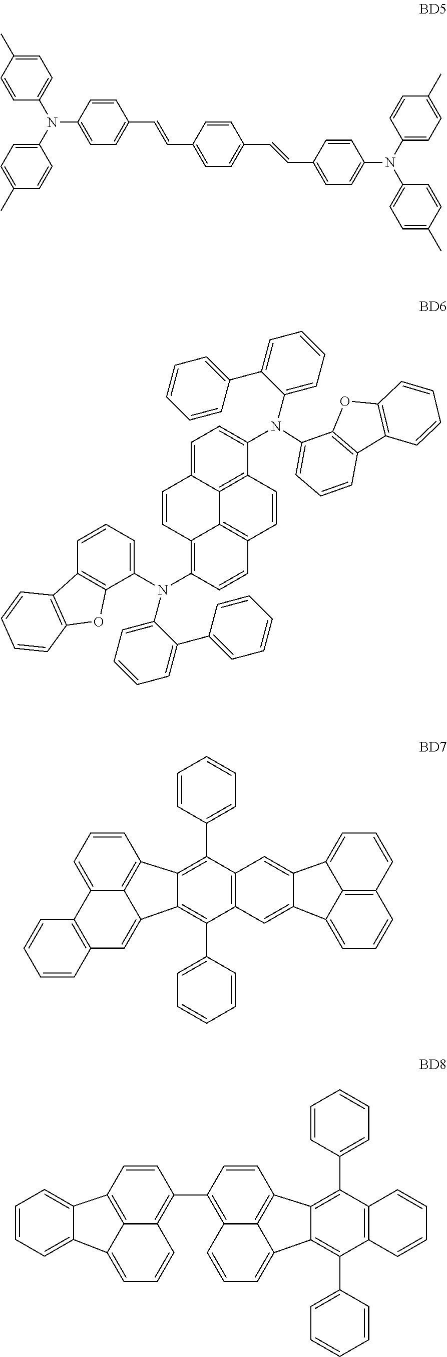

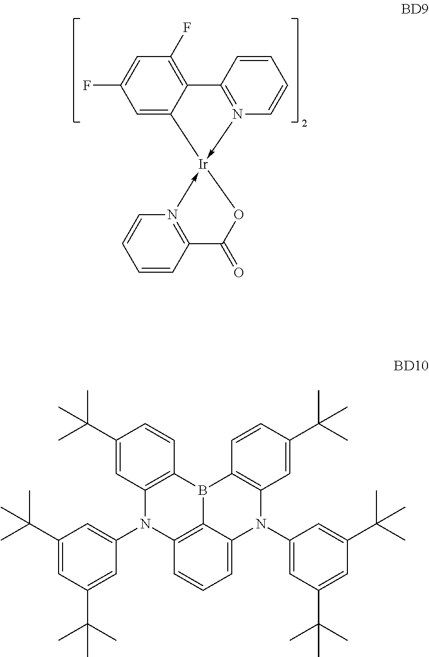

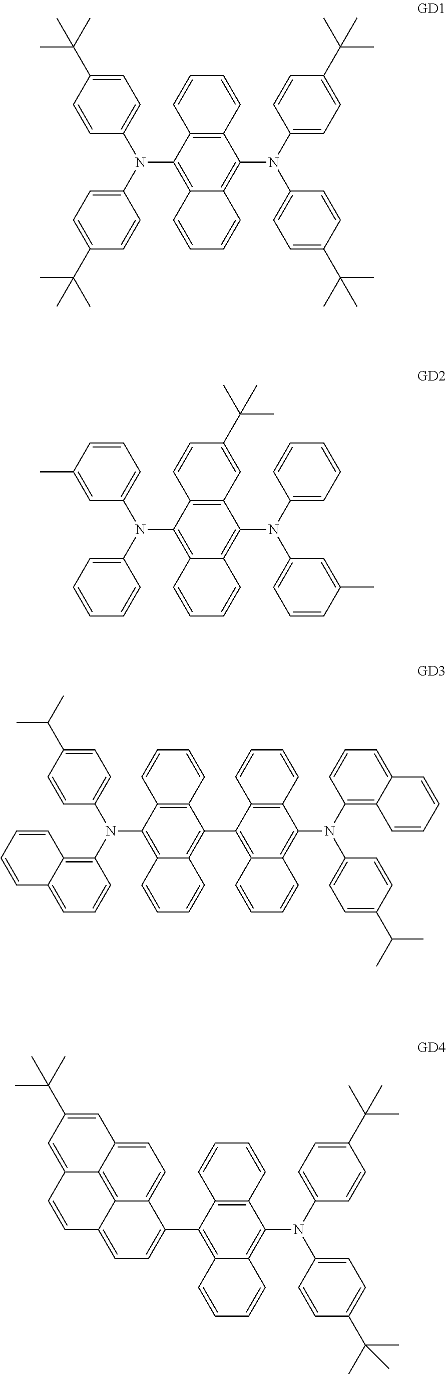

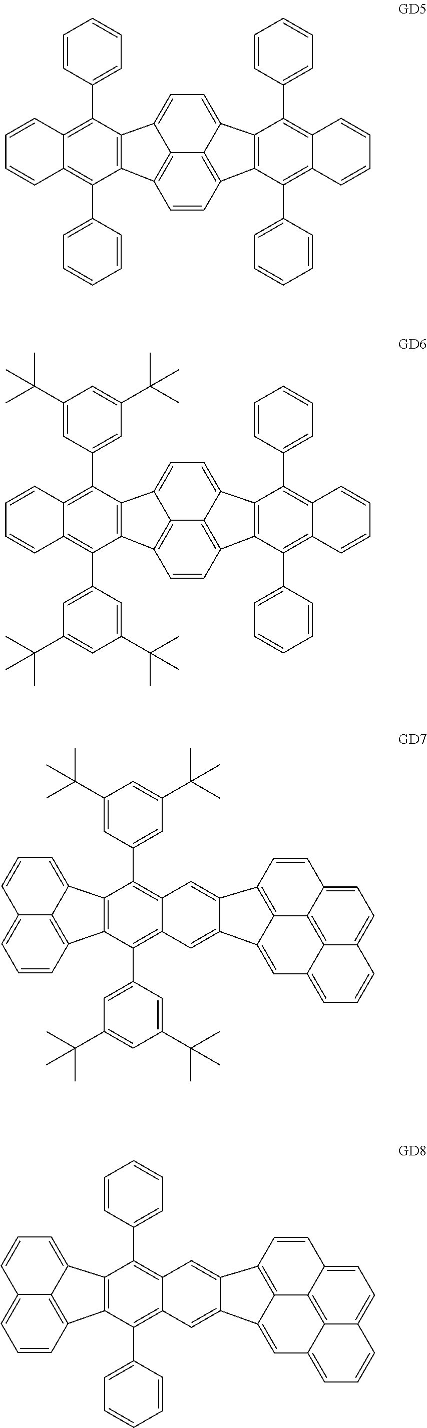

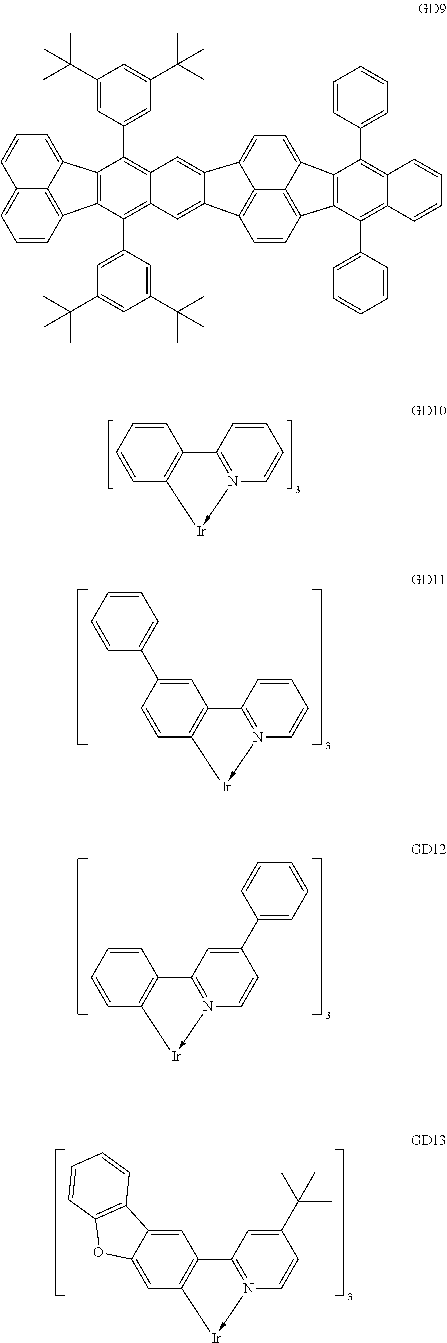

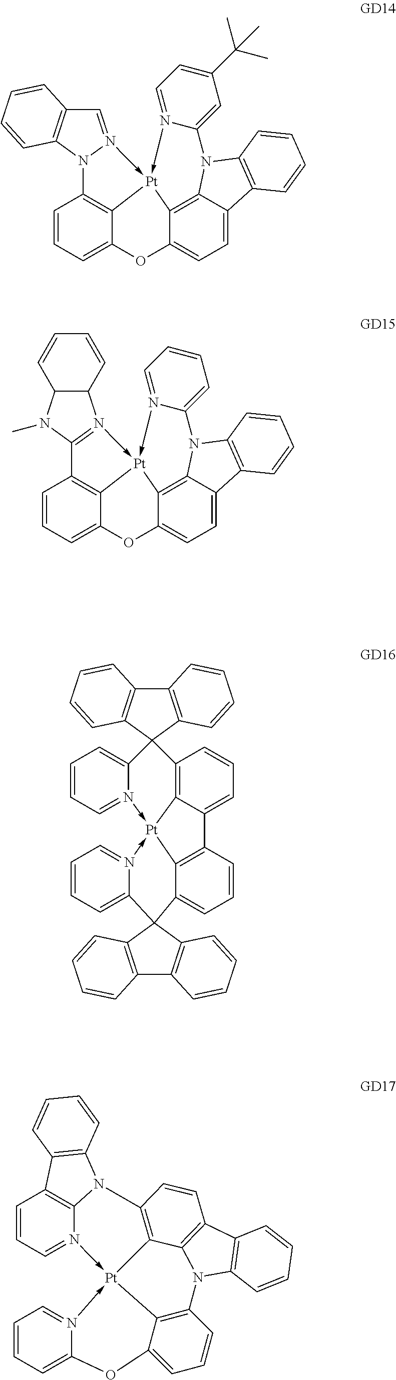

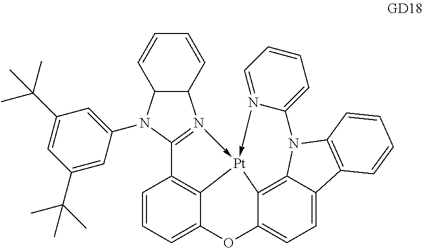

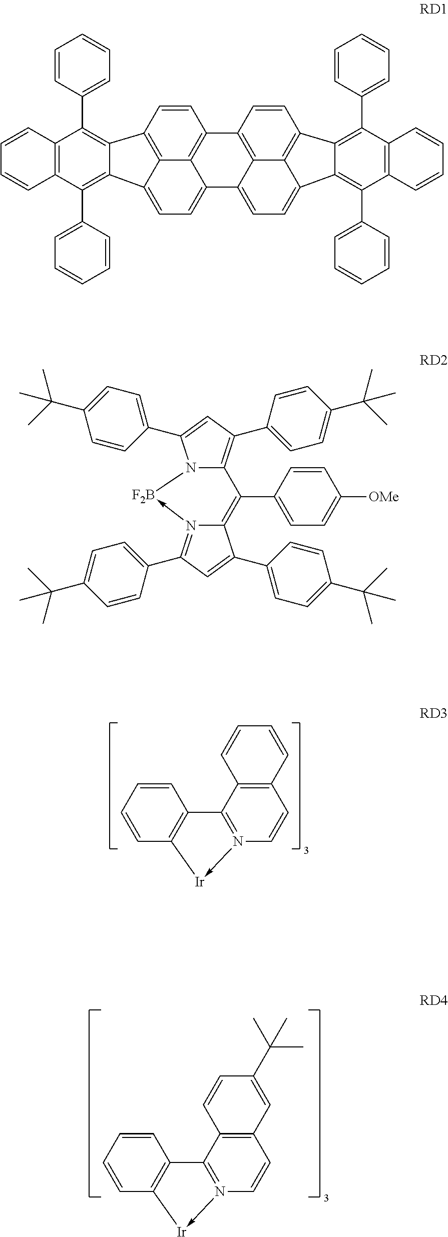

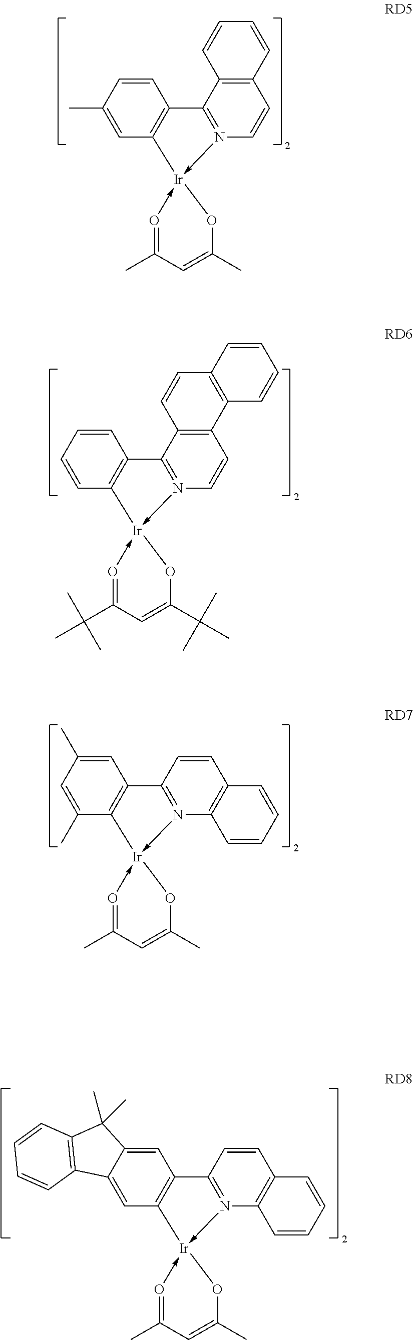

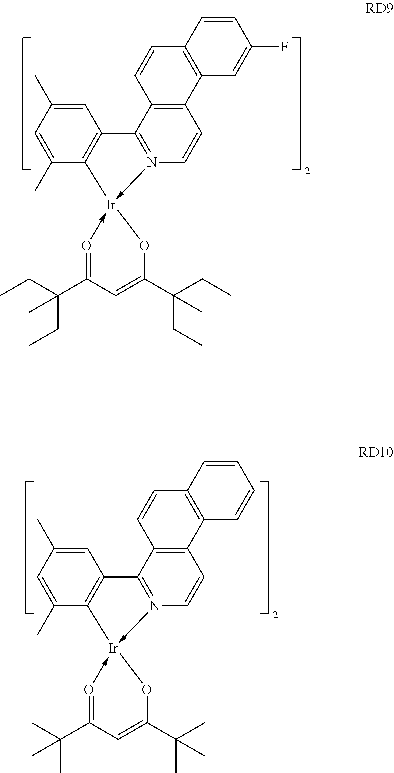

Examples of the third organic compound (host compound) and fourth organic compound (assist compound) contained in the first light-emitting layer, and the fifth organic compound (host compound) and sixth organic compound (assist compound) contained in the second light-emitting layer include, but are not limited to, aromatic hydrocarbon compounds and derivatives thereof, carbazole derivatives, azine derivatives, xanthone derivatives, dibenzofuran derivatives, dibenzothiophene derivatives, organoaluminum complexes, such as tris(8-quinolinolato)aluminum, and organoberyllium complexes. Specific examples are illustrated below.

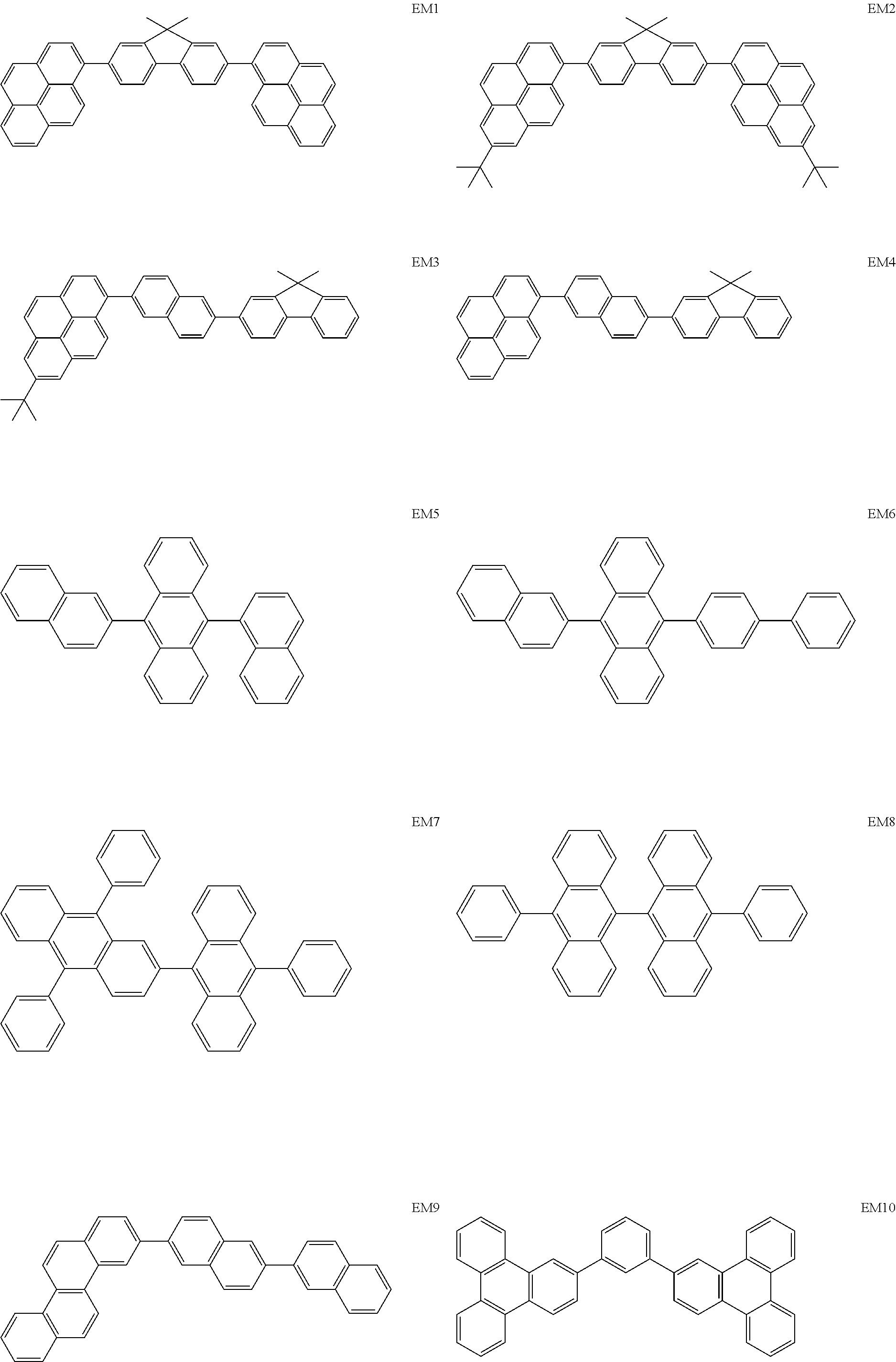

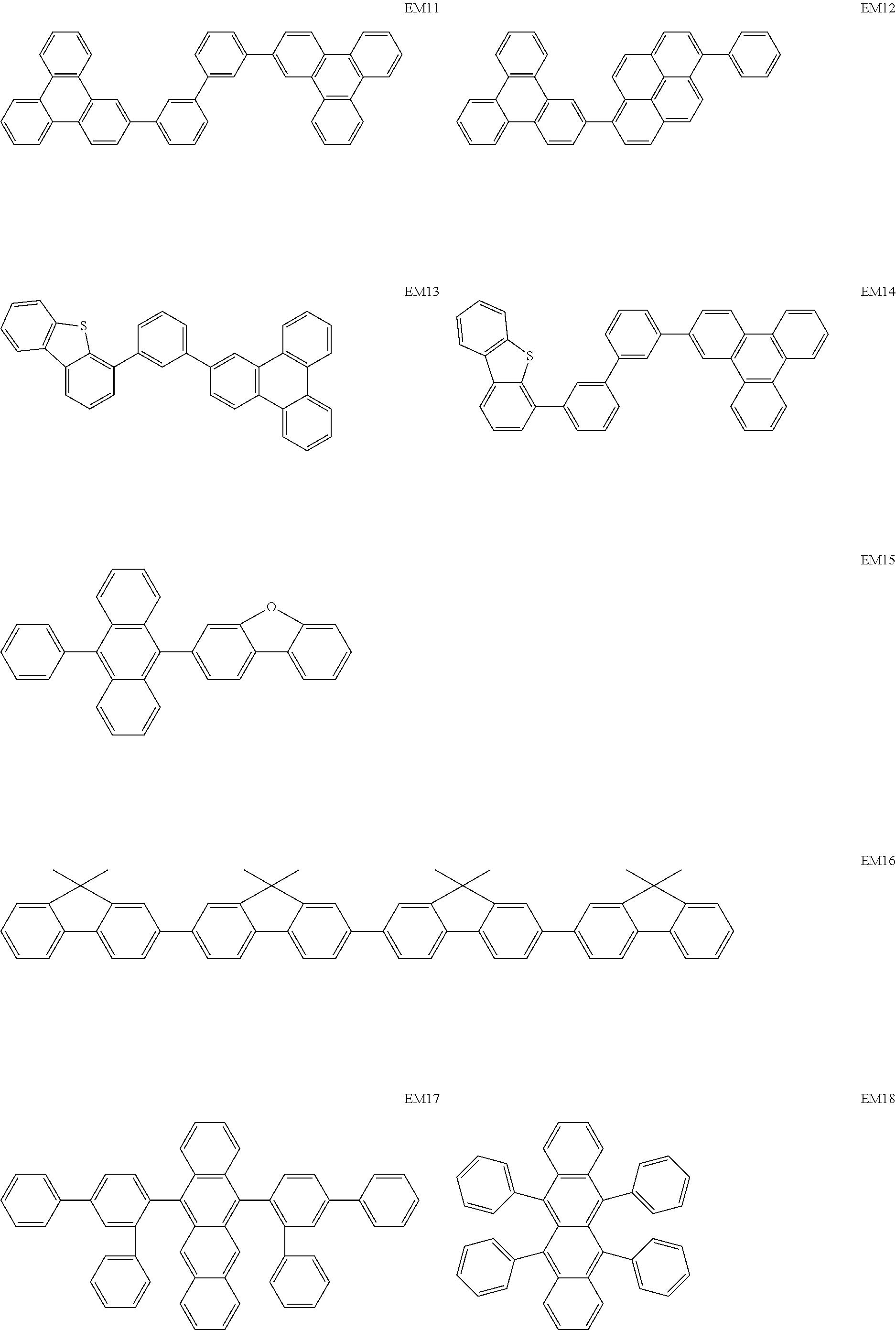

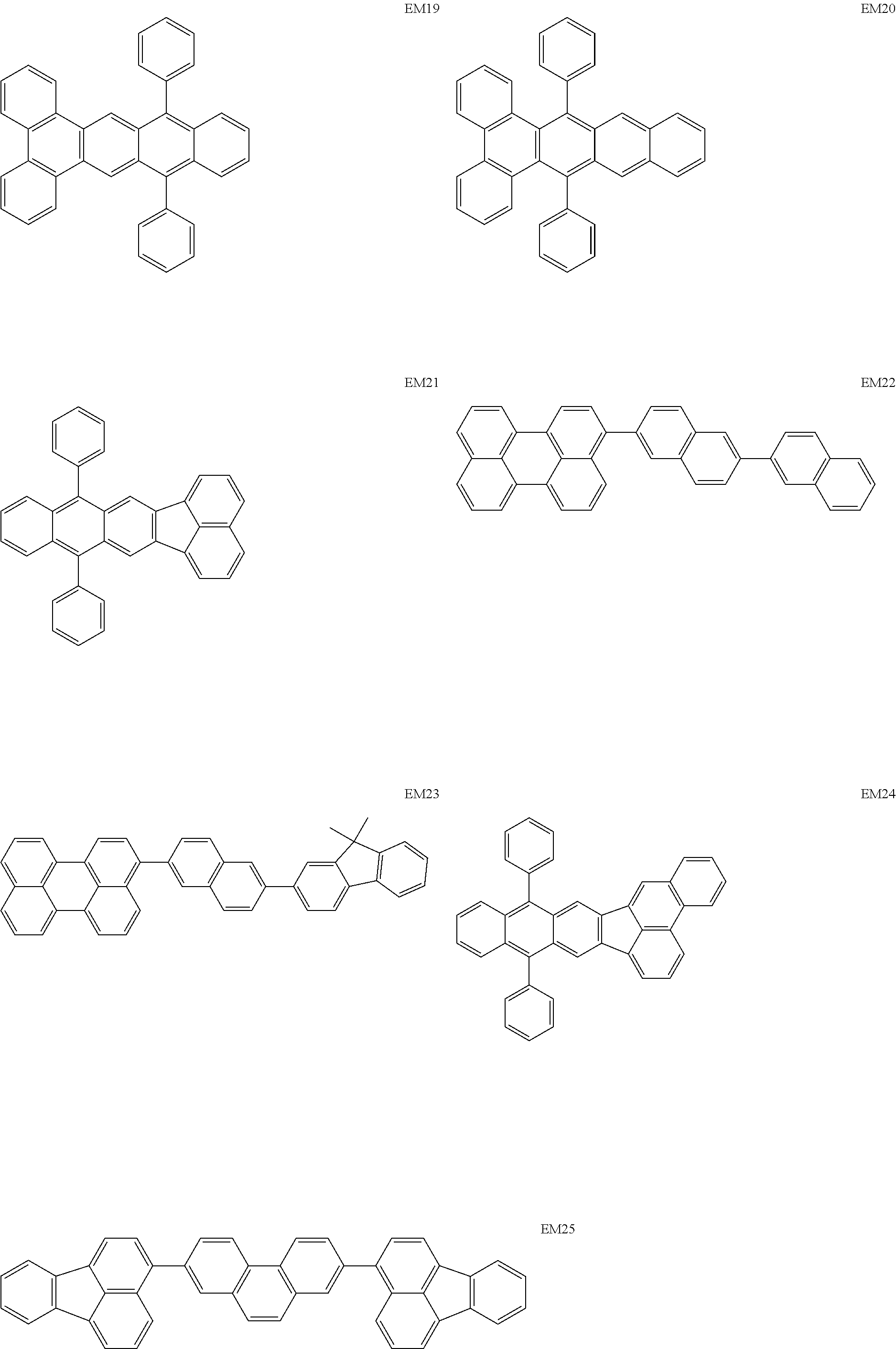

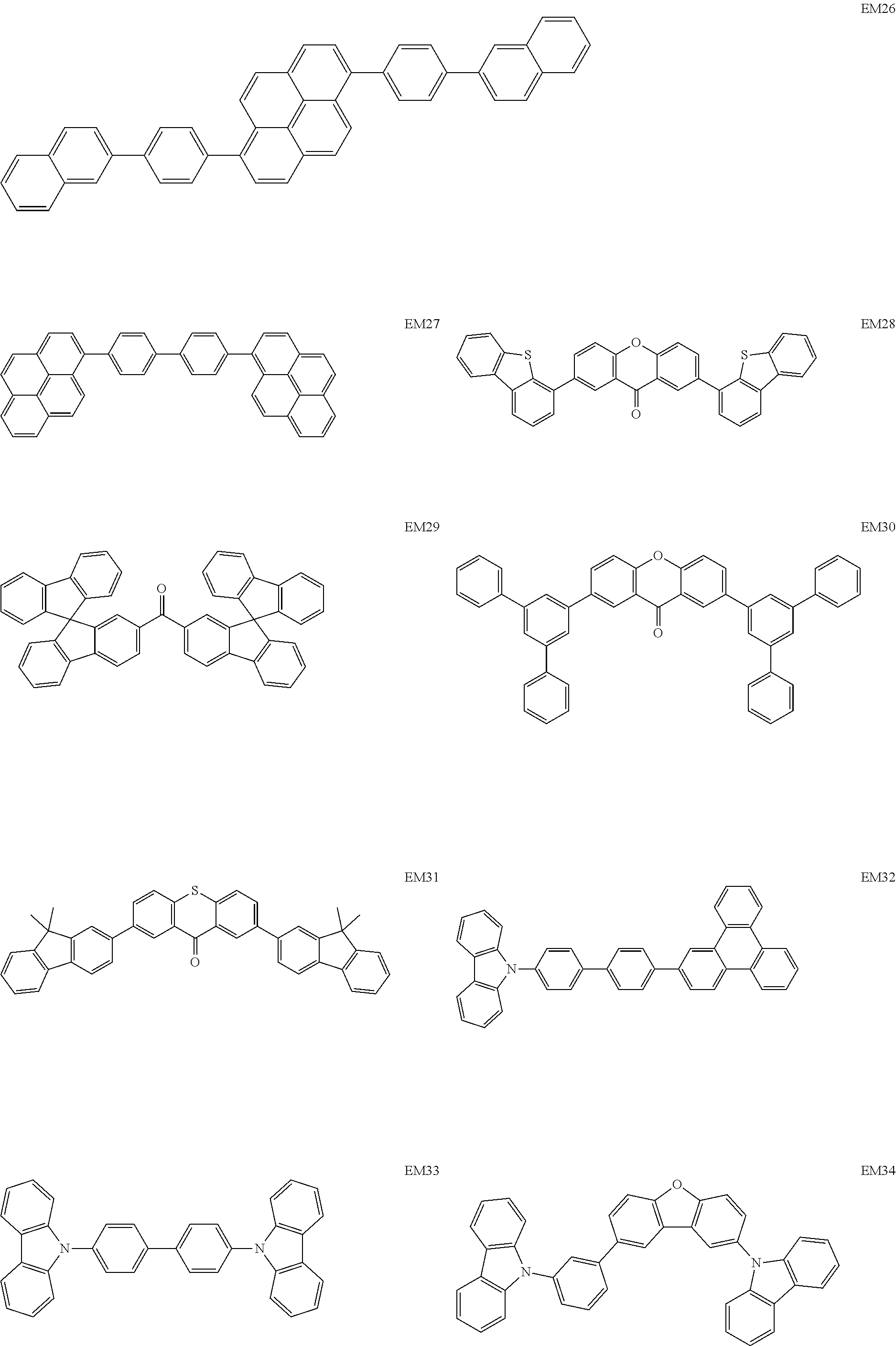

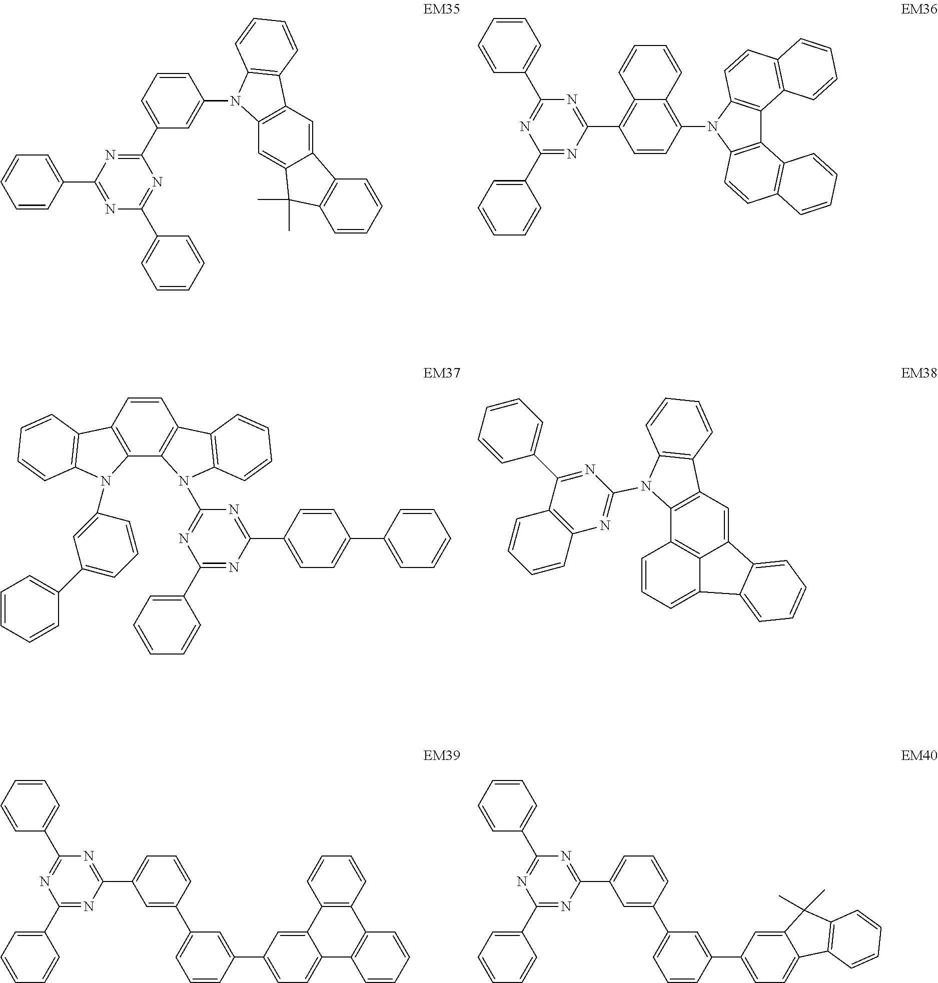 [SMILES: CC1(C)c2ccccc2-c2cc3c4ccccc4n(-c4cccc(-c5nc(-c6ccccc6)nc(-c6ccccc6)n5)c4)c3cc21 ; c1ccc(-c2nc(-c3ccccc3)nc(-c3ccc(-n4c5ccc6ccccc6c5c5c6ccccc6ccc54)c4ccccc34)n2)cc1 ; c1ccc(-c2ccc(-c3nc(-c4ccccc4)nc(-n4c5ccccc5c5ccc6c7ccccc7n(-c7cccc(-c8ccccc8)c7)c6c54)n3)cc2)cc1 ; c1ccc(-c2nc(-n3c4ccccc4c4cc5c6c(cccc6c43)-c3ccccc3-5)nc3ccccc23)cc1 ; c1ccc(-c2nc(-c3ccccc3)nc(-c3cccc(-c4cccc(-c5ccc6c7ccccc7c7ccccc7c6c5)c4)c3)n2)cc1 ; CC1(C)c2ccccc2-c2ccc(-c3cccc(-c4cccc(-c5nc(-c6ccccc6)nc(-c6ccccc6)n5)c4)c3)cc21]

The electron transport material can be freely selected from materials that can transport electrons injected from the cathode to the light-emitting layer and is selected in consideration of, for example, the balance with the hole mobility of the hole transport material. Examples of materials having electron-transport properties include oxadiazole derivatives, oxazole derivatives, pyrazine derivatives, triazole derivatives, triazine derivatives, quinoline derivatives, quinoxaline derivatives, phenanthroline derivatives, naphthyridine derivatives, organoaluminum complexes, and fused-ring compounds, such as fluorene derivatives, naphthalene derivatives, chrysene derivatives, and anthracene derivatives. The above-described electron transport materials can also be suitably used for the hole-blocking layer. Specific examples of compounds used as the electron transport materials are illustrated below, but of course the compounds are not limited thereto. Specific examples are illustrated below.

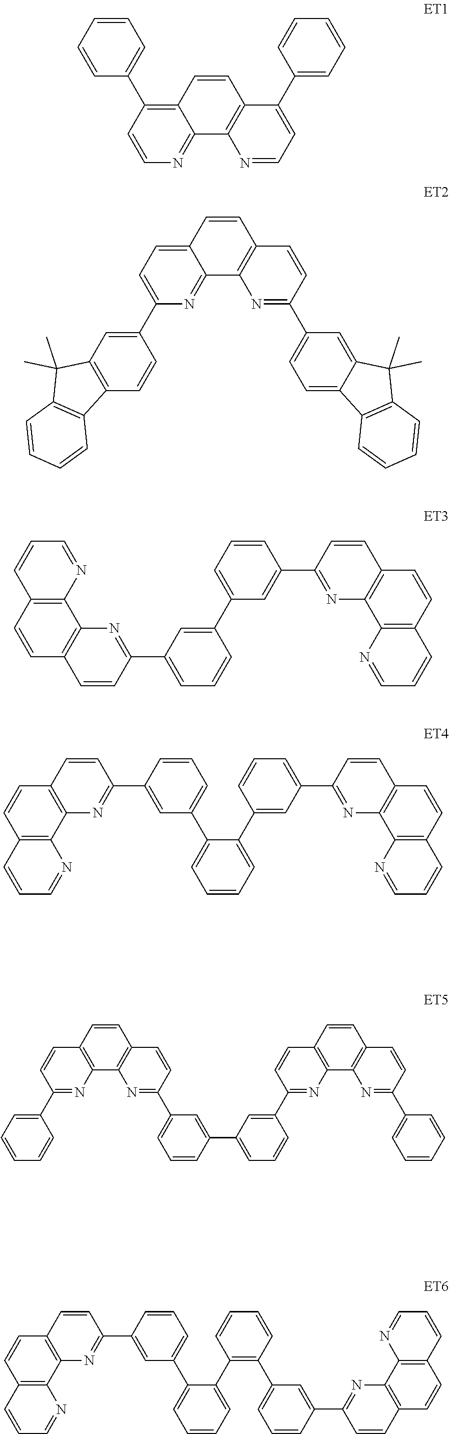

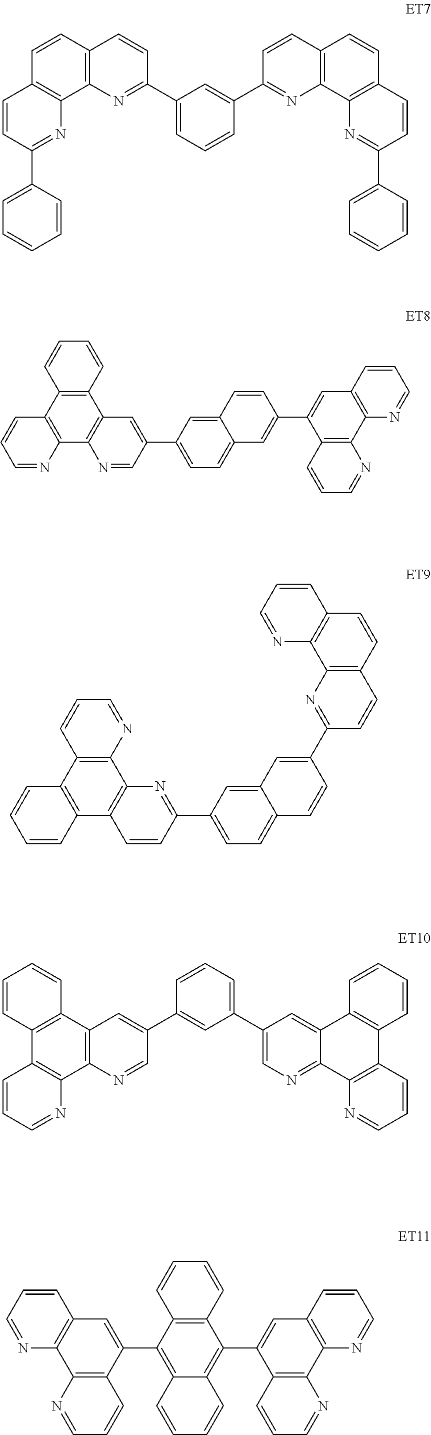 [SMILES: c1ccc(-c2ccc3ccc4ccc(-c5cccc(-c6ccc7ccc8ccc(-c9ccccc9)nc8c7n6)c5)nc4c3n2)cc1 ; c1cnc2c(c1)cc(-c1ccc3cc(-c4cnc5c(c4)c4ccccc4c4cccnc45)ccc3c1)c1cccnc12 ; c1cnc2c(c1)ccc1ccc(-c3ccc4ccc(-c5ccc6c7ccccc7c7cccnc7c6n5)cc4c3)nc12 ; c1cc(-c2cnc3c(c2)c2ccccc2c2cccnc23)cc(-c2cnc3c(c2)c2ccccc2c2cccnc23)c1 ; c1cnc2c(c1)cc(-c1c3ccccc3c(-c3cc4cccnc4c4ncccc34)c3ccccc13)c1cccnc12]

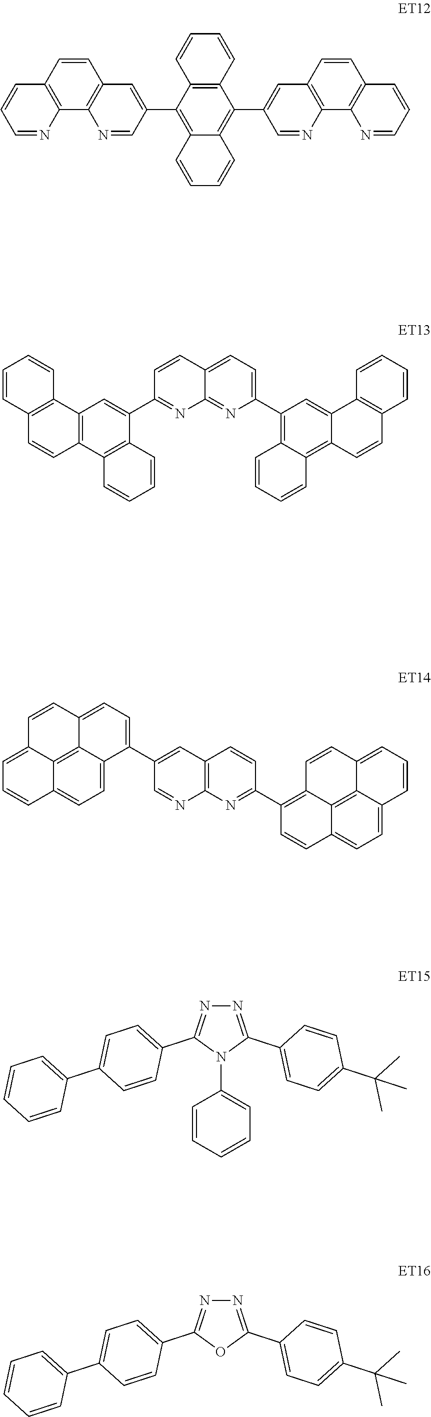 [SMILES: c1cnc2c(c1)ccc1cc(-c3c4ccccc4c(-c4cnc5c(ccc6cccnc65)c4)c4ccccc34)cnc12 ; c1ccc2c(c1)ccc1c3ccccc3c(-c3ccc4ccc(-c5cc6c7ccccc7ccc6c6ccccc56)nc4n3)cc21 ; c1cc2ccc3ccc(-c4cnc5nc(-c6ccc7ccc8cccc9ccc6c7c89)ccc5c4)c4ccc(c1)c2c34 ; CC(C)(C)c1ccc(-c2nnc(-c3ccc(-c4ccccc4)cc3)n2-c2ccccc2)cc1 ; CC(C)(C)c1ccc(-c2nnc(-c3ccc(-c4ccccc4)cc3)o2)cc1]

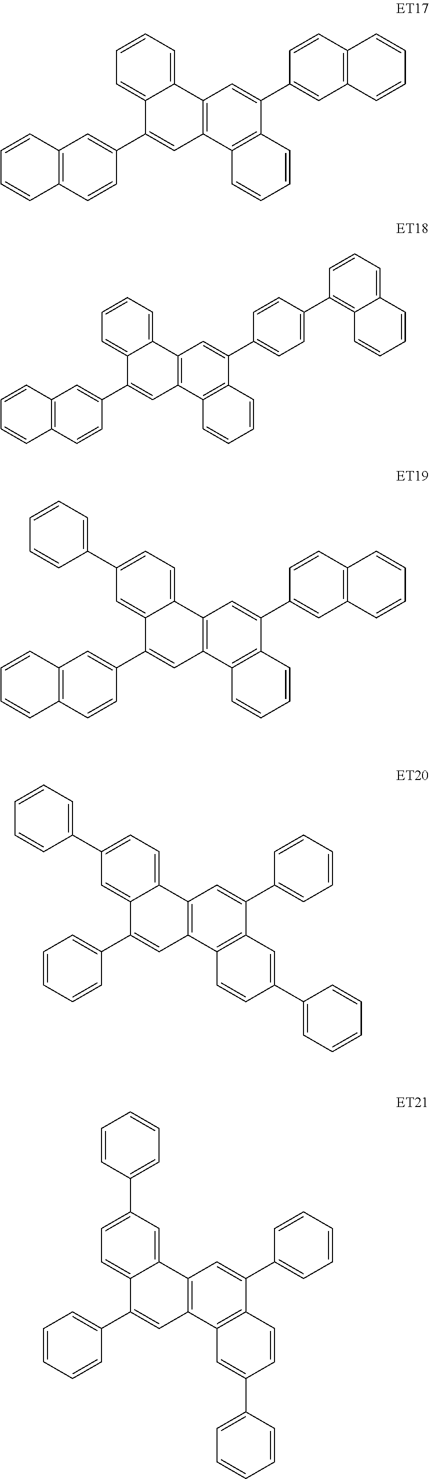

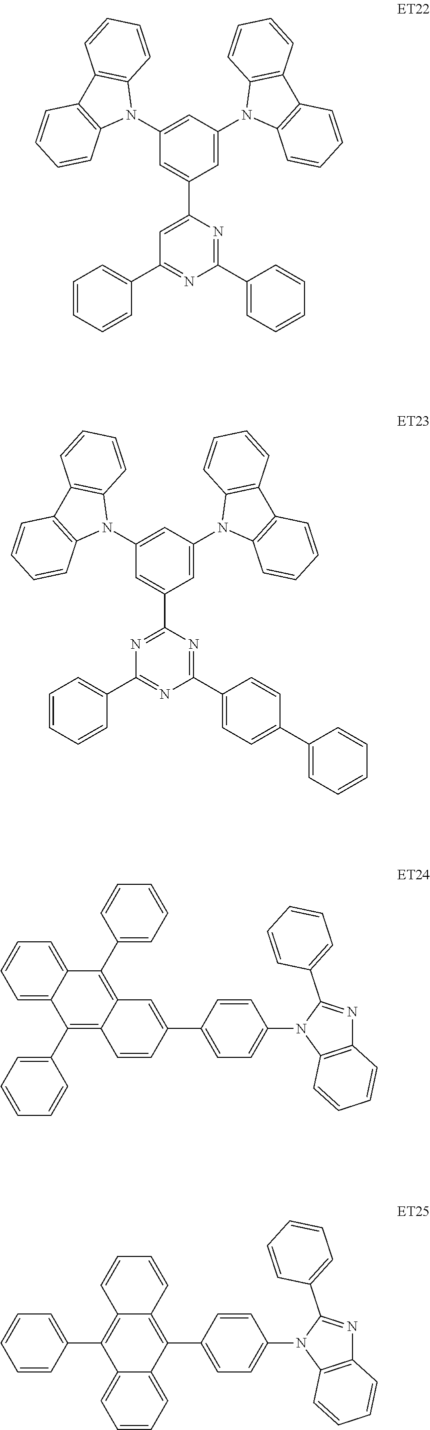 [SMILES: c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2ccc(-c3nc(-c4ccccc4)nc(-c4cc(-n5c6ccccc6c6ccccc65)cc(-n5c6ccccc6c6ccccc65)c4)n3)cc2)cc1 ; c1ccc(-c2c3ccccc3c(-c3ccccc3)c3cc(-c4ccc(-n5c(-c6ccccc6)nc6ccccc65)cc4)ccc23)cc1 ; c1ccc(-c2c3ccccc3c(-c3ccc(-n4c(-c5ccccc5)nc5ccccc54)cc3)c3ccccc23)cc1]

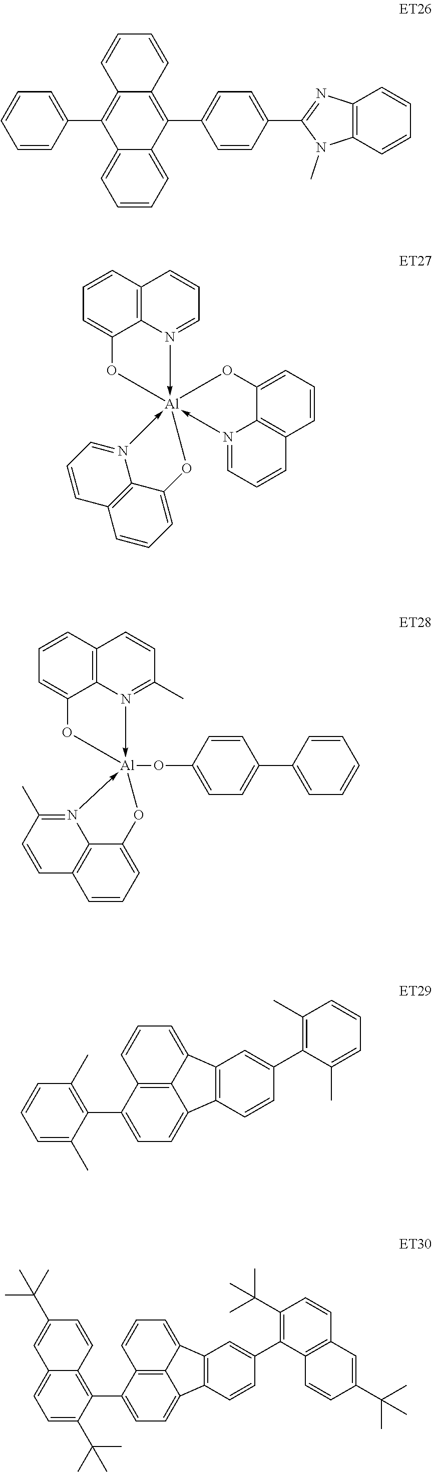

Of the above-exemplified compounds, compounds ET1 to ET21, ET24 to ET26, ET29, and ET30 can be suitably used as the first organic compound in the n-type charge generation layer.

As an electron-injection material, any material that allows for easy electron injection from the cathode can be selected, taking into account the balance with hole-injection properties. As the organic compound, n-type dopants and reducing dopants are also included. Examples thereof include alkali metal-containing compounds, such as lithium fluoride, lithium complexes, such as lithium quinolinolate, benzimidazolidine derivatives, imidazolidine derivatives, fulvalene derivatives, and acridine derivatives. These can also be used in combination with the above electron-transport material.

### Configuration of Organic Light-Emitting Device

An organic light-emitting device usually includes, over a substrate, an insulating layer, a first electrode, organic compound layers, and a second electrode. A protective layer, a color filter, a microlens, and so forth may be disposed over the second electrode. When a color filter is provided, a planarization layer may be provided between the color filter and the protective layer. The planarization layer can be made of an acrylic resin or the like. The same applies when a planarization layer is provided between the color filter and the microlens.

Preferred configurations of the organic light-emitting device according to an embodiment of the present disclosure and an apparatus including the organic light-emitting device will be described below.

### Substrate

The organic light-emitting device according to an embodiment of the present disclosure may be formed on a substrate. Examples of the substrate include quartz substrates, glass substrates, silicon wafers, resin substrates, and metal substrates. The substrate may include a switching element, such as a transistor, a line, and an insulating layer thereon. Any material can be used for the insulating layer as long as a contact hole can be formed in such a manner that a line can be coupled to the first electrode and as long as insulation with a non-connected line can be ensured. For example, a resin, such as polyimide, silicon oxide, or silicon nitride, can be used.

### Electrode

The organic light-emitting device includes a pair of electrodes. When an electric field is applied in the direction in which the organic light-emitting device emits light, an electrode having a higher potential is the anode, and the other is the cathode. It can also be said that the electrode that supplies holes to the light-emitting layer is the anode and that the electrode that supplies electrons is the cathode. In an embodiment of the present disclosure, either the anode or the cathode may be used as the first electrode (substrate side). Usually, as illustrated in FIG. 1, the first electrode 200 on the substrate 1 side is used as the anode, but this is not limitative.

It is preferable for the material constituting the anode to have a work function that is as high as possible. Examples of the material that can be used include elemental metals, such as gold, platinum, silver, copper, nickel, palladium, cobalt, selenium, vanadium, and tungsten, mixtures thereof, alloys of combinations thereof, and metal oxides, such as tin oxide, zinc oxide, indium oxide, indium-tin oxide (ITO), and indium-zinc oxide. Additionally, conductive polymers, such as polyaniline, polypyrrole, and polythiophene, can also be used.

These electrode materials may be used alone or in combination of two or more. The anode may be formed of a single layer or multiple layers.

When the electrode is used as a reflective electrode, for example, chromium, aluminum, silver, titanium, tungsten, molybdenum, an alloy thereof, or a stack thereof can be used. These materials can also be used to act as a reflective film that does not have the role of an electrode. When the electrode is used as a transparent electrode, a transparent conductive oxide layer composed of, for example, indium-tin oxide (ITO) or indium-zinc oxide can be used; however, the electrode is not limited thereto. The electrode can be formed by photolithography.

As a constituent material of the cathode, a material having a small work function is preferred. Examples thereof include elemental metals, such as alkali metals, e.g., lithium, alkaline-earth metals, e.g., calcium, aluminum, titanium, manganese, silver, lead, and chromium, and mixtures containing them. Alternatively, an alloy made by combining these metal elements can also be used. For example, magnesium-silver, aluminum-lithium, aluminum-magnesium, silver-copper, zinc-silver, and so forth can be used. Metal oxides, such as indium-tin oxide (ITO), can also be used. These electrode materials may be used alone or in combination of two or more. The cathode may have a single-layer structure or a multilayer structure. In particular, silver is preferably used. To reduce the aggregation of silver, a silver alloy is more preferred. Any alloy ratio may be used as long as the aggregation of silver can be reduced. The ratio of silver to another metal may be, for example, 1:1 or 3:1.

A top-emission device may be provided using the cathode formed of a conductive oxide layer composed of, for example, ITO. A bottom emission device may be provided using the cathode formed of a reflective electrode composed of, for example, aluminum (A1). The cathode is not particularly limited. A method for forming the cathode is not particularly limited, but a direct-current sputtering method, an alternating-current sputtering method, or the like is more preferably used because good film coverage is obtained and thus the resistance is easily reduced.

### Organic Compound Layer

The first light-emitting unit 300, the charge generation region 400, and the second light-emitting unit 500 illustrated in FIG. 1 are usually called organic compound layers, but the organic compound layers may also include a layer made of an inorganic compound. An insulating layer, an adhesive layer, or an interference layer may be provided at the interface between the first electrode 200 and the first light-emitting unit 300 and the interface between the second electrode 600 and the second light-emitting unit 500.

In a configuration in which multiple organic light-emitting devices are arranged, the organic compound layers may be formed as common layers for the organic light-emitting devices. The common layers are layers that are disposed so as to extend across the organic light-emitting devices, and the common layers can be formed by performing a coating process, such as spin coating, or a vapor-deposition process, over the entire surface of the substrate.

For each organic compound layer included in the organic light-emitting device according to an embodiment of the present disclosure, a dry process, such as a vacuum evaporation method, an ionized evaporation method, sputtering, or a plasma process, can be employed. Alternatively, instead of the dry process, it is also possible to employ a wet process in which a material is dissolved in an appropriate solvent and then a film is formed by a known coating method (for example, spin coating, dipping, a casting method, an LB technique, or an ink jet method).

When the layer is formed by, for example, the vacuum evaporation method or the solution coating method, crystallization and the like are less likely to occur, and good stability with time is obtained. In the case of forming a film by the coating method, the film can be formed in combination with an appropriate binder resin.

Examples of the binder resin include, but are not limited to, polyvinyl carbazole resins, polycarbonate resins, polyester resins, ABS resins, acrylic resins, polyimide resins, phenolic resins, epoxy resins, silicone resins, and urea resins.

These binder resins may be used alone as a homopolymer or copolymer or in combination as a mixture of two or more. Furthermore, additives, such as a known plasticizer, antioxidant, and ultraviolet absorber, may be used, as needed.

### Protective Layer

A protective layer may be disposed on the second electrode. For example, a glass member provided with a moisture absorbent can be bonded to the second electrode to reduce the entry of, for example, water into the organic compound layer, thereby reducing the occurrence of display defects. In another embodiment, a passivation film composed of, for example, silicon nitride may be disposed on the second electrode to reduce the entry of, for example, water into the organic compound layer. For example, after the formation of the second electrode, the substrate may be transported to another chamber without breaking the vacuum, and a silicon nitride film having a thickness of 2 m may be formed by a chemical vapor deposition (CVD) method to provide a protective layer. After the film deposition by the CVD method, a protective layer may be formed by an atomic layer deposition (ALD) method. Examples of the material of the layer formed by the ALD method may include, but are not limited to, silicon nitride, silicon oxide, and aluminum oxide. Silicon nitride may be deposited by the CVD method on the layer formed by the ALD method. The film formed by the ALD method may have a smaller thickness than the film formed by the CVD method. Specifically, it may be 50% or less, or even 10% or less.

### Color Filter

A color filter may be disposed on the protective layer. For example, a color filter may be disposed on another substrate in consideration of the size of the organic light-emitting device and bonded to the substrate provided with the organic light-emitting device. A color filter may be formed by patterning on the protective layer using photolithography. The color filter may be composed of a polymer.

### Planarization Layer

A planarization layer may be disposed between the color filter and the protective layer. The planarization layer is provided for the purpose of reducing the unevenness of the layer underneath. The planarization layer may be referred to as a material resin layer without limiting its purpose. The planarization layer may be composed of an organic compound, may have a low- or high-molecular-weight compound, and is preferably a high-molecular-weight compound.

The planarization layers may be disposed above and below the color filter and may be composed of the same or different constituent materials. Specific examples thereof include poly(vinyl carbazole) resins, polycarbonate resins, polyester resins, acrylonitrile-butadiene-styrene (ABS) resins, acrylic resins, polyimide resins, phenolic resins, epoxy resins, silicone resins, and urea resins.

### Microlens

The organic light-emitting device, or an organic light-emitting apparatus including the organic light-emitting device, may have an optical member, such as a microlens, on its light emission side. The microlens can be made of acrylic resin, epoxy resin, or the like. The microlens may be used to increase the amount of light emitted from the organic light-emitting device or organic light-emitting apparatus and to control the direction of the light emitted. The microlens may have a hemispherical shape. In the case of a hemispherical shape, among tangents to the hemisphere, there is a tangent parallel to the insulating layer. The point of contact of the tangent with the hemisphere is the vertex of the microlens. The vertex of the microlens can be determined in the same way for any cross-sectional view. That is, among the tangents to the semicircle of the microlens in the cross-sectional view, there is a tangent parallel to the insulating layer, and the point of contact of the tangent with the semicircle is the vertex of the microlens.

The midpoint of the microlens can be defined. In the cross section of the microlens, when a segment is hypothetically drawn from the point where an arc shape ends to the point where another arc shape ends, the midpoint of the segment can be referred to as the midpoint of the microlens. The cross section to determine the vertex and midpoint may be a cross section perpendicular to the insulating layer.

### Opposite Substrate

An opposite substrate may be disposed on the planarization layer. The opposite substrate is disposed at a position corresponding to the substrate described above and thus is called an opposite substrate. The material constituting the opposite substrate may be the same as that of the aforementioned substrate (the substrate on the first electrode side). When the above-described substrate is referred to as a first substrate, the opposite substrate may be referred to as a second substrate.

### Pixel Circuit

The organic light-emitting apparatus including the organic light-emitting device may include the pixel circuit connected to the organic light-emitting device. The pixel circuit may be of an active matrix type that independently controls the light emission of the first light-emitting device and the second light-emitting device. The active matrix-type circuit may be voltage-programmed or current-programmed. A driving circuit includes the pixel circuit for each pixel. The pixel circuit may include a light-emitting device, a transistor to control the luminance of emission light from the light-emitting device, a transistor to control the timing of the light emission, a capacitor to retain the gate voltage of the transistor to control the luminance of emission light, and a transistor to connect to GND without using the light-emitting device.

The light-emitting apparatus includes a display area and a peripheral area disposed around the display area. The display area includes a pixel circuit, and the peripheral area includes a display control circuit. The mobility of a transistor contained in the pixel circuit may be lower than the mobility of a transistor contained in the display control circuit. The slope of the current-voltage characteristics of the transistor contained in the pixel circuit may be smaller than the slope of the current-voltage characteristics of the transistor contained in the display control circuit. The slope of the current-voltage characteristics can be measured by what is called Vg-Ig characteristics. The transistor contained in the pixel circuit is a transistor coupled to a light-emitting device, such as a first light-emitting device.

### Pixel

An organic light-emitting apparatus including an organic light-emitting device may include multiple pixels. Each pixel includes subpixels configured to emit colors different from each other. The subpixels may have respective RGB emission colors.

Light emerges from a region of the pixel, also called a pixel aperture. The pixel aperture may be 15 μm or less, and may be 5 μm or more. More specifically, the pixel aperture may be, for example, 11 μm, 9.5 μm, 7.4 μm, or 6.4 μm. The distance between subpixels may be 10 μm or less. Specifically, the distance may be 8 μm, 7.4 μm, or 6.4 μm.

The pixels may be arranged in a known configuration in plan view. For example, a stripe pattern, a delta pattern, a PenTile matrix pattern, or the Bayer pattern may be used. The shape of each subpixel in plan view may be any known shape. Examples thereof include quadrilaterals, such as rectangles and rhombi, and hexagons. Of course, if the shape is close to a rectangle, rather than an exact shape, it is included in the rectangle. The shape of the subpixel and the pixel arrangement can be used in combination.

### Application of Organic Light-Emitting Device

The organic light-emitting device according to an embodiment of the present disclosure can be used as a component of a display apparatus or a lighting apparatus. Other applications include exposure light sources for electrophotographic image-forming apparatuses, backlights for liquid crystal display apparatuses, and light-emitting apparatuses including white light sources provided with color filters.

The display apparatus may be an image information-processing apparatus including an image input unit that receives image information from an area CCD, a linear CCD, a memory card, or the like, an information-processing unit that processes the input information, and a display unit that displays the input image. The display apparatus includes multiple pixels, and at least one of the multiple pixels includes the organic light-emitting device of the present embodiment and may include a transistor coupled to the organic light-emitting device.

The display unit of an image pickup apparatus or an ink jet printer may have a touch panel function. The driving method for the touch panel function may be, but is not particularly limited to, an infrared method, an electrostatic capacitive method, a resistive-film method, or an electromagnetic inductive method. The display apparatus may also be used for a display unit of a multifunction printer.

The following describes a display apparatus according to the present embodiment with reference to the attached drawings.

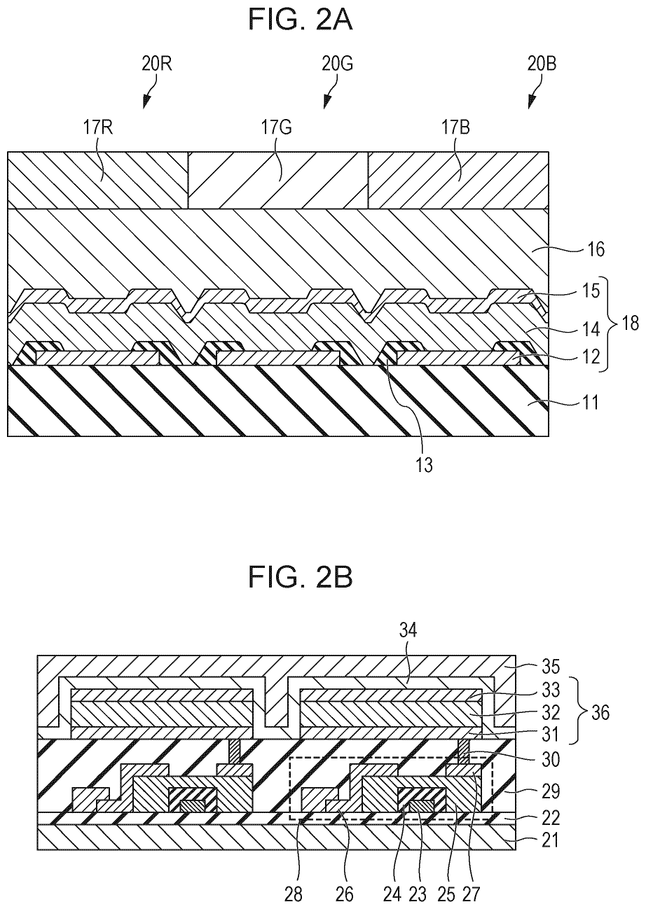

FIGS. 2A and 2B are schematic cross-sectional views each illustrating an example of a display apparatus including organic light-emitting devices according to an embodiment of the present disclosure and transistors coupled to the respective organic light-emitting devices.

FIG. 2A illustrates an example of pixels that are constituent elements of the display apparatus according to the present embodiment. Each of the pixels includes subpixels 20. The subpixels are divided into 20R, 20G, and 20B according to their light emission. The emission colors may be distinguished by the wavelength of light emitted from the light-emitting layer. Light emitted from the subpixels may be selectively transmitted or color-converted with, for example, a color filter. Each subpixel includes a first electrode 12 serving as a reflective electrode on an interlayer insulating layer 11, an insulating layer 13 covering the edge of the first electrode 12, an organic compound layer 14 covering the first electrode 12 and the insulating layer 13, a second electrode 15, a protective layer 16, and a color filter 17. The first electrode 12, the organic compound layer 14, and the second electrode 15 constitute an organic light-emitting device 18 of the present embodiment.

The transistors and capacitive elements may be disposed under or in the interlayer insulating layer 11. Each transistor may be electrically coupled to a corresponding one of the first electrodes 12 through, for example, a contact hole (not illustrated).

The insulating layer 13 is also referred to as a bank or pixel separation film. The insulating layer covers the edge of each first electrode 12 and surrounds the first electrode 12. Portions that are not covered with the insulating layer 13 are in contact with the organic compound layer 14 and serve as light-emitting regions.

The second electrode 15 may be a transparent electrode, a reflective electrode, or a semi-transparent electrode.

The protective layer 16 reduces the penetration of moisture into the organic compound layer 14. Although the protective layer 16 is illustrated as a single layer, the protective layer 16 may be formed of multiple layers. Each layer may be an inorganic compound layer or an organic compound layer.

The color filter 17 is separated into 17R, 17G, and 17B according to its color. The color filter 17 may be disposed on a planarization film, which is not illustrated. A resin protective layer, which is not illustrated, may be disposed on the color filter 17. The color filter 17 may also be formed on the protective layer 16. Alternatively, the color filter 17 may be disposed on an opposite substrate, such as a glass substrate, and then bonded.

A display apparatus illustrated in FIG. 2B includes organic light-emitting devices 36 and TFTs 28 as an example of transistors. An insulating layer 22 is disposed on a substrate 21 made of, for example, glass or silicon. TFTs 28 each including a gate electrode 23, a gate insulating film 24, a semiconductor layer 25, a drain electrode 26, and a source electrode 27 are arranged on the insulating layer 22. An insulating film 29 is provided on the TFTs 28. An anode 31 constituting the organic light-emitting devices 36 is coupled to the source electrodes 27 through contact holes 30 provided in the insulating film 29.

The mode of electrical connection between the electrodes (anode 31 and cathode 33) included in each organic light-emitting device 36 and the electrodes (source electrode 27 and drain electrode 26) included in a corresponding one of the TFTs 28 is not limited to the mode illustrated in FIG. 2B. That is, it is sufficient that any one of the anode 31 and the cathode 33 be electrically coupled to any one of the source electrode 27 and the drain electrode 26. The TFTs 28 refer to thin-film transistors.

A first protective layer 34 and a second protective layer 35 are disposed on the cathodes 33 in order to reduce the deterioration of the organic light-emitting devices.

In the organic light-emitting devices 36 according to the present embodiment, the luminance is controlled by the TFTs; thus, an image can be displayed at respective luminance levels by arranging multiple organic light-emitting devices 36 in the plane.

Although the transistors are used as switching elements in the display apparatus illustrated in FIG. 2B, other switching elements may be used instead.

The transistors used in the display apparatus illustrated in FIG. 2B are not limited to TFTs with an active layer on an insulating surface of the substrate; transistors using single-crystal silicon wafer may also be used. The active layer may also be a non-single-crystal silicon, such as amorphous silicon or microcrystalline silicon, or a non-single-crystal oxide semiconductor, such as indium-zinc oxide or indium-gallium-zinc oxide.

Additionally, the transistors may be transistors made of low-temperature polysilicon or active-matrix drivers formed on a substrate, such as a Si substrate. The expression “on a substrate” can also be said to be “in the substrate”. Whether transistors are formed in the substrate or TFTs are used is selected in accordance with the size of a display unit. For example, when the display unit has a size of about 0.5 inches, organic light-emitting devices are preferably disposed on a Si substrate. The expression “formed in the substrate” indicates that the transistors are produced by processing the substrate, such as a Si substrate. When the transistors are formed in the substrate, the substrate and the transistors can be deemed to be integrally formed.

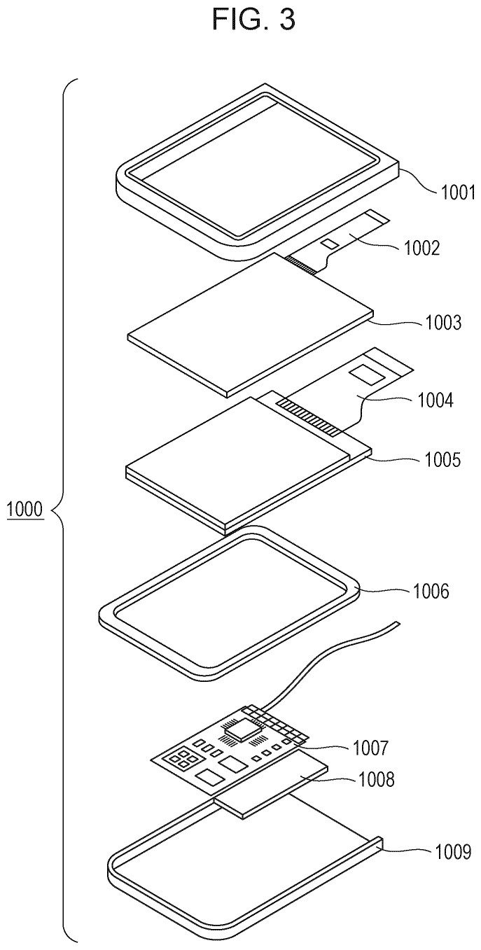

FIG. 3 is a schematic view of an example of a display apparatus according to an embodiment of the present disclosure. A display apparatus 1000 includes, between an upper cover 1001 and a lower cover 1009, a touch panel 1003, a display panel 1005, a frame 1006, a circuit substrate 1007, and a battery 1008. The touch panel 1003 and the display panel 1005 are coupled to flexible printed circuits FPCs 1002 and 1004, respectively. The circuit substrate 1007 includes printed transistors. The battery 1008 need not be provided unless the display apparatus is a portable apparatus. The battery 1008 may be disposed at a different position even if the display apparatus is a portable apparatus.

The display apparatus according to the present embodiment may include a color filter having red, green, and blue portions. In the color filter, the red, green, and blue portions may be arranged in a delta arrangement.

The display apparatus according to the present embodiment is used for the display unit of a portable terminal. In that case, the display apparatus may have both a display function and an operation function. Examples of the portable terminal include mobile phones, such as smartphones, tablets, and head-mounted displays.

The display apparatus according to the present embodiment is used for a display unit of an image pickup apparatus including an optical unit including multiple lenses and an image pickup device that receives light passing through the optical unit. The image pickup apparatus may include a display unit that displays information acquired by the image pickup device. The display unit may be a display unit exposed to the outside of the image pickup apparatus or may be a display unit disposed in a finder. The image pickup apparatus may be a digital camera or a digital camcorder.

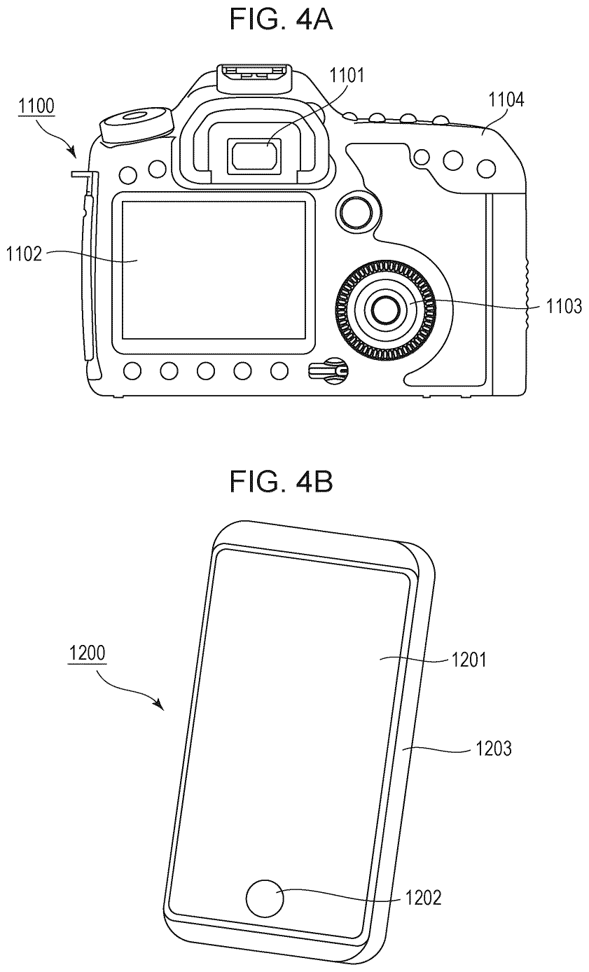

FIG. 4A is a schematic view of an example of an image pickup apparatus according to an embodiment of the present disclosure. An image pickup apparatus 1100 includes a viewfinder 1101, a rear display 1102, an operation unit 1103, and a housing 1104. The viewfinder 1101 includes the display apparatus according to the present embodiment. In this case, the display apparatus may display environmental information, imaging instructions, and so forth in addition to an image to be captured. The environmental information may include, for example, the intensity of external light, the direction of the external light, the moving speed of a subject, and the possibility that the subject will be shielded by an obstacle.

The timing suitable for imaging is only for a short time; thus, it is better to display the information as soon as possible. Thus, a display apparatus including the organic light-emitting device according to the present disclosure is preferably used. This is because organic light-emitting devices have a fast response time. The display apparatus including the organic light-emitting device can be used more suitably than liquid crystal display apparatuses for such apparatuses required to have a high display speed.

The image pickup apparatus 1100 includes an optical unit, which is not illustrated. The optical unit includes multiple lenses and is configured to form an image on an image pickup device in the housing 1104. The relative positions of the multiple lenses can be adjusted to adjust the focal point. This operation can also be performed automatically. The image pickup apparatus may also be referred to as a photoelectric conversion apparatus. Examples of an image capturing method employed in the photoelectric conversion apparatus can include a method for detecting a difference from the previous image and a method for cutting out an image from images always recorded, instead of sequentially capturing images.

FIG. 4B is a schematic view of an example of an electronic apparatus according to an embodiment of the present disclosure. An electronic apparatus 1200 includes a display unit 1201, an operation unit 1202, and a housing 1203. The housing 1203 may accommodate a circuit, a printed circuit board including the circuit, a battery, and a communication unit. The operation unit 1202 may be a button or a touch-panel-type reactive unit. The operation unit may be a biometric recognition unit that recognizes fingerprints to perform functions, such as unlocking. An electronic apparatus including a communication unit can also be referred to as a communication apparatus. The electronic apparatus may further have a camera function by including a lens and an image pickup device. An image captured by the camera function is displayed on the display unit. Examples of the electronic apparatus include smartphones and laptop computers.

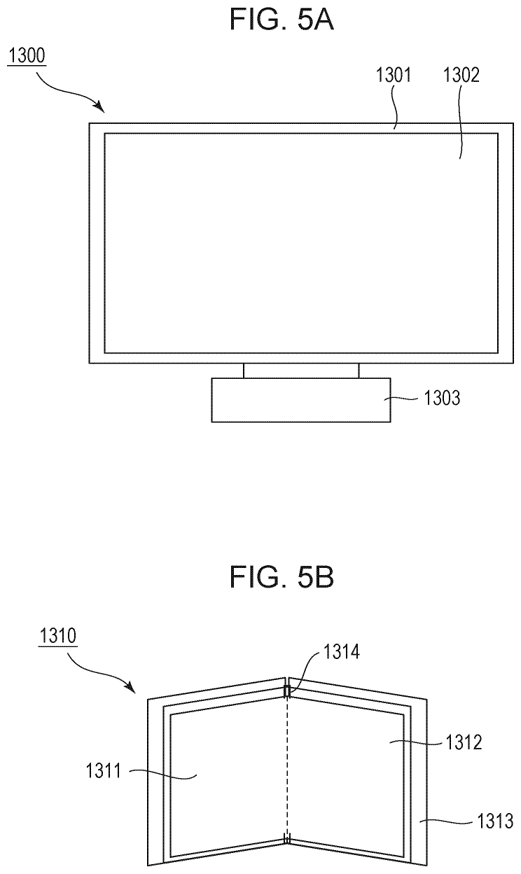

FIGS. 5A and 5B are each a schematic view of an example of a display apparatus according to an embodiment of the present disclosure. FIG. 5A illustrates a display apparatus, such as a television monitor or a PC monitor. A display apparatus 1300 includes a frame 1301 and a display unit 1302. The display unit 1302 includes a light-emitting apparatus according to an embodiment of the present disclosure. The frame 1301 and the display unit 1302 are supported by a base 1303. The base 1303 is not limited to a form illustrated in FIG. 5A. The lower side of the frame 1301 may also serve as a base. The frame 1301 and the display unit 1302 may be curved. The radius of curvature may be 5,000 mm or more and 6,000 mm or less.

FIG. 5B is a schematic view of another example of a display apparatus according to an embodiment of the present disclosure. A display apparatus 1310 illustrated in FIG. 5B can be folded and is what is called a foldable display apparatus. The display apparatus 1310 includes a first display unit 1311, a second display unit 1312, a housing 1313, and an inflection point 1314. The first display unit 1311 and the second display unit 1312 each include a light-emitting apparatus according to an embodiment of the present disclosure. The first display unit 1311 and the second display unit 1312 may be a single, seamless display apparatus. The first display unit 1311 and the second display unit 1312 can be divided from each other at the inflection point. The first display unit 1311 and the second display unit 1312 may display different images from each other. Alternatively, a single image may be displayed in the first and second display units.

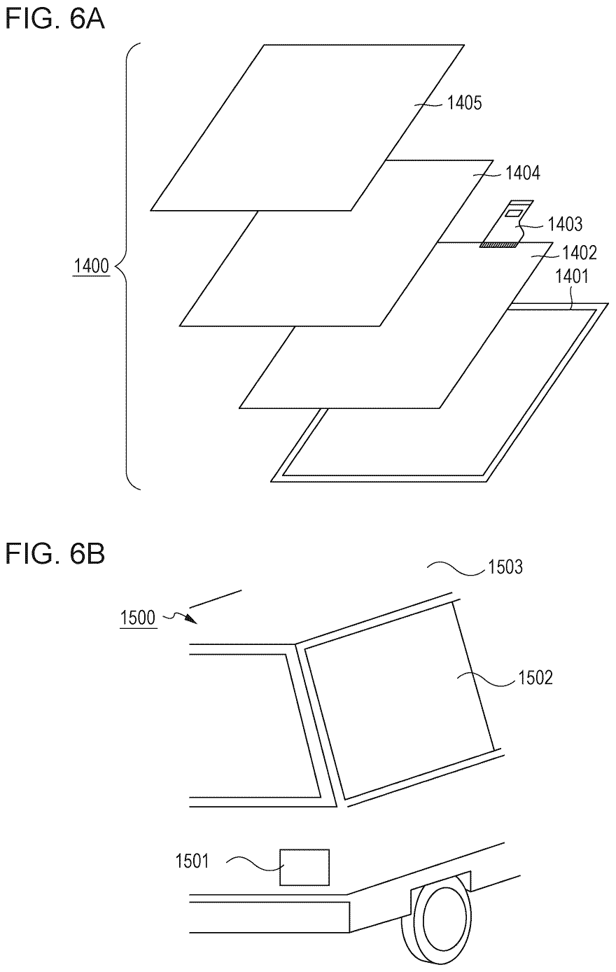

FIG. 6A is a schematic view illustrating an example of a lighting apparatus according to an embodiment of the present disclosure. A lighting apparatus 1400 includes a housing 1401, a light source 1402, a circuit board 1403, an optical filter 1404, and a light diffusion unit 1405. The light source 1402 includes an organic light-emitting device according to an embodiment of the present disclosure. The optical filter 1404 may be a filter that improves the color rendering properties of the light source. The light diffusion unit 1405 can effectively diffuse light from the light source 1402 to deliver the light to a wide range when used for illumination and so forth. The optical filter 1404 and the light diffusion unit 1405 may be disposed at the light emission side of the lighting apparatus. A cover may be disposed at the outermost portion, as needed.

The lighting apparatus is, for example, an apparatus that lights a room. The lighting apparatus may emit light of white, neutral white, or any color from blue to red. A light control circuit that controls the light may be provided. The lighting apparatus includes the organic light-emitting device of the present disclosure and a power supply circuit coupled thereto. The power supply circuit is a circuit that converts an AC voltage into a DC voltage. The color temperature of white is 4,200 K, and the color temperature of neutral white is 5,000 K. The lighting apparatus may include a color filter.

The lighting apparatus according to an embodiment of the present disclosure may include a heat dissipation unit. The heat dissipation unit is configured to release heat in the apparatus to the outside of the apparatus and is composed of, for example, a metal having a high specific heat and liquid silicone.

FIG. 6B is a schematic view of an automobile as an example of a moving object according to an embodiment of the present disclosure. The automobile includes a tail lamp, which is an example of lighting units. An automobile 1500 includes a tail lamp 1501 and may be configured to light the tail lamp when an operation, such as braking, is performed.

The tail lamp 1501 includes an organic light-emitting device according to an embodiment of the present disclosure. The tail lamp may include a protective member that protects the organic light-emitting device. The protective member may be made of any material as long as it has a certain degree of strength and is transparent. The protective member is preferably made of, for example, polycarbonate. The polycarbonate may be mixed with, for example, a furandicarboxylic acid derivative or an acrylonitrile derivative.

The automobile 1500 may include an automobile body 1503 and windows 1502 attached thereto. The windows may be transparent displays unless they are windows used to check areas in front of and behind the automobile. The transparent displays may include the organic light-emitting devices according to an embodiment of the present disclosure. In this case, the constituent materials, such as the electrodes, of the organic light-emitting devices are formed of transparent members.

The moving object according to an embodiment of the present disclosure may be, for example, a ship, an aircraft, or a drone. The moving object includes a body and a lighting unit attached to the body. The lighting unit emits light to indicate the position of the body. The lighting unit includes the organic light-emitting device according to the present embodiment.

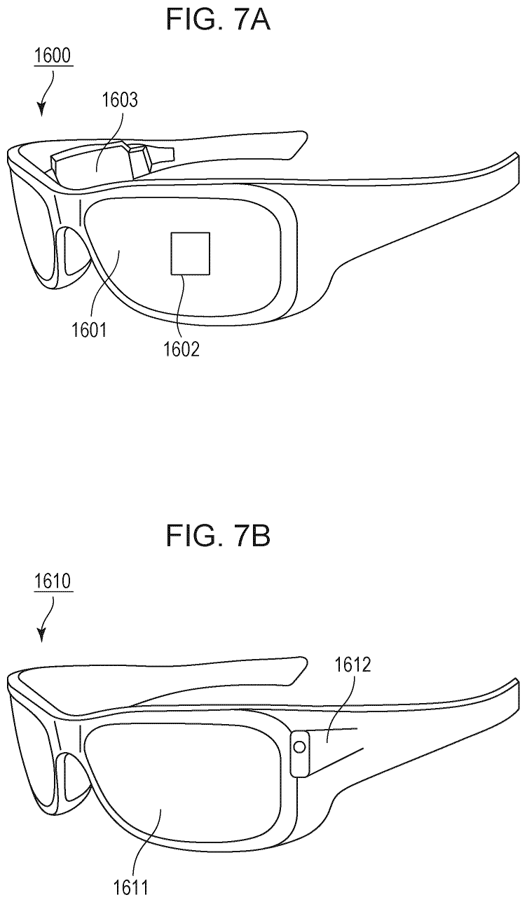

Examples of applications of the display apparatus of the above embodiment will be described with reference to FIGS. 7A and 7B. The display apparatus can be used for systems that can be worn as wearable devices, such as smart glasses, head-mounted displays (HMIDs), and smart contact lenses. An image pickup and display apparatus used in such an application example includes an image pickup apparatus that can photoelectrically convert visible light and a display apparatus that can emit visible light.

FIG. 7A illustrates a pair of glasses 1600 (smart glasses) according to one application example. An image pickup apparatus 1602, such as a complementary metal-oxide semiconductor (CMOS) sensor or a single-photon avalanche diode (SPAD), is provided on a front side of a lens 1601 of the glasses 1600. The display apparatus according to any of the above-mentioned embodiments is provided on the back side of the lens 1601.

The glasses 1600 further include a control unit 1603. The control unit 1603 functions as a power supply that supplies electric power to the image pickup apparatus 1602 and the display apparatus according to any of the embodiments. The control unit 1603 controls the operation of the image pickup apparatus 1602 and the display apparatus. The lens 1601 includes an optical system for focusing light on the image pickup apparatus 1602.

FIG. 7B illustrates a pair of glasses 1610 (smart glasses) according to one application example. The glasses 1610 include a control unit 1612. The control unit 1612 includes an image pickup apparatus corresponding to the image pickup apparatus 1602 illustrated in FIG. 7A and a display apparatus. A lens 1611 is provided with the image pickup apparatus in the control unit 1612 and an optical system that projects light emitted from the display apparatus. An image is projected onto the lens 1611. The control unit 1612 functions as a power supply that supplies electric power to the image pickup apparatus and the display apparatus and controls the operations of the image pickup apparatus and the display apparatus. The control unit 1612 may include a gaze detection unit that detects the gaze of a wearer. Infrared radiation may be used for gaze detection. An infrared light-emitting unit emits infrared light to an eyeball of a user who is gazing at a displayed image. An image of the eyeball is captured by detecting the reflected infrared light from the eyeball with an image pickup unit having light-receiving elements. A deterioration in image quality is reduced by providing a reduction unit that reduces light from the infrared light-emitting unit to the display unit when viewed in plan.

The user's gaze at the displayed image is detected from the image of the eyeball captured with the infrared light. Any known method can be used for the gaze detection using the captured image of the eyeball. As an example, a gaze detection method based on a Purkinje image of the reflection of irradiation light on a cornea can be used. More specifically, the gaze detection process is performed on the basis of a pupil-corneal reflection method. Using the pupil-corneal reflection method, the user's gaze is detected by calculating a gaze vector representing the direction (rotation angle) of the eyeball based on the image of the pupil and the Purkinje image contained in the captured image of the eyeball.

A display apparatus according to an embodiment of the present disclosure may include an image pickup apparatus including light-receiving elements, and may control an image displayed on the display apparatus based on the gaze information of the user from the image pickup apparatus. Specifically, in the display apparatus, a first field-of-view area at which the user gazes and a second field-of-view area other than the first field-of-view area are determined on the basis of the gaze information. The first field-of-view area and the second field-of-view area may be determined by the control unit of the display apparatus or may be determined by receiving those determined by an external control unit. In the display area of the display apparatus, the display resolution of the first field-of-view area may be controlled to be higher than the display resolution of the second field-of-view area. That is, the resolution of the second field-of-view area may be lower than that of the first field-of-view area.

The display area includes a first display area and a second display area different from the first display area. Based on the gaze information, an area of higher priority is determined from the first display area and the second display area. The first display area and the second display area may be determined by the control unit of the display apparatus or may be determined by receiving those determined by an external control unit. The resolution of an area of higher priority may be controlled to be higher than the resolution of an area other than the area of higher priority. In other words, the resolution of an area of a relatively low priority may be low.

Artificial intelligence (AI) may be used to determine the first field-of-view area and the high-priority area. The AI may be a model configured to estimate the angle of gaze from the image of the eyeball and the distance to a target object located in the gaze direction, using the image of the eyeball and the actual direction of gaze of the eyeball in the image as teaching data. The AI program may be stored in the display apparatus, the image pickup apparatus, or an external apparatus. When the AI program is stored in the external apparatus, the AI program is transmitted to the display apparatus via communications.

In the case of controlling the display based on visual detection, smart glasses that further include an image pickup apparatus that captures an external image can preferably be used. The smart glasses can display the captured external information in real time.

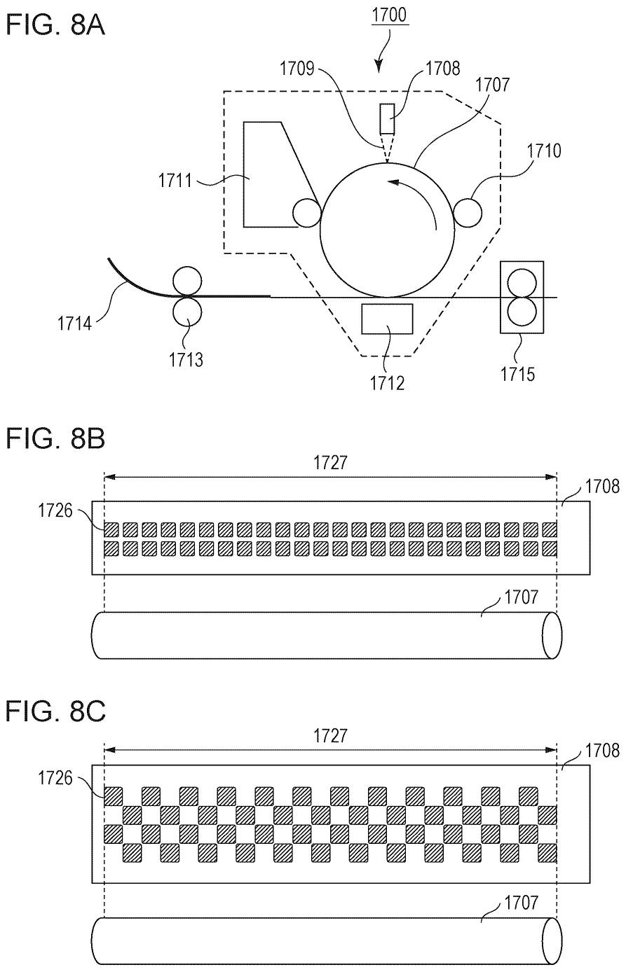

FIG. 8A is a schematic view of an example of an image-forming apparatus according to an embodiment of the present disclosure. An image-forming apparatus 1700 is an electrophotographic image-forming apparatus and includes a photoconductor 1707, an exposure light source 1708, a charging unit 1710, a developing unit 1711, a transfer unit 1712, a conveying roller 1713, and a fixing unit 1715. The irradiation of light 1709 is performed from the exposure light source 1708 to form an electrostatic latent image on the surface of the photoconductor 1707. This exposure light source 1708 includes an organic light-emitting device according to an embodiment of the present disclosure. The developing unit 1711 contains, for example, a toner. The charging unit 1710 charges the photoconductor 1707. The transfer unit 1712 transfers the developed image to a recording medium 1714. The conveying roller 1713 transports the recording medium 1714. The recording medium 1714 is paper, for example. The fixing unit 1715 fixes the image formed on the recording medium 1714.

FIGS. 8B and 8C each illustrate the exposure light source 1708 and are each a schematic view illustrating multiple light-emitting portions 1726 arranged on a long substrate. Arrows 1727 are parallel to the axis of the photoconductor and each represent the row direction in which the light-emitting portions including the organic light-emitting devices are arranged. The row direction is the same as the direction of the axis about which the photoconductor 1707 rotates. This direction can also be referred to as the long-axis direction of the photoconductor 1707. FIG. 8B illustrates a configuration in which the light-emitting portions 1726 are arranged in the long-axis direction of the photoconductor 1707. The light-emitting portions 1726 include organic light-emitting devices according to an embodiment of the present disclosure. FIG. 8C is different from FIG. 8B in that the light-emitting portions 1726 are arranged alternately in the row direction in a first row and a second row. The first row and the second row are located at different positions in the column direction. In the first row, the multiple light-emitting portions 1726 are spaced apart. The second row has the light-emitting portions 1726 at positions corresponding to the positions between the light-emitting portions 1726 in the first row. In other words, the multiple light-emitting portions 1726 are also spaced apart in the column direction. The arrangement in FIG. 8C can be rephrased as, for example, a lattice arrangement, a staggered arrangement, or a checkered pattern.

As described above, the use of an apparatus including the organic light-emitting device according to an embodiment of the present disclosure enables a stable display with good image quality even for a long time.

According to an embodiment of the present disclosure, an organic light-emitting device that operates at a low driving voltage and has excellent durability can be provided.

### EXAMPLES

The examples described below do not limit the content of the present disclosure.

### Example 1

In this example, a top-emission stacked organic light-emitting device was produced by sequentially forming, over a substrate, an anode as a first electrode, a first light-emitting unit, a charge generation region, a second light-emitting unit, and a cathode as a second electrode. An organic light-emitting device having a double-sided emission structure was produced by sequentially forming a first light-emitting unit including a blue light-emitting layer and a second light-emitting unit including a yellow light-emitting layer.

An ITO film was formed on a glass substrate and subjected to desired patterning to form an ITO electrode (anode). At this time, the thickness of the ITO electrode was 100 nm. The substrate on which the ITO electrode was formed in this manner was used as an ITO substrate. A first light-emitting unit, a charge generation region, a second light-emitting unit, and a cathode, as listed in Table 3 below, were deposited in this order over the ITO substrate by vacuum evaporation using resistance heating in the vacuum chamber. In this process, the area of the opposing electrodes (the anode and the cathode) was set to 3 mm². After the layers up to the cathode were deposited, the substrate was transferred into a glove box and encapsulated with a glass cap containing a desiccant in a nitrogen atmosphere to provide a stacked organic light-emitting device.

TABLE 3

| | | | Film |
|---|---|---|---|
| | | Material and | Thickness |
| Name | | composition | (nm) |
| Cathode | | Mg:Ag = 50:50 | 10 |
| | | (mass ratio) | |
| Second light- | Second electron | LiF | 1 |
| emitting | injection layer | | |
| unit | Second electron | ET1 | 20 |
| | transport layer | | |
| | Second hole-blocking | ET10 | 26 |
| | layer | | |
| | Second light-emitting | EM1:GD6:RD1 = | 20 |
| | layer | 97.5:2.0:0.5 | |
| | | (mass ratio) | |
| | Second electron- | HT7 | 10 |
| | blocking layer | | |
| Charge | p-Type charge | HT2 | 25 |
| generation | generation layer | HT16 | 8 |
| region | n-Type charge | ET1:B3:CsCO₃ = | 10 |
| | generation layer | 65:34:1 (mass ratio) | |
| First light- | First electron transport | ET1 | 20 |
| emitting | layer | | |
| unit | First hole-blocking | ET10 | 33 |
| | layer | | |
| | First light-emitting | EM2:BD8 = | 20 |
| | layer | 98.5:1.5 (mass ratio) | |
| | First electron-blocking | HT7 | 10 |
| | layer | | |
| | First hole transport | HT2 | 25 |
| | layer | | |
| | First hole injection | HT16 | 7 |
| | layer | | |

### Examples 2 to 17 and Comparative Examples 1 and 2

Organic light-emitting devices were produced in the same manner as in Example 1, except that the second organic compound and the alkali metal were changed to the compounds given in Table 4.

For the obtained organic light-emitting devices, the voltage-current characteristics were measured using a Hewlett-Packard 4140B picoammeter, and the emission spectra were measured using an SR-3 (manufactured by Topcon Corporation). The organic light-emitting devices of Examples 1 to 17 exhibited good white emission. A driving test of the organic light-emitting devices was carried out under a constant current density of 50 mA/cm². LT80, defined as the time required for the luminance to decrease by 20% from its initial value, and the driving voltage were evaluated. The results are presented in Table 4. The values of the driving-voltage ratio and durability ratio are relative values, with the driving voltage and LT80 of Comparative Example 1 each set to 1.0.

ΔLUMO and ΔHOMO in Table 4 are as follows.

$$Δ LUMO = \vert LUMO ( H 1 ) - LUMO ( H 2 ) \vert$$

$$Δ HOMO = HOMO ( H 2 ) - HOMO ( H 1 )$$

TABLE 4

| | First | | | | | | | |
|---|---|---|---|---|---|---|---|---|
| | electron | First | Second | Alkali | | | Driving | |
| | transport | organic | organic | metal | | | voltage | Durability |
| | layer | compound | compound | atom | ΔLUMO | ΔHOMO | ratio | ratio |
| Example 1 | ET1 | ET1 | B3 | Cs | 0.1 | 0.1 | 0.9 | 1.1 |
| Example 2 | ET1 | ET1 | A6 | Cs | 0.0 | 0.7 | 0.7 | 1.4 |
| Example 3 | ET1 | ET1 | A3 | Cs | 0.0 | 0.5 | 0.8 | 1.4 |
| Example 4 | ET1 | ET1 | A5 | Cs | 0.1 | 0.6 | 0.9 | 1.5 |
| Example 5 | ET1 | ET1 | A6 | Li | 0.0 | 0.7 | 0.7 | 1.4 |
| Example 6 | ET1 | ET1 | A5 | Li | 0.1 | 0.6 | 0.9 | 1.5 |
| Example 7 | ET1 | ET1 | D39 | Cs | 0.1 | 0.6 | 0.9 | 1.4 |
| Example 8 | ET1 | ET1 | E8 | Cs | 0.0 | 0.6 | 0.7 | 1.3 |
| Example 9 | ET1 | ET1 | F10 | Cs | 0.0 | 0.6 | 0.8 | 1.3 |
| Example 10 | ET1 | ET1 | D39 | Li | 0.1 | 0.6 | 0.9 | 1.4 |
| Example 11 | ET1 | ET1 | E8 | Li | 0.0 | 0.6 | 0.7 | 1.3 |
| Example 12 | ET1 | ET1 | AA6 | Cs | 0.1 | 0.5 | 0.9 | 1.1 |
| Example 13 | ET1 | ET1 | CC21 | Cs | 0.1 | 0.4 | 0.9 | 1.1 |
| Example 14 | ET1 | ET1 | DD6 | Cs | 0.0 | 0.6 | 0.8 | 1.2 |
| Example 15 | ET1 | ET1 | AA6 | Li | 0.1 | 0.5 | 0.9 | 1.1 |
| Example 16 | ET1 | ET1 | CC21 | Li | 0.1 | 0.4 | 0.9 | 1.1 |
| Example 17 | ET1 | ET1 | DD6 | Li | 0.0 | 0.6 | 0.8 | 1.2 |
| Comparative | ET1 | ET1 | 1-a | Cs | 0.2 | 0.5 | 1.0 | 1.0 |
| Example 1 | | | | | | | | |
| Comparative | ET1 | ET1 | ET3 | Cs | 0.2 | 0.4 | 1.0 | 0.8 |
| Example 2 | | | | | | | | |

### Examples 18 to 23 and Comparative Example 3

Organic light-emitting devices were produced in the same manner as in Example 1, except that, in each device, the material of the first electron transport layer was changed from ET1 to a corresponding one of the second organic compounds as listed in Table 5, and LT80 and the driving voltage were evaluated. The results are presented in Table 5. The values of the driving-voltage ratio and durability ratio are relative values, with the driving voltage and LT80 of Comparative Example 3 each set to 1.0. ΔLUMO and ΔHOMO are the same as in Table 4.

TABLE 5

| | First | | | | | | | |
|---|---|---|---|---|---|---|---|---|
| | electron | First | Second | Alkali | | | Driving | |
| | transport | organic | organic | metal | | | voltage | Durability |
| | layer | compound | compound | atom | ΔLUMO | ΔHOMO | ratio | ratio |
| Example 18 | 1-a | ET1 | AA6 | Li | 0.1 | 0.5 | 0.9 | 1.1 |
| Example 19 | AA6 | ET1 | AA6 | Li | 0.1 | 0.5 | 0.9 | 1.2 |
| Example 20 | 1-a | ET1 | CC21 | Li | 0.1 | 0.4 | 0.9 | 1.1 |
| Example 21 | CC21 | ET1 | CC21 | Li | 0.1 | 0.4 | 0.9 | 1.2 |
| Example 22 | 1-a | ET1 | DD6 | Li | 0.0 | 0.6 | 0.8 | 1.2 |
| Example 23 | DD6 | ET1 | DD6 | Li | 0.0 | 0.6 | 0.8 | 1.3 |
| Comparative | 1-a | ET1 | 1-a | Li | 0.2 | 0.5 | 1.0 | 1.0 |
| Example 3 | | | | | | | | |

As can be seen from Tables 4 and 5, when the second organic compound satisfying both formulae [1] and [2-1] is incorporated in the n-type charge generation layer as in Examples 1 to 23, the second organic compound traps only holes and does not trap electrons. This can inhibit the degradation of the first organic compound due to holes. As a result, deterioration of the entire n-type charge generation layer can be inhibited. Since holes are trapped in the n-type charge generation layer, the holes are less likely to reach the p-type charge generation layer. This inhibits deterioration of the organic light-emitting device. Furthermore, since electrons are not trapped, it is possible to improve durability and also achieve a lower driving voltage.

The organic light-emitting devices of Examples 1 to 11 have particularly high durability because, in each device, the second organic compound is the aromatic hydrocarbon compound and satisfies both formulae [1] and [2-2].

Organic compounds represented by General Formula [I] or [II] were used in Examples 12 to 23. In particular, in each of Examples 19, 21, and 23, the same compound as the second organic compound used in the n-type charge generation layer was used in the first electron transport layer. It was found that this inhibited the diffusion of lithium atoms used as alkali metal atoms into the light-emitting layer, inhibited quenching of the light-emitting material by the lithium atoms, and improved the durability of the organic light-emitting device.

In contrast, in Comparative Example 1, the second organic compound does not satisfy Formula [1], resulting in low electron mobility. Since the compound has a phenanthroline skeleton in its structure, the effect of inhibiting the diffusion of alkali metals is small, and the stability to holes is also low. Therefore, the organic light-emitting devices of Comparative Examples 1 and 3 each operate at a high driving voltage and exhibit poor durability. In Comparative Example 2, ET3 is used as the second organic compound. ET3 has two phenanthroline skeletons. Therefore, the diffusivity of alkali metals further increases, thereby decreasing the durability characteristics.

### Examples 24 to 26

Organic light-emitting devices were produced in the same manner as in Example 1, except that, in each device, the second organic compound used in Example 1 was changed to the compound listed in Table 6. LT80 and driving voltage were evaluated. The results are presented in Table 6. ΔLUMO and ΔHOMO are the same as in Table 4.

TABLE 6

| | First organic | | Second organic | | | | | |
|---|---|---|---|---|---|---|---|---|
| | compound | | compound | | | | Driving | |
| | | LUMO | | LUMO | | | voltage | Durability |
| | No. | HOMO | No. | HOMO | ΔLUMO | ΔHOMO | ratio | ratio |
| Example 24 | ET1 | −3.1 | BB3 | −2.8 | 0.3 | 0.7 | 1.0 | 1.2 |
| | | −6.6 | | −5.9 | | | | |
| Example 25 | ET1 | −3.1 | CC5 | −2.7 | 0.4 | 0.5 | 1.0 | 1.1 |
| | | −6.6 | | −6.1 | | | | |
| Example 26 | ET1 | −3.1 | DD5 | −2.9 | 0.2 | 0.6 | 0.9 | 1.2 |
| | | −6.6 | | −6.0 | | | | |
| Comparative | ET1 | −3.1 | 1-a | −2.9 | 0.2 | 0.5 | 1.0 | 1.0 |
| Example 1 | | −6.6 | | −6.1 | | | | |
| Comparative | ET1 | −3.1 | ET3 | −3.3 | 0.2 | 0.4 | 1.0 | 0.8 |
| Example 2 | | −6.6 | | −6.2 | | | | |

In each of Examples 24 to 26, the second organic compound in the n-type charge generation layer is represented by General Formula [I] or [II], but does not satisfy the requirement of Formula [1]. The organic compound does not have a phenanthroline skeleton, unlike the second organic compounds used in Comparative Examples 1 and 2. Thus, the effect of inhibiting the diffusion of alkali metals is high, and the stability to holes is high. Therefore, the organic light-emitting devices of Examples 24 to 26 exhibit superior durability to the organic light-emitting devices of Comparative Examples 1 and 2, despite the fact that Formulae [1] and [2-1] are not satisfied.

### Example 27

An organic light-emitting device was produced in the same manner as in Example 4, except that the light-emitting compound in the first light-emitting layer was changed from BD8 to BD1. LT80 and the driving voltage were evaluated. The results are presented in Table 7. In Table 7, ΔLUMO and ΔHOMO are defined as follows.

$$Δ LUMO = LUMO ( H 3 ) - LUMO ( D 1 )$$

$$Δ HOMO = HOMO ( D 1 ) - HOMO ( H 3 )$$

TABLE 7

| | | | First light- | | | | | |
|---|---|---|---|---|---|---|---|---|
| | Third organic | | emitting | | | | | |
| | compound | | compound | | | | Driving | |
| | | LUMO | | LUMO | | | voltage | Durability |
| | No. | HOMO | No. | HOMO | ΔLUMO | ΔHOMO | ratio | ratio |
| Example 4 | EM2 | −3.0 | BD8 | −3.2 | 0.2 | −0.1 | 0.9 | 1.5 |
| | | −6.0 | | −6.1 | | | | |
| Example 27 | EM2 | −3.0 | BD1 | −2.9 | −0.1 | 0.8 | 0.9 | 1.2 |
| | | −6.0 | | −5.2 | | | | |

As presented in Table 7, in Example 4, ΔLUMO (LUMO(H3)-LUMO(D1)) represented by Formula [4] is large, and the light-emitting layer has the configuration such that electrons are trapped, whereas holes are not trapped. In contrast, the configuration of Example 27 is such that electrons are not trapped, whereas holes are trapped. When holes are excessive in the light-emitting layer, excitons generated in the emitting layer tend to undergo a degradation mode that proceeds via a cationic state. Accordingly, in Example 27, the effect of the n-type charge generation layer according to an embodiment of the present disclosure is decreased due to the influence of this degradation mode in the light-emitting layer. Therefore, in an embodiment of the present disclosure, in particular, a configuration in which holes are not trapped in the light-emitting layer of the first light-emitting unit, that is, an electron-trap-type configuration as in Example 4, is more preferred, thereby enabling the n-type charge generation layer to exert a greater effect.

### Example 28

An organic light-emitting device was produced in the same manner as in Example 4, except that a ternary light-emitting layer was formed by adding EM3, serving as a fourth organic compound, to the first light-emitting layer in an amount of 30% by mass so that the mass ratio EM2:EM3:BD8 was 68.5:30:1.5. LT80 and the driving voltage were evaluated. The results are presented in Table 8. In Table 8, ΔHOMO is defined as follows.

$$Δ HOMO = HOMO ( H 4 ) - HOMO ( H 3 )$$

TABLE 8

| | Third organic | | Fourth organic | | | | |
|---|---|---|---|---|---|---|---|
| | compound | | compound | | | Driving | |
| | | LUMO | | LUMO | | voltage | Durability |
| | No. | HOMO | No. | HOMO | ΔHOMO | ratio | ratio |
| Example 4 | EM2 | −3.0 | — | — | — | 0.9 | 1.5 |
| | | −6.0 | | — | | | |
| Example 28 | EM2 | −3.0 | EM3 | −2.9 | 0.1 | 0.9 | 1.6 |
| | | −6.0 | | −5.9 | | | |

The configuration of Example 28 is one obtained by introducing the hole-trapping assist material into the light-emitting layer in the electron-trap-type configuration of Example 4. As a result, the light-emitting layer in which both electrons and holes are trapped can be formed. Therefore, as compared with Example 4, which exhibited good characteristics, leakage of holes into the n-type charge generation layer can be further inhibited, resulting in improved durability.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

1. An organic light-emitting device, comprising, in this order:
a first electrode;
a first light-emitting unit;
a charge generation region;
a second light-emitting unit; and
a second electrode,
wherein the charge generation region includes at least one n-type charge generation layer,
the at least one n-type charge generation layer contains at least a first organic compound and a second organic compound, and
the first organic compound and the second organic compound satisfy relationships represented by the following Formulae [1] and [2-1]:
$$\vert LUMO ( H 1 ) - LUMO ( H 2 ) \vert \leq 0.1 eV \qquad [ 1 ]$$
$$HOMO ( H 2 ) - HOMO ( H 1 ) > 0. eV \qquad [ 2 - 1 ]$$
where, in Formulae [1] and [2-1], LUMO(H1) represents a LUMO energy level of the first organic compound, LUMO(H2) represents a LUMO energy level of the second organic compound, HOMO(H1) represents a HOMO energy level of the first organic compound, and HOMO(H2) represents a HOMO energy level of the second organic compound.

2. The organic light-emitting device according to claim 1, wherein the first organic compound and the second organic compound satisfy a relationship represented by the following Formula [2-2]:
$$HOMO ( H 2 ) - HOMO ( H 1 ) \geq 0.2 eV . \qquad [ 2 - 2 ]$$

3. The organic light-emitting device according to claim 1, wherein the first organic compound is a nitrogen-containing aromatic compound, and
the second organic compound is an aromatic hydrocarbon compound or an aromatic heterocyclic compound.

4. The organic light-emitting device according to claim 1, wherein the at least one n-type charge generation layer further contains an alkali metal atom or an alkaline-earth metal atom.

5. The organic light-emitting device according to claim 1, wherein the first light-emitting unit includes a first light-emitting layer,
the first light-emitting layer contains at least a third organic compound and a first light-emitting compound, and
the third organic compound and the first light-emitting compound satisfy a relationship represented by the following Formula [3]:
$$LUMO ( H 3 ) - LUMO ( D 1 ) > HOMO ( D 1 ) - HOMO ( H 3 ) \qquad [ 3 ]$$
where, in Formula [3], LUMO(H3) represents a LUMO energy level of the third organic compound, LUMO(D1) represents a LUMO energy level of the first light-emitting compound, HOMO(H3) represents a HOMO energy level of the third organic compound, and HOMO(D1) represents a HOMO energy level of the first light-emitting compound.

6. The organic light-emitting device according to claim 5, wherein the third organic compound and the first light-emitting compound satisfy a relationship represented by the following Formula [4]:
$$LUMO ( H 3 ) - LUMO ( D 1 ) \geq 0.1 eV . \qquad [ 4 ]$$

7. The organic light-emitting device according to claim 5, wherein the first light-emitting layer further contains a fourth organic compound, and
the third organic compound and the fourth organic compound satisfy a relationship represented by the following Formula [5]:
$$HOMO ( H 4 ) - HOMO ( H 3 ) \geq 0.1 eV . \qquad [ 5 ]$$
where, in Formula [5], HOMO(H4) represents a HOMO energy level of the fourth organic compound.

8. An organic light-emitting device, comprising, in this order:
a first electrode;
a first light-emitting unit;
a charge generation region;
a second light-emitting unit; and
a second electrode,
wherein the charge generation region includes at least one n-type charge generation layer,
the at least one n-type charge generation layer contains at least a first organic compound and a second organic compound,
the first organic compound is a nitrogen-containing aromatic compound, and
the second organic compound is represented by the following General Formula [I] or [II]: 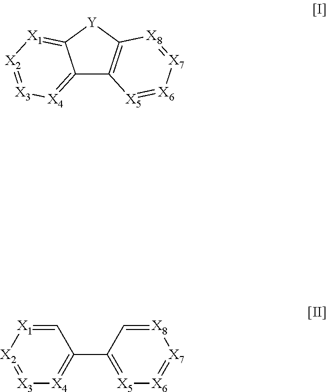
where, in General Formulae [I] and [II], X₁ to X₈ each represent a carbon atom having a substituent R or a nitrogen atom;
Y in General Formula [I] represents a carbon atom having substituents R₁ and R₂, or any of an oxygen atom, a sulfur atom, a selenium atom, and a tellurium atom;
when Y in General Formula [I] represents a carbon atom having substituents R₁ and R₂, at least one of X₁ to X₈ represents a nitrogen atom;
when the second organic compound is represented by General Formula [II], at least one of X₁ to X₈ represents a nitrogen atom;
R, R₁, and R₂ are each selected from a hydrogen atom, a deuterium atom, a halogen atom, a substituted or unsubstituted alkyl group, a substituted or unsubstituted aryl group, a substituted or unsubstituted heterocyclic group, a substituted or unsubstituted amino group, a substituted or unsubstituted silyl group, a substituted or unsubstituted alkoxy group, and a cyano group;
in General Formulae [I] and [II], when, among X₁ to X₈, carbon atoms each having a substituent R are adjacent to each other and each substituent R has a carbon atom, the adjacent substituents R are optionally taken together to form a ring; and
in General Formula [I], when R₁ and R₂ each have a carbon atom, the adjacent substituents R₁ and R₂ are optionally taken together to form a ring.

9. The organic light-emitting device according to claim 8, wherein the second organic compound is represented by the following General Formula [III]: 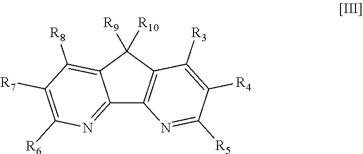
where, in General Formula [III], substituents R₃ to R₁₀ are each independently selected from the group consisting of a hydrogen atom, a deuterium atom, a substituted or unsubstituted alkyl group, a substituted or unsubstituted aryl group, and a substituted or unsubstituted heterocyclic group; and
when adjacent substituents among R₃ to R₁₀ each have a carbon atom, the adjacent substituents are optionally taken together to form a ring.

10. The organic light-emitting device according to claim 8, wherein the second organic compound is represented by the following General Formula [IV]: 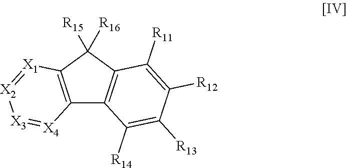
where, in General Formula [IV], X₁ to X₄ each represent a carbon atom having a substituent R or a nitrogen atom, and at least one of X₁ to X₄ represents a nitrogen atom;
R and R₁₁ to R₁₆ are each independently selected from the group consisting of a hydrogen atom, a deuterium atom, a substituted or unsubstituted alkyl group, a substituted or unsubstituted aryl group, and a substituted or unsubstituted heterocyclic group; and
when adjacent substituents among R₁₁ to R₁₆ each have a carbon atom, the adjacent substituents are optionally taken together to form a ring.

11. The organic light-emitting device according to claim 8, wherein the second organic compound is represented by the following General Formula [V]: 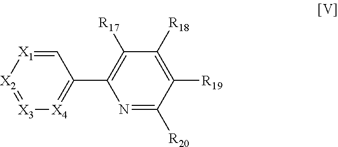
where, in General Formula [V], X₁ to X₄ each represent a carbon atom having a substituent R or a nitrogen atom, and at least one of X₁ to X₄ represents a nitrogen atom;
R and R₁₇ to R₂₀ are each independently selected from the group consisting of a hydrogen atom, a deuterium atom, a substituted or unsubstituted alkyl group, a substituted or unsubstituted aryl group, and a substituted or unsubstituted heterocyclic group; and
when adjacent substituents among R₁₇ to R₂₀ each have a carbon atom, the adjacent substituents are optionally taken together to form a ring.

12. The organic light-emitting device according to claim 8, wherein the second organic compound is represented by the following General Formula [VI]: 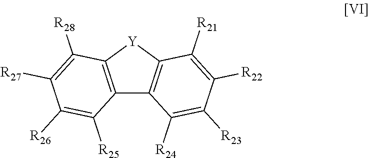
where, in General Formula [VI], Y represents any of an oxygen atom, a sulfur atom, a selenium atom, and a tellurium atom;
R₂₁ to R₂₈ are each independently selected from the group consisting of a hydrogen atom, a deuterium atom, a substituted or unsubstituted alkyl group, a substituted or unsubstituted aryl group, and a substituted or unsubstituted heterocyclic group; and
when adjacent substituents among R₂₁ to R₂₈ each have a carbon atom, the adjacent substituents are optionally taken together to form a ring.

13. The organic light-emitting device according to claim 8, further comprising an electron transport layer provided on the first electrode side and adjacent to the at least one n-type charge generation layer,
wherein the electron transport layer contains an organic compound represented by General Formula [I] or [II].

14. The organic light-emitting device according to claim 8, wherein the first organic compound and the second organic compound satisfy a relationship represented by the following Formula [1]:
$$\vert LUMO ( H 1 ) - LUMO ( H 2 ) \vert \leq 0.1 eV \qquad [ 1 ]$$
where, in Formula [1], LUMO(H1) represents a LUMO energy level of the first organic compound, and LUMO(H2) represents a LUMO energy level of the second organic compound.

15. The organic light-emitting device according to claim 14, wherein the first organic compound and the second organic compound satisfy a relationship represented by the following Formula [2-1]:
$$HOMO ( H 2 ) - HOMO ( H 1 ) > 0. eV \qquad [ 2 - 1 ]$$
where, in Formula [2-1], HOMO(H1) represents a HOMO energy level of the first organic compound, and HOMO(H2) represents a HOMO energy level of the second organic compound.

16. The organic light-emitting device according to claim 14, wherein the first organic compound and the second organic compound satisfy a relationship represented by the following Formula [2-2]:
$$HOMO ( H 2 ) - HOMO ( H 1 ) \geq 0.2 eV . \qquad [ 2 - 2 ]$$

17. The organic light-emitting device according to claim 8, wherein the at least one n-type charge generation layer further contains an alkali metal atom or an alkaline-earth metal atom.

18. The organic light-emitting device according to claim 8, wherein the first light-emitting unit includes a first light-emitting layer,
the first light-emitting layer contains at least a third organic compound and a first light-emitting compound, and
the third organic compound and the first light-emitting compound satisfy a relationship represented by the following Formula [3]:
$$LUMO ( H 3 ) - LUMO ( D 1 ) > HOMO ( D 1 ) - HOMO ( H 3 ) \qquad [ 3 ]$$
where, in Formula [3], LUMO(H3) represents a LUMO energy level of the third organic compound, LUMO(D1) represents a LUMO energy level of the first light-emitting compound, HOMO(H3) represents a HOMO energy level of the third organic compound, and HOMO(D1) represents a HOMO energy level of the first light-emitting compound.

19. The organic light-emitting device according to claim 18, wherein the third organic compound and the first light-emitting compound satisfy a relationship represented by the following Formula [4]:
$$LUMO ( H 3 ) - LUMO ( D 1 ) \geq 0.1 eV . \qquad [ 4 ]$$

20. The organic light-emitting device according to claim 18, wherein the first light-emitting layer further contains a fourth organic compound, and
the third organic compound and the fourth organic compound satisfy a relationship represented by the following Formula [5]:
$$HOMO ( H 4 ) - HOMO ( H 3 ) \geq 0.1 eV . \qquad [ 5 ]$$
where, in Formula [5], HOMO(H4) represents a HOMO energy level of the fourth organic compound.

21. A display apparatus, comprising:
a display unit including the organic light-emitting device according to claim 1; and
a housing provided with the display unit.

22. A photoelectric conversion apparatus, comprising:
an image pickup device configured to receive light; and
a display unit configured to display an image captured by the image pickup device,
wherein the display unit includes the organic light-emitting device according to claim 1.

23. An electronic apparatus, comprising:
a display unit including the organic light-emitting device according to claim 1;
a housing provided with the display unit; and
a communication unit disposed in the housing and configured to communicate with the outside.

24. A wearable device, comprising:
a display unit including the organic light-emitting device according to claim 1;
an optical system configured to focus light from the display unit; and
a control unit configured to control display of the display unit.

25. Alighting apparatus, comprising:
a light source including the organic light-emitting device according to claim 1; and
a housing provided with the light source.

26. A moving object, comprising:
a lighting unit including the organic light-emitting device according to claim 1; and
a body provided with the lighting unit.

27. An image-forming apparatus, comprising:
a photoconductor; and
an exposure light source configured to expose the photoconductor,
wherein the exposure light source includes the organic light-emitting device according to claim 1.
